(19) United States
(12) Patent Application Publication
(10) Pub. No.: US 2026/0058089 A1
(43) Pub. Date: Feb. 26, 2026

(54) VACUUM SIMULATION FOR CHARGED-PARTICLE MICROSCOPY GRID RECEPTACLES

(71) Applicant: FEI Company, Hillsboro, OR (US)

(72) Inventors: David Levi, Portland, OR (US); Simon-Pierre Smith, Hillsboro, OR (US); Jae Hong Kim, Lake Oswego, OR (US); Ali Haghshenas, Portland, OR (US)

(21) Appl. No.: 18/809,902

(22) Filed: Aug. 20, 2024

(51) Int. Cl. H01J 37/18; H01J 37/16; H01J 37/20

(52) U.S. Cl. CPC H01J 37/18; H01J 37/16; H01J 37/20; H01J 2237/166

(57) ABSTRACT

Systems/techniques are provided for facilitating vacuum simulation for charged-particle microscopy grid receptacles. In various embodiments, an apparatus can comprise a positioning mechanism configured to be coupled to a vacuum chamber of a charged-particle microscope. In various aspects, the apparatus can comprise an adjustable force applicator coupled to the positioning mechanism and configured to simulate a vacuum for a microscopy grid receptacle located on an inner surface of a load-lock door of the vacuum chamber by mechanically pressing against an outer surface of the load-lock door.

### BACKGROUND

Aligning a charged-particle microscopy robotic gripper with a grid receptacle can be difficult.

### SUMMARY

The following presents a summary to provide a basic understanding of one or more embodiments. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, devices, systems, computer-implemented methods, apparatus or computer program products that facilitate vacuum simulation for charged-particle microscopy grid receptacles are described.

According to one or more embodiments, an apparatus is provided. In various aspects, the apparatus can comprise a positioning mechanism configured to be coupled to a vacuum chamber of a charged-particle microscope. In various instances, the apparatus can comprise an adjustable force applicator coupled to the positioning mechanism and configured to simulate a vacuum for a microscopy grid receptacle located on an inner surface of a load-lock door of the vacuum chamber by mechanically pressing against an outer surface of the load-lock door.

According to one or more embodiments, a method is provided. In various aspects, the method can comprise coupling a positioning mechanism to a charged-particle microscope, wherein the charged-particle microscope has a vacuum chamber with a load-lock door and a microscopy grid receptacle coupled to an inner surface of the load-lock door. In various instances, the method can comprise simulating a vacuum for the microscopy grid receptacle by mechanically pressing against an outer surface of the load-lock door via an adjustable force applicator that is coupled to the positioning mechanism.

According to one or more embodiments, a method is provided. In various aspects, the method can comprise causing a vacuum chamber of a charged-particle microscope to enter a vacuumed state. In various instances, the method can comprise measuring, via a feedback sensor coupled to a load-lock door of the vacuum chamber, a vacuum-induced deflection or pressure experienced by the load-lock door due to the vacuumed state. In various cases, the method can comprise causing the vacuum chamber to exit the vacuumed state. In various aspects, the method can comprise simulating the vacuumed state, by causing an adjustable force applicator to mechanically press against the load-lock door such that the load-lock door experiences the vacuum-induced deflection or pressure while the vacuum chamber is not in the vacuumed state.

### DESCRIPTION OF THE DRAWINGS

Various embodiments will be readily understood by the following detailed description in conjunction with the accompanying figures. To facilitate this description, like reference numerals designate like structural elements. Embodiments are illustrated by way of example, not by way of limitation, in the figures. The figures are not necessarily drawn to scale.

FIG. 1 illustrates an example, non-limiting block diagram of a scientific instrument module in accordance with various embodiments described herein.

FIG. 2 illustrates an example, non-limiting flow diagram of a computer-implemented method in accordance with various embodiments described herein.

FIG. 3 illustrates a block diagram of an example, non-limiting system that facilitates vacuum simulation for charged-particle microscopy grid receptacles in accordance with one or more embodiments described herein.

FIGS. 4-9 illustrate example, non-limiting block diagrams showing how a vacuum chamber of a charged-particle microscope can be outfitted with vacuum-simulation hardware in accordance with one or more embodiments described herein.

FIG. 10 illustrates a block diagram of an example, non-limiting system including a reference feedback signal that facilitates vacuum simulation for charged-particle microscopy grid receptacles in accordance with one or more embodiments described herein.

FIG. 11 illustrates an example, non-limiting block diagram showing how a reference feedback signal can be obtained in accordance with one or more embodiments described herein.

FIG. 12 illustrates a block diagram of an example, non-limiting system including a vacuum-simulation pressing input value that facilitates vacuum simulation for charged-particle microscopy grid receptacles in accordance with one or more embodiments described herein.

FIGS. 13-14 illustrate example, non-limiting block diagrams showing how a vacuum-simulation pressing input value can be obtained in accordance with one or more embodiments described herein.

FIGS. 15-16 illustrate flow diagrams of example, non-limiting computer-implemented methods for obtaining a reference feedback signal and a vacuum-simulation pressing input value in accordance with one or more embodiments described herein.

FIG. 17 illustrates a block diagram of an example, non-limiting system including a vacuum-less alignment procedure that facilitates vacuum simulation for charged-particle microscopy grid receptacles in accordance with one or more embodiments described herein.

FIGS. 18-19 illustrate flow diagrams of example, non-limiting computer-implemented methods that facilitate a vacuum-less alignment procedure in accordance with one or more embodiments described herein.

FIGS. 20-25 illustrate example, non-limiting images of various experimental reductions to practice in accordance with one or more embodiments described herein.

FIG. 26 illustrates an example, non-limiting block diagram of a graphical user interface that can be used in the performance of some or all of the methods or techniques disclosed herein, in accordance with various embodiments described herein.

FIG. 27 illustrates an example, non-limiting block diagram of a computing device that can perform some or all of the methods or techniques disclosed herein, in accordance with various embodiments described herein.

FIG. 28 illustrates an example, non-limiting block diagram of a scientific instrument support system in which some or all of the methods or techniques disclosed herein may be performed, in accordance with various embodiments described herein.

FIG. 29 illustrates a block diagram of an example, non-limiting operating environment in which one or more embodiments described herein can be facilitated.

FIG. 30 illustrates an example networking environment operable to execute various implementations described herein.

FIG. 31 illustrates an example dual beam microscope that can be implemented in accordance with various embodiments described herein.

### DETAILED DESCRIPTION

The following detailed description is merely illustrative and is not intended to limit embodiments or application/uses of embodiments. Furthermore, there is no intention to be bound by any expressed or implied information presented in the preceding Background or Summary sections, or in the Detailed Description section.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Various operations can be described as multiple discrete actions or operations in turn, in a manner that is most helpful in understanding the subject matter disclosed herein. However, the order of description should not be construed as to imply that these operations are necessarily order dependent. In particular, these operations can be performed in an order different from the order of presentation. Operations described can be performed in a different order from the described embodiments. Various additional operations can be performed, or described operations can be omitted in additional embodiments.

Although some elements may be referred to in the singular (e.g., “a processing device”), any appropriate elements may be represented by multiple instances of that element, and vice versa. For example, a set of operations described as performed by a processing device may be implemented with different ones of the operations performed by different processing devices. As used herein, the phrase “based on” should be understood to mean “based at least in part on,” unless otherwise specified.

A charged-particle microscope (e.g., a scanning electron microscope (SEM), a transmission electron microscope (TEM), a focused ion beam microscope (FIB), a dual beam microscope) can be any suitable computerized device that can capture or generate microscopic or nanoscopic images of specimens in a scientific, laboratory, research, or clinical operational environment. To facilitate the capture or generation of such images, charged-particle microscopes can leverage complex arrangements of actuatable parts (e.g., ion sources, electron sources, optical lenses or apertures, optical plates or deflectors, columns, coils, heaters, coolers, fluid valves, fluid pumps, circuit switches, specimen stages), sensors (e.g., ion detectors, electron detectors, voltmeters, thermistors, potentiometers, pressure gauges), or consumables (e.g., carrier fluids, calibrants, filters, reactive gases).

In order for a charged-particle microscope to capture an image of a specimen (e.g., an integrated circuit chip, a semiconductor wafer, a lamella, an organic or biological tissue sample), the specimen can be placed on an actuatable stage within a vacuum chamber of the charged-particle microscope. Such placement can be accomplished via a robotic gripper and a grid receptacle that are also within the vacuum chamber. In particular, the grid receptacle can be any suitable fixed, static, or otherwise substantially stationary structure that can physically hold, house, or otherwise support any suitable number of grids, where each grid can be any suitable mesh, carrier, plate, or dish on which any suitable number of specimens can physically rest. Furthermore, the robotic gripper can be any suitable articulating or telescoping end-effector (e.g., an automated claw, an automated clamp, an automated hand) that can selectively grab one or more desired grids, and thus one or more desired specimens, from the grid receptacle and that can angularly or translationally move, so as to transport or convey the one or more desired grids to the actuatable stage. Accordingly, the robotic gripper can release its grip on the one or more desired grids, thereby placing, setting, or leaving the one or more desired grids, and thus the one or more desired specimens, on the actuatable stage, and so the charged-particle microscope can subsequently scan or capture images of the one or more desired specimens. After such scanning or image capturing, the robotic gripper can grab the one or more desired grids from the actuatable stage and can angularly or translationally move, so as to transport or convey the one or more desired grids back to the grid receptacle. Accordingly, the robotic gripper can release its grip on the one or more desired grids, thereby causing the one or more desired grids, and thus the one or more desired specimens, to be replaced or re-housed on or in the grid receptacle.

For any given grid, the given grid can be physically held, housed, or otherwise supported by the grid receptacle, based on or due to a shaft that protrudes from the given grid (e.g., that protrudes from the grid itself, or that protrudes from any suitable intermediate holder, carrier, cartridge, or other accessory to which the given grid is temporarily or permanently coupled) being inserted into a corresponding bore of the grid receptacle. Indeed, the shaft and the bore can be considered as mating surfaces. Accordingly, when the shaft protruding from the given grid is physically inserted into the bore of the grid receptacle, the given grid can be considered as being removably or slidably mated to the grid receptacle. Thus, when it is desired to transport or convey the given grid to the actuatable stage from the grid receptacle, the robotic gripper can grab onto the given grid (or onto whatever intermediate holder, carrier, cartridge, or other accessory is temporarily or permanently coupled to the given grid, as appropriate) and can physically pull on the given grid, so as to slide the shaft protruding from the given grid out of the bore, thereby freeing the given grid from the grid receptacle. Conversely, when it is desired to transport or convey the given grid to the grid receptacle from the actuatable stage, the robotic gripper can grab onto the given grid (or onto whatever intermediate holder, carrier, cartridge, or other accessory is temporarily or permanently coupled to the given grid, as appropriate) and can physically push on the given grid, so as to slide the shaft protruding from the given grid into the bore, thereby once again slidably or removably mating the given grid to the grid receptacle.

In order for the robotic gripper to correctly, properly, or otherwise accurately retrieve the given grid from the grid receptacle or replace the given grid back onto the grid receptacle, the robotic gripper should know how to angularly or translationally position or orient itself in three-dimensional space, so that the shaft protruding from the grid receptacle is precisely aligned in two translational directions (e.g., left-right direction, up-down direction) and in two rotational directions (e.g., pitch, yaw) with the bore of the grid receptacle. Indeed, there can be as little as only 6 to 30 micrometers of clearance between the shaft and the bore. If the shaft is not precisely aligned with the bore when the robotic gripper attempts to remove the given grid from the grid receptacle, or when the robotic gripper attempts to replace the given grid back onto the grid receptacle, then the shaft's outer surface can rub, bind, or collide excessively against the bore's inner surface. In some cases, such excessive rubbing, binding, or collision can physically jostle, destabilize, or otherwise damage whatever specimen is on the given grid, which can be undesirable. In other cases, such excessive rubbing, binding, or collision can generate metal shavings or other particulates that can contaminate whatever specimen is on the given grid, which can be undesirable. In even other cases, such excessive rubbing, binding, or collision can physically deteriorate or prematurely wear the robotic gripper, the given grid, or the grid receptacle, which can be undesirable.

Various techniques involving borescopes, cameras, or lasers can be implemented to teach the robotic gripper how to become translationally or angularly aligned with the grid receptacle. However, to avoid having to constantly reteach the robotic gripper such alignment, the position of the grid receptacle within the vacuum chamber should be constant, uniform, or otherwise precisely repeatable (e.g., to less than 5 micrometers of variation) over time (e.g., if the robotic gripper is taught how to become translationally or angularly aligned when the grid receptacle is located at a first position within the vacuum chamber, such teaching can be considered as useless or wasted if the grid receptacle is later located at a different position within the vacuum chamber).

Ensuring that the grid receptacle is located at a precisely repeatable position within the vacuum chamber can often involve iteratively or incrementally altering or correcting the position of the grid receptacle. In various cases, the vacuum chamber can be considered as being made up of a main portion and a load-lock portion, where the main portion can contain the actuatable stage and thus be considered as the site where scanning occurs, and where the load-lock portion can be considered as a type of anti-chamber used for the delivery of fresh grids into or the removal of old grids from the vacuum chamber. The load-lock portion can have a load-lock door which can be considered as a structurally reinforced door which can be opened or closed, and which, when closed, can be considered as separating the interior of the vacuum chamber from gases outside of the vacuum chamber. Oftentimes, the grid receptacle can be physically affixed or coupled to the inner surface of the load-lock door. Since the grid receptacle can be inanimate, stationary, or otherwise non-automated, the position of the grid receptacle can be adjusted or corrected manually by a technician only when the load-lock door is open. After all, if the load-lock door is closed, the technician cannot physically access or touch the grid receptacle and thus cannot alter the position of the grid receptacle.

Unfortunately, existing techniques for achieving a precisely repeatable position of the grid receptacle are excessively time-consuming. Indeed, existing techniques proceed as follows. First, such existing techniques involve a technician coarsely positioning the grid receptacle on the inner surface of the load-lock door (e.g., the technician can be considered as placing the grid receptacle at whatever approximate position at which the grid receptacle was located when the robotic gripper was taught alignment). Such existing techniques then involve closing the load-lock door and pumping the vacuum chamber down to whatever vacuum pressure at which the charged-particle microscope is expected or intended to perform scans. Such existing techniques then involve causing the robotic gripper to attempt to engage, interact, or become aligned with the grid receptacle and observing (e.g., via cameras, borescopes, or lasers) how much alignment error the robotic gripper exhibits. Accordingly, such existing techniques involve venting the vacuum chamber back to atmospheric pressure and opening the load-lock door, such that the technician can incrementally alter or correct the position of the grid receptacle so as to reduce the observed error. Such existing techniques can then repeat, iterate, or cycle such actions (e.g., closing the load-lock door; pumping down the vacuum chamber; observing a new alignment error; venting the vacuum chamber; opening the load-lock door; and adjusting or correcting the position of the grid receptacle based on the new alignment error) until the most recently observed alignment error is satisfactory or below any suitable threshold. In practice, it often takes upwards of 30 of such iterations or cycles for the observed alignment error to become satisfactorily small. Note that each of such iterations or cycles can consume about 207 minutes of time (e.g., opening and closing the load-lock lock door can take less than one minute each; altering the position of the grid receptacle can take about 5 minutes; observing the alignment error can take about 20 minutes; venting the vacuum chamber to atmospheric pressure can take about 30 minutes; and pumping the vacuum chamber down to operating pressure can take about 150 minutes). Thus, 30 of such iterations or cycles can consume over 103 hours in total. In some cases, implementation of a load-lock valve in between the robotic gripper and the load-lock door can help to somewhat reduce this exorbitant amount of time from hundreds of hours to dozens of hours (e.g., the load-lock valve can be closed prior to opening the load-lock door, such that each cycle or iteration can involve pumping and venting only the portion of the vacuum chamber that is in between the load-lock valve and the load-lock door rather than the entirety of the vacuum chamber), but even that can still be considered as excessively time-consuming.

Accordingly, systems or techniques that can achieve a constant, uniform, or precisely repeatable grid receptacle position with less time-consumption can be desirable.

Various embodiments described herein can address this technical problem. One or more embodiments described herein can include systems, computer-implemented methods, apparatus, or computer program products that can facilitate vacuum simulation for charged-particle microscopy grid receptacles. In other words, the inventors of various embodiments described herein devised various techniques for achieving a precisely repeatable position of a grid receptacle within a vacuum chamber of a charged-particle microscope, by having each alignment iteration or cycle simulate a vacuumed state of the vacuum chamber rather than having each alignment iteration or cycle actually pump and vent the vacuum chamber.

Existing techniques require actual pumping and venting of the vacuum chamber during each alignment iteration or cycle, because the load-lock door can experience non-zero vacuum-induced deflection or deformation. Indeed, the grid receptacle can be physically affixed to a load-lock door of the vacuum chamber. Moreover, the charged-particle microscope can properly scan a specimen only when the vacuum chamber is in a vacuumed state (e.g., if scanning were performed when the vacuum chamber were instead in a vented state, then whatever charged-particle beam that the charged-particle microscope were to use for such scanning would experience instability or interference due to collisions with gas molecules). When the vacuum chamber is in the vacuumed state, the load-lock door can be considered as experiencing a significant pressure differential (e.g., atmospheric pressure on the outside of the load-lock door; negative or vacuum pressure on the inside of the load-lock door). This pressure differential can cause the load-lock door to bow, bend, deflect, or otherwise deform inwards by tens or even hundreds of micrometers. In contrast, such bowing, bending, deflection, or deformation does not occur when the vacuum chamber is in a vented state (e.g., is at atmospheric pressure). Accordingly, since the grid receptacle can be physically affixed to the inside of the load-lock door, the exact position of the grid receptacle can change by tens or even hundreds of micrometers due to vacuum-induced bowing, bending, deflection, or deformation of the load-lock door. In other words, if the alignment iterations of existing techniques were performed without pumping and venting the vacuum chamber, whatever finalized position of the grid receptacle is determined to minimize the observed alignment error would not be the true position that the grid receptacle would occupy during operation of the charged-particle microscope (e.g., during operation of the charged-particle microscope, the vacuum chamber would be in the vacuumed state, and the grid-receptacle would thus move away from that finalized position by tens or hundreds of micrometers due to vacuum-induced deflection of the load-lock door). For at least these reasons, existing techniques emphasize the importance of pumping and venting the vacuum chamber during each alignment iteration or cycle, so as to avoid alignment inconsistencies caused by vacuum-induced deflection of the load-lock door.

The present inventors counterintuitively devised the herein-described embodiments, which can include alignment iterations or cycles that omit or exclude the repetitive vacuum chamber pumping and venting that are required, necessitated, and emphasized by existing techniques. Indeed, the present inventors innovatively realized that the vacuum-induced bowing, bending, deflection, or deformation of the load-lock door can be mechanically simulated in each alignment iteration or cycle, as opposed to being actually implemented by pumping or venting the vacuum chamber. Specifically, various embodiments described herein can involve measuring an amount of deflection or force that the load-lock door experiences due to the vacuum chamber being in the vacuumed state. Moreover, various embodiments described herein can involve recreating or simulating such deflection or force when the vacuum chamber is in the vented state, by physically or mechanically pressing against the outside of the load-lock door. Such physical or mechanical pressing can be accomplished in mere seconds by any suitable electric, pneumatic, or hydraulic actuators, in contrast to actually pumping and venting the vacuum chamber which can instead be accomplished in tens or hundreds of minutes. Accordingly, each alignment iteration or cycle of various embodiments described herein can omit pumping and venting the vacuum chamber and can instead include mechanically pushing or pressing against the outside of the load-lock door. In this way, a total of 30 alignment iterations or cycles can be accomplished in a few hours, which can be considered as extremely fast or quick when compared to the over 100 hours required by existing techniques.

Various embodiments described herein can be considered as a computerized tool (e.g., any suitable combination of computer-executable hardware or computer-executable software) that can facilitate vacuum simulation for charged-particle microscopy grid receptacles. In various aspects, such computerized tool can comprise an access component, a reference component, a simulation component, or an alignment component.

In various embodiments, there can be a charged-particle microscope. In various aspects, the charged-particle microscope can exhibit any suitable design or construction (e.g., can be an SEM, can be a TEM, can be a dual-beam microscope). In various instances, the charged-particle microscope can have any suitable vacuum chamber, and any suitable robotic gripper and grid receptacle can be deployed or implemented within the vacuum chamber. In various cases, the grid receptacle can be affixed to an inner surface of a load-lock door of the vacuum chamber.

In various aspects, the robotic gripper can have been taught (e.g., via borescopes, cameras, or lasers) how to translationally or angularly align its shaft-axis (e.g., axis that would be concentric with a shaft protruding from a grid, when the grid is held by the robotic gripper) with a bore-axis (e.g., axis of a bore into which a shaft protruding from a grid can be inserted) of the grid receptacle. It can be desired to precisely place or align the grid receptacle in or with whatever position it occupied during such teaching. As described herein, the computerized tool can accomplish such placement or alignment, by leveraging various vacuum-simulation hardware that can be equipped onto or into the charged-particle microscope.

In particular, the vacuum-simulation hardware can include an adjustable force applicator, a positioning mechanism, or a feedback sensor.

In various embodiments, the adjustable force applicator can be any suitable actuatable mechanical tool or device that can controllably or selectively apply continuous physical or tactile pushing or compressive force to any suitable target object (e.g., can be an electric or hydraulic press or clamp). In various aspects, the adjustable force applicator can be affixed to the positioning mechanism.

In various instances, the positioning mechanism can be any suitable physical structure that is kinematically actuatable, so as to move the adjustable force applicator from a retracted position to a deployed position, or from the deployed position to the retracted position, in a precise or otherwise highly repeatable fashion (e.g., can include rigid bodies that are kinematically coupled to each other or to electric motors via hinges, pins, slides, or bearings). When in the retracted position, the adjustable force applicator can be not in physical contact with the outer surface of the load-lock door, such that the adjustable force applicator cannot push or press against the outer surface of the load-lock door. In other words, when in the retracted position, the adjustable force applicator can be considered as having no target object on which it can impart physical or tactile pushing or compressive force. On the other hand, when in the deployed position, the adjustable force applicator can be in physical contact with the outer surface of the load-lock door, such that the adjustable force applicator can push or press against the outer surface of the load-lock door. In other words, when in the deployed position, the outer surface of the load-lock door can be considered as the target object on which the adjustable force applicator can impart physical or tactile pushing or compressive force.

In various cases, the feedback sensor can be any suitable electronic or mechanical sensor that can measure deflection of or force experienced by the load-lock door (e.g., can be a strain gauge, force transducer, or chromatic confocal sensor).

Now, in various embodiments, the reference component of the computerized tool can electronically identify a reference feedback signal, by leveraging the vacuum-simulation hardware. In particular, the reference component can electronically cause the positioning mechanism to place the adjustable force applicator into the retracted position. Moreover, the vacuum chamber can initially be in a vented state, and the load-lock door can initially be open. In various aspects, the reference component can electronically cause the load-lock door to close and can electronically cause the vacuum chamber to transition from the vented state to a vacuumed state (e.g., can cause the vacuum chamber to be pumped down to operating pressure). In various instances, the reference component can obtain the reference feedback signal, by reading the feedback sensor while the vacuum chamber is in the vacuumed state and the adjustable force applicator is in the retracted position. For example, if the feedback sensor is a strain gain, then the feedback sensor can be considered as measuring how much strain or deflection the load-lock door experiences due to the vacuumed state, and the reference feedback signal can be equal to that measured strain or deflection. As another example, if the feedback sensor is a force transducer, then the feedback sensor can be considered as measuring how much force or stress the load-lock door experiences due to the vacuumed state, and the reference feedback signal can be equal to that measured force or stress. In any case, the reference feedback signal can be any suitable electronic data that quantifies or indicates how the load-lock door physically responds to the vacuumed state.

In various embodiments, the simulation component of the computerized tool can electronically identify a vacuum-simulation pressing input value, by leveraging the vacuum-simulation hardware and the reference feedback signal.

More specifically, the adjustable force applicator can be considered as having a pressing input parameter. In various aspects, the pressing input parameter can be any suitable controllable, configurable, or adjustable setting of the adjustable force applicator that can dictate how hard or with how much force the adjustable force applicator mechanically pushes or presses against a target object (e.g., assigning a minimum value to the pressing input parameter can cause the adjustable force applicator to push or press against a target object with a minimum amount of force; assigning a maximum value to the pressing input parameter can cause the adjustable force applicator to push or press against a target object with a maximum amount of force; assigning an intermediate value to the pressing input parameter can cause the adjustable force applicator to push or press against a target object with an intermediate amount of force).

Now, the reference component can have caused the vacuum chamber to be in the vacuumed state and the adjustable force applicator to be in the retracted position. In various instances, the simulation component can electronically cause the vacuum chamber to transition from the vacuumed state to the vented state (e.g., by venting the vacuum chamber to atmospheric pressure). In various cases, the simulation component can electronically cause the load-lock door to remain closed and can electronically cause the positioning mechanism to place the adjustable force applicator into the deployed position. Because the adjustable force applicator is in the deployed position, the adjustable force applicator can be able to mechanically press or push against the outer surface of the load-lock door. In various aspects, the simulation component can electronically cause the adjustable force applicator to mechanically push or press against the outer surface of the load-lock door, so as to recreate the reference feedback signal. For example, the simulation component can: incrementally sweep the pressing input parameter through its possible range or domain of values beginning with a minimum possible value; and, for each swept pressing input value, read the feedback sensor. In such case, each swept value of the pressing input parameter can be considered as causing the adjustable force applicator to mechanically press against the outer surface of the load-lock door with a respective or commensurate amount of pressure and can thus be considered as causing the feedback sensor to readout a respective or commensurate amount of displacement or force. In various instances, whichever swept value of the pressing input parameter causes the readout of the feedback sensor to be equal to (or otherwise within any suitable threshold margin of) the reference feedback signal can be considered or treated as the vacuum-simulation pressing input value. In other words, the vacuum-simulation pressing input value can be considered as being whatever value of the pressing input parameter of the adjustable force applicator that causes the load-lock door to respond or behave as if the vacuum chamber were in the vacuumed state. In still other words, the vacuum-simulation pressing input value can be considered as being whatever value of the pressing input parameter that causes the adjustable force applicator to simulate the vacuumed state of the vacuum chamber.

In various embodiments, the alignment component of the computerized tool can electronically facilitate a vacuum-less alignment procedure for the grid receptacle, by leveraging the vacuum-simulation pressing input value and the vacuum-simulation hardware. In particular, the vacuum-less alignment procedure can proceed as follows. In various aspects, the alignment component can cause the vacuum chamber to be in the vented state. Moreover, the alignment component can cause the adjustable force applicator to be placed in the retracted position and the load-lock door to be open. Since the load-lock door is open, a technician can make whatever manual adjustment or change to the position of the grid receptacle on the inner surface of the load-lock door that they desire (e.g., can coarsely place the grid receptacle at or near whatever approximate position it occupied when the robotic gripper was taught how to become translationally or angularly aligned with the grid receptacle). In response to an electronic indication that the technician has completed whatever positional change or adjustment to the grid receptacle that they desire (e.g., the technician can push a user interface button of the charged-particle microscope upon completing the positional adjustment to the grid receptacle), the alignment component can cause the load-lock door to close and can cause the positioning mechanism to place the adjustable force applicator into the deployed position. In various aspects, the alignment component can then cause the adjustable force applicator to mechanically press against the outer surface of the load-lock door according to the vacuum-simulation pressing input value, thereby causing the load-lock door to experience whatever deflection or force that it would experience if the vacuum chamber were in the vacuumed state. In various instances, the alignment component can then cause the robotic gripper to attempt to engage, interact, or align with the grid receptacle, thereby allowing the technician to observe an alignment error. In various cases, the alignment component can then cause the positioning mechanism to place the adjustable force applicator into the retracted state and can cause the load-lock door to open, thereby allowing the technician to make whatever positional adjustment or change to the grid receptacle that they believe will reduce the observed alignment error. In various aspects, the alignment component can repeat, iterate, or cycle the above-described actions until the most recently observed alignment error is below any suitable threshold.

Note that the vacuum-less alignment procedure can omit or exclude repetitively pumping and venting the vacuum chamber, hence the term “vacuum-less”. In place of such repetitive pumping and venting, the vacuum-less alignment procedure can instead include mechanically simulating such pumping and venting via the adjustable force applicator, which can be considered as significantly less time-consuming (e.g., pumping the vacuum chamber can take about 150 minutes, and venting the vacuum chamber can take about 30 minutes; in stark contrast, engaging or activating the adjustable force applicator can take mere seconds). Accordingly, the vacuum-less alignment procedure can consume less time (e.g., indeed, more than an order of magnitude less time) than existing techniques.

Various embodiments described herein can be employed to use hardware or software to solve problems that are highly technical in nature (e.g., to facilitate vacuum simulation for charged-particle microscopy grid receptacles), that are not abstract and that cannot be performed as a set of mental acts by a human. Further, some of the processes performed can be performed by a specialized computer (e.g., charged-particle microscopes such as SEMs, TEMs, or dual-beam microscopes having vacuum chambers and grid-handling robotics; physical hardware such as hydraulic presses and strain gauges) for carrying out defined acts related to the field of charged-particle microscopy.

For example, such defined acts can include: coupling a positioning mechanism to a charged-particle microscope, wherein the charged-particle microscope has a vacuum chamber with a load-lock door and a microscopy grid receptacle coupled to an inner surface of the load-lock door; and simulating a vacuum for the microscopy grid receptacle by mechanically pressing against an outer surface of the load-lock door via an adjustable force applicator that is coupled to the positioning mechanism. In various cases, the adjustable force applicator can comprise a toggle-clamp, an electric rotary or linear actuator, a pneumatic rotary or linear actuator, or a hydraulic rotary or linear actuator. In various aspects, the positioning mechanism can be configured to move the adjustable force applicator between: a retracted position in which the adjustable force applicator is not in contact with the load-lock door; and a deployed position in which the adjustable force applicator is in contact with the load-lock door. In various cases, the positioning mechanism can comprise one or more sliding, articulating, or telescoping arms or frames. In various instances, the charged-particle microscope can comprise a feedback sensor coupled to the load-lock door and configured to measure feedback associated with the load-lock door. In various cases, the feedback sensor can comprise a strain gauge, a spring gauge, a force or pressure transducer, a chromatic confocal sensor, a capacitive sensor, an eddy current sensor, or a laser interferometer, and the feedback can be a deflection experienced by the load-lock door or a force experienced by the load-lock door. In various aspects, such defined acts can comprise: causing the positioning mechanism to move the adjustable force applicator to the retracted position; activating a pump of the vacuum chamber, thereby causing the vacuum chamber to transition to a vacuumed state; measuring, via the feedback sensor, a reference feedback signal that the load-lock door experiences due to the vacuumed state; activating a vent of the vacuum chamber, thereby causing the vacuum chamber to transition to a vented state; causing the positioning mechanism to move the adjustable force applicator to the deployed position; and identifying, via the feedback sensor and by causing the adjustable force applicator to sweep through a plurality of pressing input values, a pressing input value of the adjustable force applicator that causes the load-lock door to experience the reference feedback signal. In various cases, such defined acts can comprise: performing a vacuum-less alignment procedure on the microscopy grid receptacle using the identified pressing input value.

Such defined acts are inherently hardware-based. Indeed, a charged-particle microscope (e.g., SEM, TEM, FIB, dual beam microscope) is a highly-technical computerized device comprising specific computerized hardware (e.g., temperature sensors, pressure sensors, voltage sensors, ion beam emitters, electron beam emitters, focusing lenses, ion detectors, electron detectors, beam apertures, fluid valves, actuatable specimen stages). Neither a charged-particle microscope nor the specimen-handling robotic hardware thereof can be implemented by the human mind, or by a human with pen and paper, in any reasonable or practicable way without computers. Furthermore, positioning mechanisms (e.g., rotating or telescoping robotic arms), adjustable force applicators (e.g., electric, pneumatic, or hydraulic clamps or presses), and feedback sensors (e.g., strain gauges or force transducers) are tangible, physical pieces of specific hardware that cannot be implemented in any reasonable way by the human mind or by a human with mere pen and paper.

Moreover, various embodiments described herein can integrate into a practical application various teachings relating to the field of charged-particle microscopy. As explained above, a robotic gripper of a charged-particle microscope can be taught (e.g., via cameras, borescopes, or lasers) how to angularly or translationally align its shaft-axis with a bore-axis of a grid receptacle of the charged-particle microscope. That is, whichever specific three-dimensional position or orientation of the robotic gripper causes the shaft-axis to be aligned with the bore-axis can be identified. However, such teaching can be considered as useful only if the grid receptacle has a constant, uniform, or otherwise precisely repeatable position within the charged-particle microscope. Generally, the grid receptacle is physically affixed to an inner surface of a load-lock door of a vacuum chamber of the charged-particle microscope. Existing techniques attempt to achieve a constant, uniform, or repeatable position of the grid receptacle by: closing the load-lock door; pumping the vacuum chamber down to operating pressure; observing an alignment error by causing the robotic gripper to attempt to engage or interact with the grid receptacle while the vacuum chamber is at operating pressure; venting the vacuum chamber back to atmospheric pressure; opening the load-lock door such that a technician can adjust the position of the grid receptacle based on the alignment error; and iterating the above actions until the most recently observed alignment error is satisfactorily small.

Unfortunately, such existing techniques are extremely time-consuming. Indeed, due to the pumping and venting of the vacuum chamber, each alignment iteration or cycle of such existing techniques can consume upwards of 200 minutes. Thus, since such existing techniques often require as many as 30 iterations to achieve a satisfactorily small alignment error, such existing techniques can consume a total of about 100 hours.

Although such pumping and venting are the most time-consuming portions of such existing techniques, such existing techniques emphasize how important such pumping and venting are for achieving a constant, uniform, or repeatable position of the grid receptacle. After all, the charged-particle microscope can properly perform scans only when the vacuum chamber is in the vacuumed state, and the vacuumed state can be considered as exposing the load-lock door to a significant pressure differential that can cause the load-lock door to bow, bend, or otherwise deflect inwards by dozens of micrometers. Thus, if the alignment procedure of existing techniques were performed without pumping the vacuum chamber down to operating pressure during each iteration or cycle, whatever finalized position of the grid receptacle that seems to achieve a satisfactorily small alignment error would not actually be the true position occupied by the grid receptacle during use of the charged-particle microscope. In other words, vacuum-induced deflection of the load-lock door would lead to alignment inconsistencies if the alignment procedure of existing techniques did not involve pumping the vacuum chamber down to operating pressure. However, the alignment procedure of existing techniques also requires the vacuum chamber to be at least sometimes at atmospheric pressure. Otherwise, the load-lock door would not be able to be opened, and the position of the grid receptacle would thus not be able to be moved or changed. Accordingly, existing techniques necessitate pumping and venting of the vacuum chamber during each alignment iteration or cycle.

Various embodiments described herein can help to ameliorate one or more of these technical problems. In other words, various embodiments described herein can achieve a constant, uniform, or repeatable position of the grid receptacle without the excessive time-consumption of existing techniques. In particular, the present inventors realized that, rather than having each alignment iteration or cycle actually pump and vent the vacuum chamber, each alignment iteration or cycle can instead mechanically simulate such pumping or venting. In this way, alignment inconsistencies caused by vacuum-induced deflection of the load-lock door can be avoided, without the excessive time-consumption that accompanies actually pumping and venting the vacuum chamber. More specifically, various embodiments described herein can achieve a constant, uniform, or repeatable position of the grid receptacle by: closing the load-lock door; while keeping the vacuum chamber at atmospheric pressure, simulating vacuum-induced deflection by mechanically pressing against an outside surface of the load-lock door, such that the deflection or force experienced by the load-lock door is equivalent to that which the load-lock door would experience if the vacuum chamber were pumped down to operating pressure; observing an alignment error by causing the robotic gripper to attempt to engage or interact with the grid receptacle while the vacuum chamber is at operating pressure; ceasing the mechanical pressing against the outside of the load-lock door; opening the load-lock door such that the technician can adjust the position of the grid receptacle based on the alignment error; and iterating the above actions until the most recently observed alignment error is satisfactorily small.

Such embodiments are significantly less time-consuming than existing techniques. Indeed, since pumping and venting of the vacuum chamber can be omitted, each alignment iteration or cycle of such embodiments can consume a mere fraction of the time that an alignment iteration or cycle of existing techniques would consume (e.g., since venting the vacuum chamber from operating pressure to atmospheric pressure can consume about 30 minutes, and since pumping the vacuum chamber from atmospheric pressure to operating pressure can consume about 150 minutes, each alignment iteration or cycle of existing techniques can consume 180 fewer minutes than those of existing techniques). Thus, since as many as 30 iterations can be needed to achieve a satisfactorily small alignment error, such embodiments can consume a total amount of time that is about 90 hours less than the total amount of time consumed by existing techniques. Accordingly, various embodiments described herein constitute a significant technical improvement over existing techniques.

Furthermore, it must be highlighted how counter-intuitive various embodiments described herein are. As explained above, existing techniques emphasize the importance of actually pumping and venting the vacuum chamber during each alignment iteration or cycle. Indeed, existing techniques teach that such pumping and venting are necessary to avoid alignment inconsistencies caused by vacuum-induced deflection of the load-lock door. In other words, existing techniques emphasize that pumping and venting are critical, crucial, important, or otherwise indispensable in achieving a constant, uniform, or repeatable position of the grid receptacle. Accordingly, because various embodiments described herein omit or exclude such pumping and venting, such various embodiments can be considered as being highly counterintuitive or unexpected in view of existing techniques. In other words, the present inventors devised innovative techniques to achieve a constant, uniform, or repeatable position of the grid receptacle, which innovative techniques eliminate the purportedly critical, crucial, important, or indispensable parts of existing techniques. In still other words, existing techniques can be considered as teaching away from or against various embodiments described herein.

Further still, various embodiments not only consume less time than existing techniques, but can also achieve higher alignment precision than existing techniques. Indeed, various embodiments described herein can involve simulating operating pressure of the vacuum chamber by mechanically pressing against the outside surface of the load-lock door, where such mechanical pressing can be accomplished via an electric, pneumatic, or hydraulic clamp or press. In particular, a strain gauge, force transducer, or contactless displacement sensor (e.g., chromatic confocal sensor, capacitive sensor) can monitor the load-lock door so as to measure how much deflection or force the operating pressure of the vacuum chamber imparts onto the load-lock door, and the electric, pneumatic, or hydraulic clamp or press can push against the outside surface of the load-lock door so as to recreate that same amount of deflection or force. Indeed, in experiments that measured deflection of the load-lock door via a chromatic confocal sensor, the present inventors found that the deflection measured by the chromatic confocal sensor exhibited a certain level of variance or noise when that deflection was caused by the operating pressure of the vacuum chamber, and the present inventors also found that the deflection measured by the chromatic confocal sensor exhibited a lower level of variance or noise when that deflection was instead caused by the electric, pneumatic, or hydraulic clamp or press. In other words, the electric, pneumatic, or hydraulic clamp or press was able to impart a tighter, less varying, or more stable deflection (and thus force) onto the load-lock door than the operating pressure of the vacuum chamber was able to impart. The present inventors found this result to be rational, since fixing an electric, pneumatic, or hydraulic clamp or press at a given level of actuation can be considered as easier, less difficult, or less resource-intensive than fixing a vacuum chamber at a given negative pressure. In other words, controlling an electric, pneumatic, or hydraulic clamp or press can be considered as a less difficult mechanical, electrical, or physical task than controlling a vacuum chamber. Accordingly, because the electric, pneumatic, or hydraulic clamp or press was able to impart a tighter, less varying, or more stable deflection (and thus force) onto the load-lock door than the operating pressure of the vacuum chamber was able to impart, various embodiments described herein can be considered as achieving more precise, tighter, or less varying alignment of the grid receptacle than existing techniques are able to achieve. Again, various embodiments described herein thus constitute a significant technical improvement over existing techniques.

Additionally, various embodiments described herein can be considered as an elegant solution for achieving repeatable and less-time-consuming positioning of the grid receptacle that introduces a low amount of complexity to the charged-particle microscope. Indeed, a potential alternative solution for achieving repeatable and less-time-consuming positioning of the grid receptacle could be to fabricate, manufacture, or otherwise integrate feedthrough actuators into the load-lock door, such that the grid receptacle's position can be changed or altered without having to open the load-lock door. Such alternative solution would eliminate the need to repetitively pump and vent the vacuum chamber (e.g., the vacuum chamber could be kept at operating pressure, and the grid receptacle could be positionally altered via the feedthrough actuators without opening the load-lock door). However, such alternative solution would require significantly redesigning the load-lock door and thereby introduce a myriad of new failure modes to the vacuum chamber (e.g., would require rebuilding the vacuum chamber so as to have many new moving pieces that can potentially fail). In stark contrast, various embodiments described herein do not require redesigning the charged-particle microscope (e.g., such embodiments can be considered as add-ons that can be bolted onto any suitable charged-particle microscope).

For at least the above reasons, various embodiments described herein can be considered as addressing or ameliorating various problems or disadvantages that afflict existing techniques. Therefore, various embodiments described herein can be considered as a concrete and tangible technical improvement in the field of charged-particle microscopy. Accordingly, various embodiments described herein certainly qualify as useful and practical applications of computers.

Furthermore, it should be appreciated that various embodiments described herein can control real-world, tangible devices. Indeed, various embodiments can involve activating or deactivating real-world robotic grippers, real-world vacuum chambers, and real-world electric or hydraulic presses that can be deployed on or in real-world charged-particle microscopes.

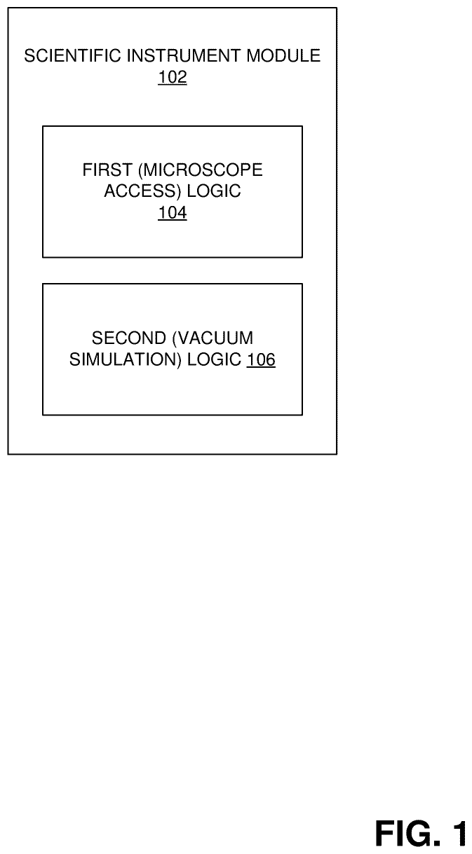

FIG. 1 illustrates an example, non-limiting block diagram of a scientific instrument module 102 in accordance with various embodiments described herein.

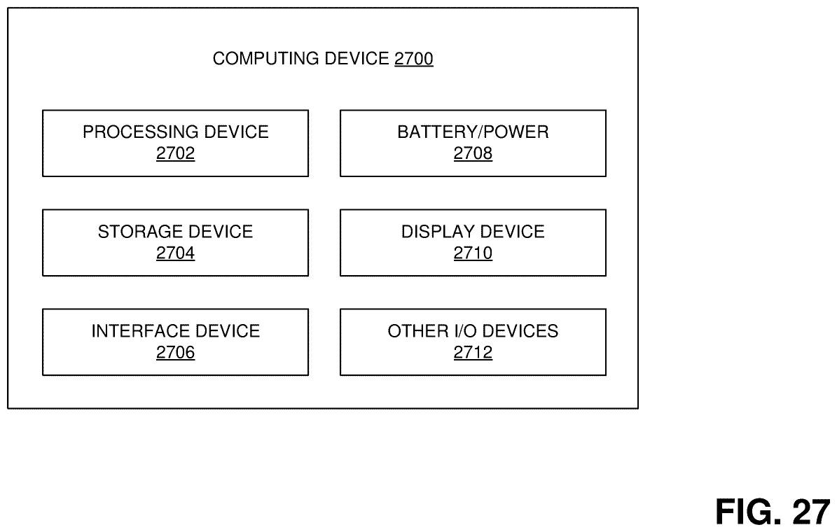

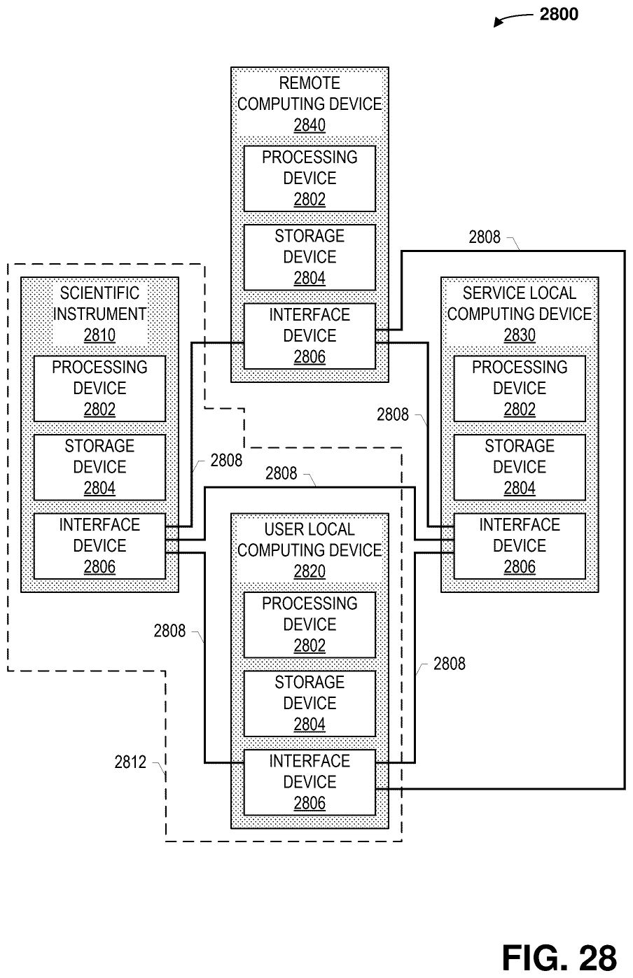

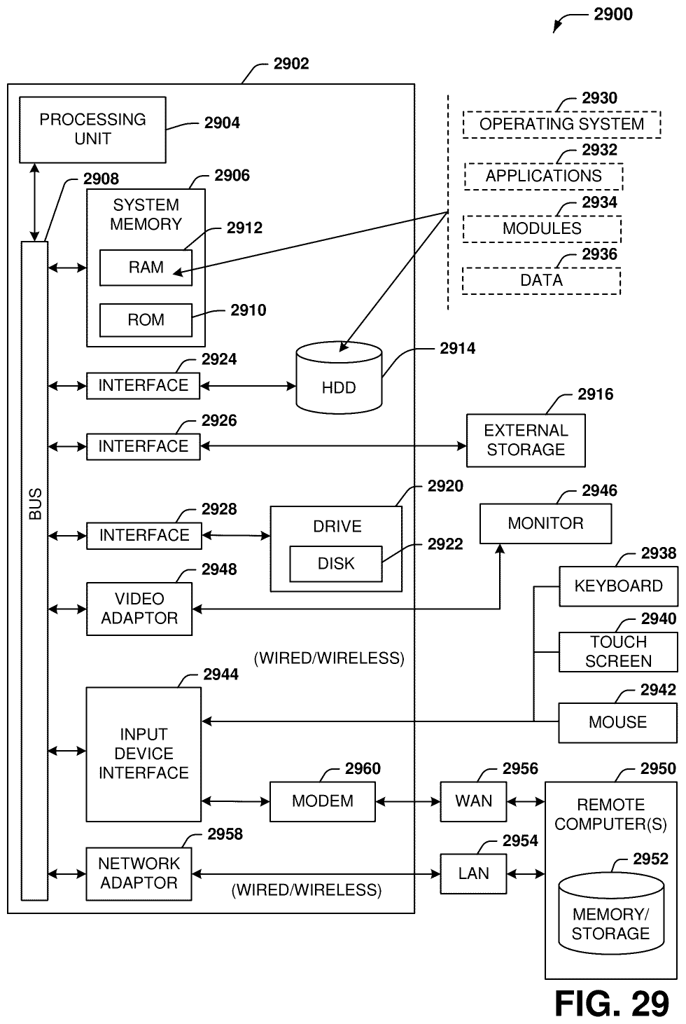

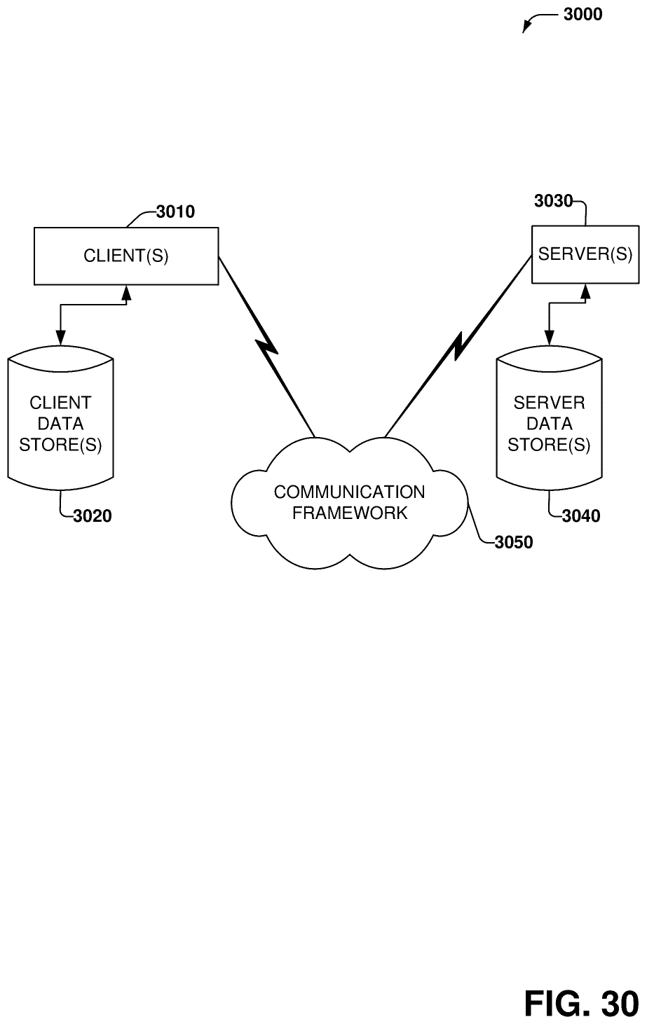

In various embodiments, the scientific instrument module 102 can be implemented by circuitry (e.g., including electrical or optical components), such as a programmed computing device. Logic of the scientific instrument module 102 can be included in a single computing device or can be distributed across multiple computing devices that are in communication with each other as appropriate. Examples of computing devices that may, singly or in combination, implement the scientific instrument module 102 are discussed herein with reference to FIGS. 27 and 29, and examples of systems or networks of interconnected computing devices, in which the scientific instrument module 102 may be implemented across one or more of the computing devices, are discussed herein with reference to FIGS. 28 and 30. The scientific instrument module 102 can include first logic 104 and second logic 106. As used herein, the term “logic” can include an apparatus that is to perform a set of operations associated with the logic. For example, any of the logic elements included in the scientific instrument module 102 can be implemented by one or more computing devices programmed with instructions to cause one or more processing devices of the computing devices to perform the associated set of operations. In a particular embodiment, a logic element may include one or more non-transitory computer-readable media having instructions thereon that, when executed by one or more processing devices of one or more computing devices, cause the one or more computing devices to perform the associated set of operations. As used herein, the term “module” can refer to a collection of one or more logic elements that, together, perform a function associated with the module. Different ones of the logic elements in a module may take the same form or may take different forms. For example, some logic in a module may be implemented by a programmed general-purpose processing device, while other logic in a module may be implemented by an application-specific integrated circuit (ASIC). In another example, different ones of the logic elements in a module may be associated with different sets of instructions executed by one or more processing devices. A module can omit one or more of the logic elements depicted in the associated drawings; for example, a module may include a subset of the logic elements depicted in the associated drawings when that module is to perform a subset of the operations discussed herein with reference to that module.

In various embodiments, there can be a scientific instrument corresponding to the scientific instrument module 102. In various aspects, the scientific instrument can be any suitable computerized device that can electronically measure some scientifically-relevant, clinically-relevant, or research-relevant characteristic, property, or attribute of an analytical specimen (e.g., of a known or unknown mixture, compound, or collection of matter). As a non-limiting example, a scientific instrument can be a scanning electron microscope. In such case, the scientific instrument can capture images of the analytical specimen, so as to measure or determine a surface topography, a surface material composition, or a crystallographic structure of the analytical specimen. As another non-limiting example, a scientific instrument can be a transmission electron microscope. In such case, the scientific instrument can capture images of the interior of the analytical specimen, so as to measure or determine interior structural details of the analytical specimen. As even another non-limiting example, a scientific instrument can be a dual beam microscope. In such case, the scientific instrument can capture images of the analytical specimen in addition to being able to mill or otherwise make physical or chemical changes to the analytical specimen. As a more general non-limiting example, a scientific instrument can be any suitable type of charged-particle microscope (e.g., some types of microscopes can use beams of non-electron ions to capture images). In various instances, the scientific instrument can contain or otherwise have a vacuum chamber with a load-lock door and a grid receptacle coupled to an inner surface of the load-lock door.

In various embodiments, the first logic 104 can involve accessing the scientific instrument. Accordingly, electronic instructions or commands can be transmitted to or from the scientific instrument.

In various embodiments, the second logic 106 can involve simulating a vacuum for the grid receptacle by mechanically pressing against an outer surface of the load-lock door via an adjustable force applicator. More specifically, the adjustable force applicator can be movable (e.g., via sliding, hinging, or articulating structural supports) between a retracted position (in which the adjustable force applicator cannot press against the outer surface of the load-lock door) and a deployed position (in which the adjustable force applicator can press against the outer surface of the load-lock door). In various aspects, the second logic 106 can involve moving the adjustable force applicator to the retracted position, closing the load-lock door, pumping the vacuum chamber to a vacuumed state, and measuring, via a feedback sensor, how much deflection or force the vacuumed state imparts onto the load-lock door. In various instances, the second logic 106 can involve venting the vacuum chamber to a vented state, moving the adjustable force applicator to the deployed position, and identifying (e.g., via a parameter sweep and via the feedback sensor) an input parameter value that causes the adjustable force applicator to press against the outer surface of the load-lock door such that the load-lock door experiences the same deflection or force that it experienced when the vacuum chamber was in the vacuumed state. In various cases, that input parameter value can be considered as causing the adjustable force applicator to simulate the vacuumed state. In various aspects, the second logic 106 can involve performing a vacuum-less alignment procedure on the grid receptacle, by leveraging that input parameter value.

Accordingly, the scientific instrument module 102 can facilitate vacuum simulation for charged-particle microscopy grid receptacles.

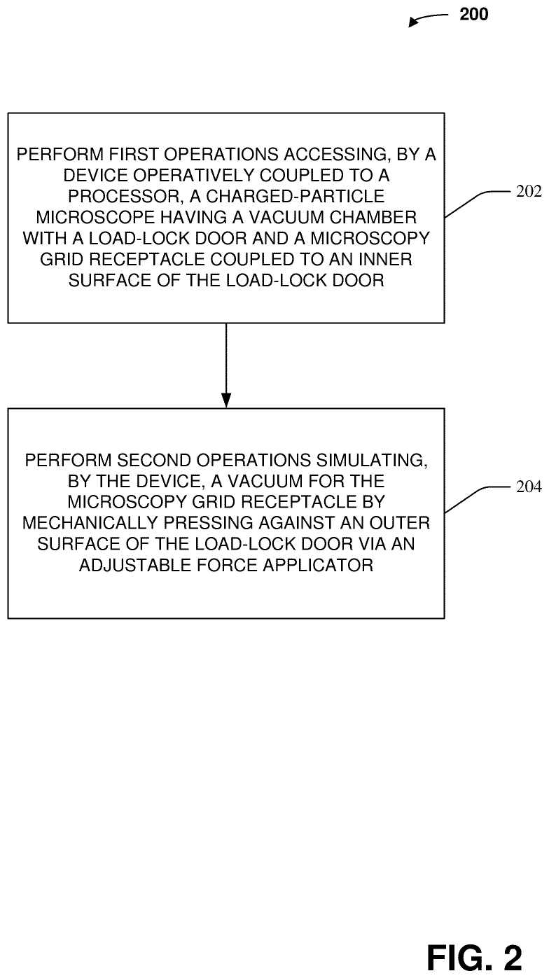

FIG. 2 is an example, non-limiting flow diagram of a computer-implemented method 200 in accordance with various embodiments described herein. The operations of the computer-implemented method 200 may be used in any suitable context to perform any suitable operations (e.g., can be performed by or used in conjunction with any of the various modules, computing devices, or graphical user interfaces described with respect to of FIGS. 1, 26, 27, 28, 29, and 30). Operations are illustrated once each and in a particular order in FIG. 2, but the operations may be reordered or repeated as desired and appropriate (e.g., different operations performed may be performed in parallel, as suitable).

In various aspects, act 202 can include performing first operations accessing, by a device operatively coupled to a processor, a charged-particle microscope having a vacuum chamber with a load-lock door and a microscopy grid receptacle coupled to an inner surface of the load-lock door. In various cases, the first logic 104 can perform or otherwise facilitate act 202.

In various aspects, act 204 can include performing second operations simulating, by the device, a vacuum for the microscope grid receptacle by mechanically pressing against an outer surface of the load-lock door via an adjustable force applicator. In various instances, the second logic 106 can perform or otherwise facilitate act 204.

Accordingly, the computer-implemented method 200 can facilitate vacuum simulation for charged-particle microscopy grid receptacles.

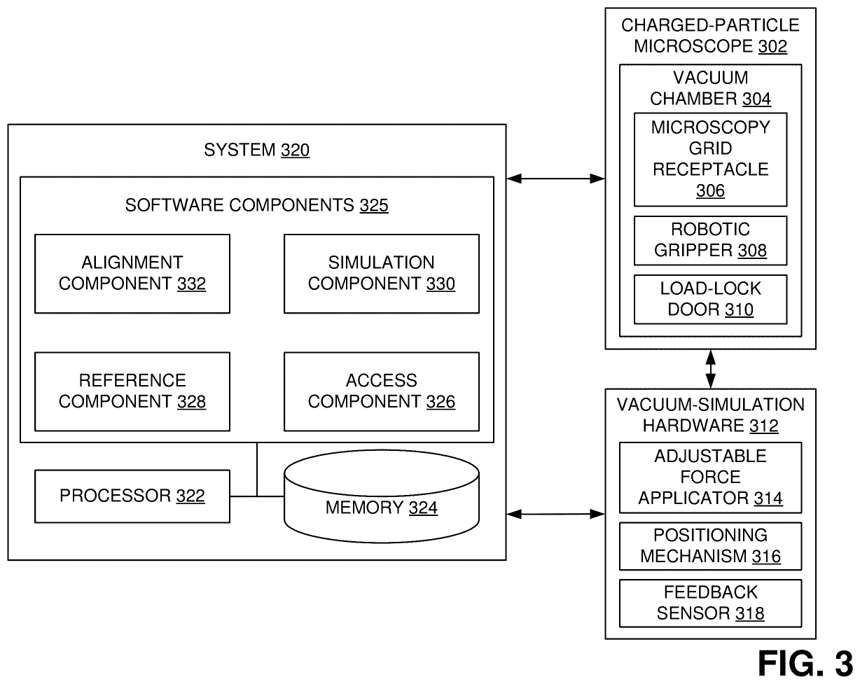

FIG. 3 illustrates a block diagram of an example, non-limiting system that can facilitate vacuum simulation for charged-particle microscopy grid receptacles in accordance with one or more embodiments described herein.

In various embodiments, there can be a charged-particle microscope 302. In various aspects, the charged-particle microscope 302 can be as described above.

That is, the charged-particle microscope 302 can be any suitable computerized device that can leverage its constituent hardware (e.g., electron sources, anodes, condenser lenses, condenser apertures, scan coils, objective lenses, objective apertures, deflectors, condensers, stigmators, electron detectors, X-ray detectors, actuatable specimen stages) to electronically capture any suitable image of any suitable analytical specimen. As a non-limiting example, the charged-particle microscope 302 can be any suitable SEM. As another non-limiting example, the charged-particle microscope 302 can be any suitable TEM. As yet another non-limiting example, the charged-particle microscope 302 can be any suitable dual-beam microscope.

Although not explicitly shown in the figures, the charged-particle microscope 302 can be electronically integrated with any suitable human-computer interface device, which can be remote from or local to the charged-particle microscope 302. Accordingly, a user or technician associated with the charged-particle microscope 302 can interact with or otherwise control the charged-particle microscope 302. Some non-limiting examples of the human-computer interface device can be a keyboard of the charged-particle microscope 302, a keypad of the charged-particle microscope 302, a touchscreen of the charged-particle microscope 302, or a voice-command system of the charged-particle microscope 302.

In any case, the charged-particle microscope 302 can comprise a vacuum chamber 304. In various aspects, the vacuum chamber 304 can be any suitable type of structural shell or enclosure having any suitable size or shape, being made up of any suitable materials (e.g., stainless steel, titanium), and having an interior volume that can be vacated or evacuated of air or other gases to any suitable vacuum pressure via any suitable vacuum pumps. Indeed, when it is desired for the charged-particle microscope 302 to scan any given specimen, such scanning can be performed under vacuum within the vacuum chamber 304. After all, if such scanning were not performed under vacuum, whatever charged-particle beam that the charged-particle microscope 302 were to use for such scanning would experience instability or interference due to collisions with gas molecules.

In various embodiments, a microscopy grid receptacle 306 and a robotic gripper 308 can be implemented or deployed within the vacuum chamber 304.

In various instances, the microscopy grid receptacle 306 can be any suitable structure having any suitable size or shape, being made up of any suitable materials (e.g., stainless steel, titanium, aluminum), and being configured to physically hold or support any suitable number of microscopy grids. In various cases, a microscopy grid can be any suitable partitioned or non-partitioned plate, dish, or slab on which any suitable specimen can be placed or set for purposes of carrying, transportation, or conveyance. Non-limiting examples of a microscopy grid can include: a copper grid; a gold grid; a quantifoil grid; a carbon grid; a silicon nitride grid; a mesh grid; a holey grid; or a support film.

In various aspects, the robotic gripper 308 can be any suitable automated end-effector that can controllably move through three-dimensional space. In particular, the robotic gripper 308 can be any suitable automated hand, automated clamp, automated claw, automated hook, or automated suction-cup affixed to any suitable articulating or telescoping arm that has any suitable number and any suitable types of kinematic degrees of freedom. In various cases, the robotic gripper 308 can be made up of any suitable types of linear or rotational actuators, such as: electric, electronic, or piezoelectric linear or rotational actuators (e.g., servo motors); pneumatic linear or rotational actuators; or hydraulic linear or rotational actuators. Prior to a microscopy scan, the robotic gripper 308 can physically grab a given microscopy grid from the microscopy grid receptacle 306, can angularly or translationally transport that given microscopy grid to an actuatable stage (not shown) within the vacuum chamber 304, and can then release its grip, thereby placing or setting the given microscopy grid onto the actuatable stage in preparation for the microscopy scan. Conversely, after the microscopy scan, the robotic gripper 308 can physically grab the given microscopy grid receptacle from the surface of the actuatable stage, can angularly or translationally transport the given microscopy grid back to the microscopy grid receptacle 306, and can then release its grip, thereby replacing or resetting the given microscopy grid onto or into the microscopy grid receptacle 306.

In particular, a microscopy grid (or any suitable accessory hardware that can be coupled to the microscopy grid) can comprise a protruding shaft. In various aspects, such shaft can be configured to mate with a respective bore of the microscopy grid receptacle 306. In other words, such shaft can be insertable into the bore of the microscopy grid receptacle 306. When the shaft is inserted into the bore of the microscopy grid receptacle 306, the microscopy grid can be considered as being slidably or removably coupled to the microscopy grid receptacle 306. Accordingly, the microscopy grid receptacle 306 can, in some cases, be considered as a structural rack, stand, or other fixture on which or from which microscopy grids can be pegged or hung via such shaft-to-bore insertion.

In various embodiments, the vacuum chamber 304 can comprise a load-lock door 310. In various aspects, the load-lock door 310 can be any suitable actuatable hatch that can serve as an openable or closeable entrance or exit into or out of the vacuum chamber 304. As a non-limiting example, the vacuum chamber 304 can, as mentioned above, be a structural shell or enclosure whose interior can contain the microscopy grid receptacle 306 and the robotic gripper 308, and whose interior can be vacated of air or other gases. So, that structural shell or enclosure can be considered as being a collection of structurally-reinforced walls that form an air-tight surrounding around the microscopy grid receptacle 306 and the robotic gripper 308. In various instances, at least one of those structurally-reinforced walls can have a discrete part, portion, or section that can be movably attached to the remainder of the vacuum chamber 304 via any suitable number of any suitable types of hinges, pins, swivels, slides, or other mechanical joints. Thus, in various cases, that discrete part, portion, or section of structurally-reinforced wall can be opened by any suitable electric, pneumatic, hydraulic, or other mechanical actuators, thereby allowing any fresh microscopy grids to be delivered into the vacuum chamber 304 or old microscopy grids to be removed from the vacuum chamber 304 (e.g., when that discrete part, portion, or section of structurally-reinforced wall is opened, fresh microscopy grids from outside of the vacuum chamber 304 can be passed through such opening and thereby delivered into the vacuum chamber 304, or old microscopy grids from inside the vacuum chamber 304 can be passed through such opening and thereby removed from the vacuum chamber 304). Conversely, that discrete part, portion, or section of structurally-reinforced wall can be closed by any suitable electric, pneumatic, hydraulic, or other mechanical actuators, thereby allowing the vacuum chamber 304 to be pumped down to any suitable vacuum pressure. In various aspects, such openable and closable discrete part, portion, or section of structurally-reinforced wall can be considered as the load-lock door 310.

In various instances, the load-lock door 310 can be considered as having an inner surface and an outer surface. In various cases, the inner surface can be whatever surface of the load-lock door 310 that faces inwards or is otherwise exposed to the interior of the vacuum chamber 304 when the load-lock door 310 is closed. In contrast, the outer surface can be whatever surface of the load-lock door 310 that faces outwards or is otherwise exposed to the exterior of the vacuum chamber 304 when the load-lock door 310 is closed. In various aspects, the microscopy grid receptacle 306 can be physically coupled, affixed, or otherwise attached to the inner surface of the load-lock door 310. In some instances, such physical coupling, affixation, or attachment can be facilitated via any suitable mechanical fasteners, such as bolts, screws, brackets, or even electrostatic magnets that physically hold the microscopy grid receptacle 306 to or against the inner surface of the load-lock door 310. In various cases, such mechanical fasteners can be physically adjustable by a technician, such that the technician can adjust or otherwise change where on or along the inner surface of the load-lock door 310 the microscopy grid receptacle 306 can be located or positioned (e.g., such that the technician can cause the microscopy grid receptacle 306 to be moved horizontally or vertically along the inner surface of the load-lock door 310). In various aspects, it can be the case that such mechanical fasteners can be physically adjusted by the technician only when the load-lock door 310 is open and not when the load-lock door 310 is closed. After all, if the load-lock door 310 is closed, such mechanical fasteners can be inside of the vacuum chamber 304, and the technician, who can be outside of the vacuum chamber 304, can be unable to physically reach or touch such mechanical fasteners.

In order to avoid damage to the charged-particle microscope 302, and in order to avoid damage to or contamination of any specimens that are to be scanned by the charged-particle microscope 302, the robotic gripper 308 can be taught how to angularly or translationally align a shaft protruding from any given microscopy grid with the bore of the microscopy grid receptacle 306. Such teaching can be facilitated via any suitable techniques, such as techniques that rely on cameras, borescopes, or lasers. In any case, such teaching can be considered as identifying what position or orientation of the robotic gripper 308 would cause a shaft protruding from a microscopy grid to be angularly and translationally aligned with the bore of the microscopy grid receptacle 306.

Now, during such teaching, the microscopy grid receptacle 306 can have some particular or specific location or position on or along the inner surface of the load-lock door 310. Sometimes, the microscopy grid receptacle 306 can be removed from the vacuum chamber 304 for maintenance or servicing and can, after such maintenance or servicing, be placed back in the vacuum chamber 304. In order to avoid having to reteach the robotic gripper 308, it can be desired to ensure that the microscopy grid receptacle 306 is precisely placed back at the particular or specific location or position on or along the inner surface of the load-lock door 310. In other words, it can be desired to ensure that, after such maintenance or servicing, the robotic gripper 308 still knows how to become angularly or translationally aligned with the microscopy grid receptacle 306. As described herein, a system 320 can facilitate such alignment, by leveraging various vacuum-simulation hardware 312.

In various embodiments, the vacuum-simulation hardware 312 can comprise an adjustable force applicator 314, a positioning mechanism 316, or a feedback sensor 318.

In various aspects, the adjustable force applicator 314 can be any suitable mechanical device that can controllably or selectively impart a compressive tactile force onto any suitable target object. As some non-limiting examples, the adjustable force applicator 314 can be or comprise any suitable mechanical press, piston, clamp, ram, or jack that can be electrically actuated, pneumatically actuated, or hydraulically actuated so as to push, compress, or otherwise load a target object. As other non-limiting examples, the adjustable force applicator 314 can be or comprise any suitable combination of any suitable linear or rotary actuators that can be electrically driven, pneumatically driven, or hydraulically driven so as to push or force a hardened or load-resistant element (e.g., a ball transfer unit) into a target object. In various instances, the adjustable force applicator 314 can have or otherwise be associated with a pressing input parameter. In various cases, the pressing input parameter can be whatever input that is receivable by the adjustable force applicator 314 and that selectively controls or dictates how intensely or how forcefully the adjustable force applicator 314 presses or pushes against a target object. As a non-limiting example, the pressing input parameter can be a positive, real-valued scalar whose value or magnitude can range between any suitable minimum value and any suitable maximum value. When the pressing input parameter is assigned or set to the minimum value, the adjustable force applicator 314 can press or push against a target object with whatever minimum amount of intensity or forcefulness that is achievable by the adjustable force applicator 314. Conversely, when the pressing input parameter is assigned or set to the maximum value, the adjustable force applicator 314 can press or push against a target object with whatever maximum amount of intensity or forcefulness that is achievable by the adjustable force applicator 314. Likewise, when the pressing input parameter is assigned or set to an intermediary value that is greater than the minimum value but less than the maximum value, the adjustable force applicator 314 can press or push against a target object with whatever intermediate amount of intensity or forcefulness that corresponds to (e.g., that is proportional to or commensurate with) the intermediate value. Accordingly, by selectively controlling or adjusting the pressing input parameter of the adjustable force applicator 314, the amount of intensity or forcefulness exhibited by the adjustable force applicator 314 can be selectively controlled or adjusted, hence the term “adjustable”.

Although the herein disclosure mainly describes the adjustable force applicator 314 in the singular sense, this is a mere non-limiting example for ease of explanation and illustration. It should be understood and appreciated that various embodiments described herein can comprise any suitable number of any suitable types of adjustable force applicators arranged in any suitable physical layout with respect to each other. In such cases, it should be understood that the pressing input parameter can exhibit greater dimensionality than a mere scalar. Indeed, in such cases, the pressing input parameter can be one or more scalars, one or more vectors, one or more matrices, one or more tensors, or any suitable combination thereof, depending upon how many or what types of adjustable force applicators are implemented.

In various aspects, the positioning mechanism 316 can be any suitable mechanical structure to which the adjustable force applicator 314 can be physically coupled and which can be kinematically actuatable so as to controllably or selectively move, transport, or otherwise reposition the adjustable force applicator 314 in space. As some non-limiting examples, the positioning mechanism 316 can be or comprise a kinematically actuatable truss, frame, or platform made up of any suitable numbers of struts, rods, beams, or plates that are movably coupled to each other via hinges, pins, stroke-limited slides, ball bearings, universal joints, meshed gear teeth (e.g., rack-and-pinion gears), or any other suitable types of mechanical joints, and that are drivable by any suitable electric, pneumatic, or hydraulic linear or rotational actuators. In such case, one end of such kinematically actuatable truss, frame, or platform can be affixed via any suitable mechanical fasteners to the outside of the vacuum chamber 304, and another end of such kinematically actuatable truss, frame, or platform can be affixed via any suitable mechanical fasteners to the adjustable force applicator 314. Accordingly, kinematic actuation of such truss, frame, or platform can cause the adjustable force applicator 314 to physically move or otherwise be repositioned with respect to the vacuum chamber 304. As another non-limiting example, the positioning mechanism 316 can be or comprise any suitable articulating or telescoping arms that can be driven by any suitable electric, pneumatic, or hydraulic linear or rotary actuators. In such case, one end of such articulating or telescoping arms can be affixed via any suitable mechanical fasteners to the outside of the vacuum chamber 304, and another end of such articulating or telescoping arms can be affixed via any suitable mechanical fasteners to the adjustable force applicator 314. Accordingly, kinematic actuation of such articulating or telescoping arms can cause the adjustable force applicator 314 to physically move or otherwise be repositioned with respect to the vacuum chamber 304.

In various aspects, the positioning mechanism 316 can be structurally configured or designed so as to move the adjustable force applicator 314 to a retracted position or instead to a deployed position. In various instances, the retracted position can cause the adjustable force applicator 314 to not be in physical or tactile contact with the load-lock door 310 (e.g., in some cases, can cause the adjustable force applicator 314 to not be in physical or tactile contact with any portion of the vacuum chamber 304). Accordingly, when in the retracted position, the adjustable force applicator 314 can be considered as being unable to apply or impart mechanical force onto the load-lock door 310. In contrast, the deployed position can cause the adjustable force applicator 314 to be in physical or tactile contact with the outer surface of the load-lock door 310. Accordingly, when in the deployed position, the adjustable force applicator 314 can be considered as being able to apply or impart mechanical force onto the outer surface of the load-lock door 310. In other words, when the adjustable force applicator 314 is in the deployed position, the outer surface of the load-lock door 310 can be considered as a target object against which the adjustable force applicator 314 can mechanically push or press.

In various instances, the feedback sensor 318 can be any suitable electronic, mechanical, or optical sensor that can measure any suitable kinematic-based information regarding the load-lock door 310 (e.g., that can measure position, deflection, deformation, displacement, or strain exhibited by the load-lock door 310) or that can measure any suitable kinetic-based information regarding the load-lock door 310 (e.g., that can measure force, pressure, or stress experienced by the load-lock door 310). As some non-limiting examples, the feedback sensor 318 can be or comprise any suitable force or pressure transducer, any suitable strain gauge, any suitable spring gauge, any suitable dial indicator, any suitable plunge indicator, any suitable caliper, any suitable chromatic confocal sensor, any suitable laser interferometer, any suitable eddy current sensor, any suitable capacitive sensor, any suitable coordinate measuring machine (CMM), or any suitable linear variable differential transformer (LVDT) sensor.

Although the herein disclosure mainly describes the feedback sensor 318 in the singular sense, this is a mere non-limiting example for ease of explanation and illustration. It should be understood and appreciated that various embodiments described herein can comprise any suitable number of any suitable types of feedback sensors arranged in any suitable physical layout with respect to each other. For example, an array of multiple feedback sensors can be implemented, with each feedback sensor in the array measuring a deflection, deformation, strain, force, pressure, or stress experienced by a respective portion or part of the load-lock door 310.

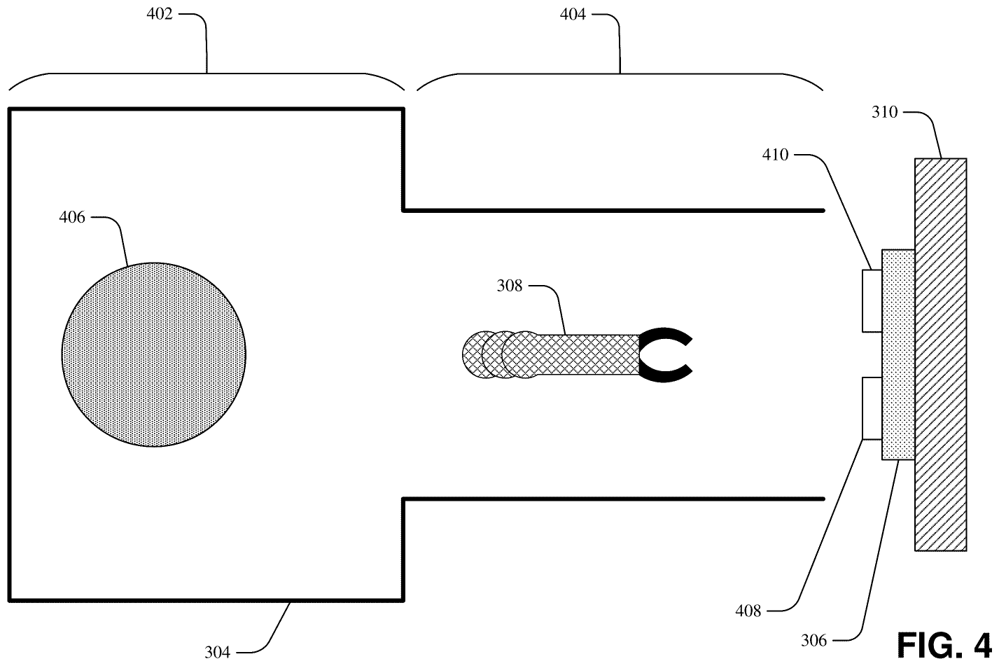

Non-limiting aspects of the charged-particle microscope 302 and of the vacuum-simulation hardware 312 are described with respect to FIGS. 4-9.

FIGS. 4-9 illustrate example, non-limiting block diagrams showing how the vacuum chamber 304 of the charged-particle microscope 302 can be outfitted with the vacuum-simulation hardware 312 in accordance with one or more embodiments described herein. It should be appreciated that FIGS. 4-9 are not necessarily drawn to scale.

First, consider FIG. 4. In various embodiments, as shown, the vacuum chamber 304 can be considered as comprising or otherwise being made up of a main portion 402 and a load-lock portion 404. In various aspects, an actuatable stage 406 of the charged-particle microscope 302 can be located or otherwise implemented within the main portion 402. Thus, the main portion 402 can be considered as being the primary area or site of the vacuum chamber 304 in which scanning of specimens is designed, intended, or otherwise configured to occur. In contrast to the main portion 402, the load-lock portion 404 can be considered as an anti-chamber that facilitates the delivery of new or fresh specimens into the vacuum chamber 304, as well as the removal of old or stale specimens from the vacuum chamber 304. In various instances, as shown, the robotic gripper 308 can be located or otherwise implemented within the load-lock portion 404. However, in other cases, the robotic gripper 308 can instead be located or otherwise implemented in the main portion 402 and can be able to reach or extend into the load-lock portion 404. It should be appreciated that FIG. 4 shows a mere conceptual depiction of the robotic gripper 308 for ease of illustration. Indeed, although FIG. 4 shows the robotic gripper 308 as being a telescoping arm equipped with a grasping claw, it should be understood that the robotic gripper 308 can exhibit any suitable level of mechanical complexity and can, as mentioned above, have any suitable degrees of kinematic freedom.

Now, as mentioned above, the load-lock door 310 can be an openable and closeable entrance or exit of the vacuum chamber 304. In the non-limiting example of FIG. 4, the load-lock door 310 is depicted as being an opened entrance or exit of the load-lock portion 404. As above, it should be appreciated that FIG. 4 shows a mere conceptual depiction of the load-lock door 310 for ease of illustration. Indeed, although FIG. 4 shows the load-lock door 310 as being a mere rectilinear block, it should be understood that the load-lock door 310 can be any suitable openable and closeable structure, portal, or hatch in the vacuum chamber 304 having any suitable shape or size and exhibiting any suitable level of structural complexity.

In various instances, as mentioned above, the microscopy grid receptacle 306 can be physically affixed (e.g., via any suitable adjustable mechanical fasteners) to the inner surface of the load-lock door 310. As above, it should be appreciated that FIG. 4 shows a mere conceptual depiction of the microscopy grid receptacle 306 for ease of illustration. Indeed, although FIG. 4 shows the microscopy grid receptacle 306 as being a mere rectilinear block, it should be understood that the microscopy grid receptacle 306 can be any suitable static or stationary structure of any suitable shape or size and exhibiting any suitable level of structural complexity.

Note that, in the non-limiting example of FIG. 4, since the load-lock door 310 is opened, the vacuum chamber 304 can be considered as being in a vented state. In other words, the interior of the vacuum chamber 304 can be not devoid or evacuated of air (e.g., can be at atmospheric pressure), due to the load-lock door 310 currently being open.

Now, in the non-limiting example of FIG. 4, the microscopy grid receptacle 306 is supporting, carrying, or holding two microscopy grids: a microscopy grid 408, and a microscopy grid 410. Although not explicitly shown, it should be understood that any suitable specimens can be held or carried on the microscopy grid 408 or on the microscopy grid 410. Moreover, although FIG. 4 shows the microscopy grid receptacle 306 as holding or supporting two microscopy grids, this is a mere non-limiting example for ease of illustration. It should be understood and appreciated that, in various embodiments, the microscopy grid receptacle 306 can hold or support any suitable number of microscopy grids at any given time.

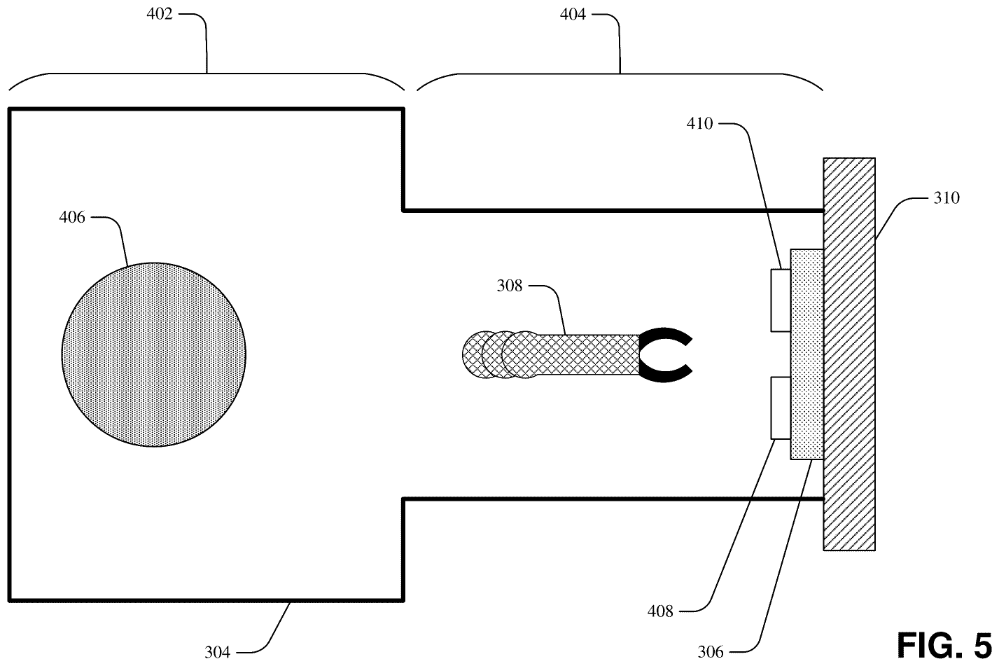

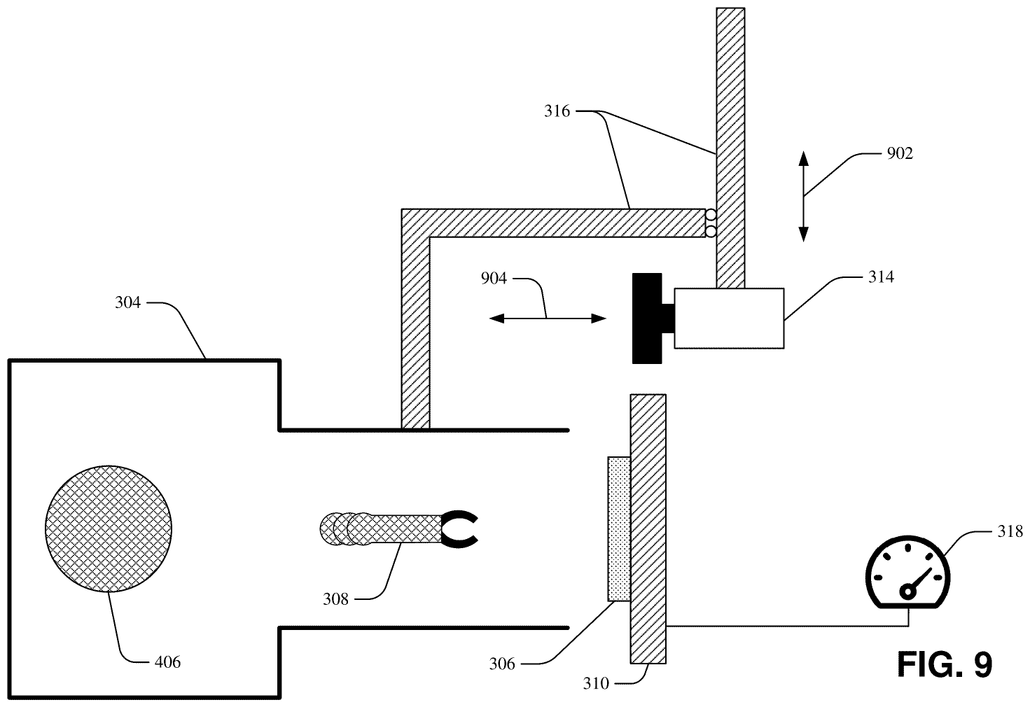

FIGS. 5-8 depict in non-limiting fashion some basic operations or functionalities that can be facilitated or performed by or within the vacuum chamber 304 (e.g., the robotic gripper 308 can physically grab a microscopy grid from the microscopy grid receptacle 306 and can transport it to the actuatable stage 406 for scanning). FIG. 9 depicts in non-limiting fashion how the vacuum chamber 304 can be outfitted or equipped with the vacuum-simulation hardware 312.

Consider FIG. 5. In various aspects, as shown, the load-lock door 310 can be closed. Such closing can be facilitated or performed via any suitable electric, pneumatic, or hydraulic linear or rotational actuators associated with or coupled to the load-lock door 310. Note that, although the load-lock door 310 is now closed, the vacuum chamber 304 can nevertheless still be in the vented state. In other words, the closing of the load-lock door 310 can have caused air or other gases to now be trapped within the vacuum chamber 304, such that the interior of the vacuum chamber 304 is still at atmospheric pressure.

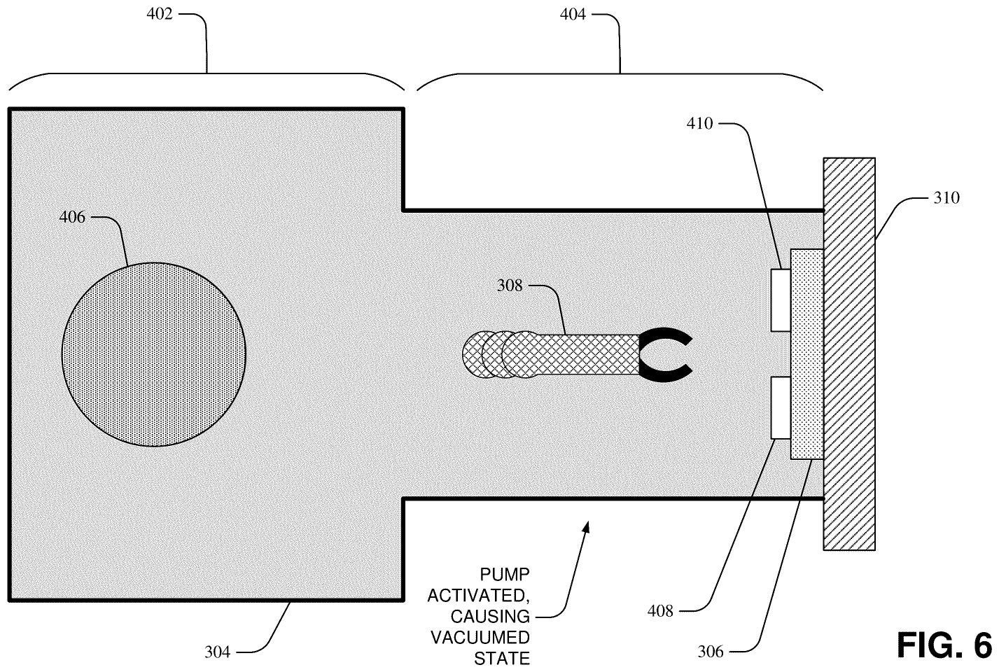

Next, consider FIG. 6. In various instances, as shown, the vacuum chamber 304 can be transitioned from the vented state to a vacuumed state. That is, the interior of the vacuum chamber 304 can be fully or partially vacated or evacuated of air or other gases, such that the interior of the vacuum chamber 304 is no longer at atmospheric pressure. Instead, the interior of the vacuum chamber 304 can now be at whatever negative operating pressure at which the charged-particle microscope 302 is configured or designed to scan specimens. In various cases, the vacuum chamber 304 can comprise any suitable number of any suitable types of vacuum pumps (not shown), and activation or engagement of such pumps can cause the vacuum chamber 304 to transition from the vented state to the vacuumed state.

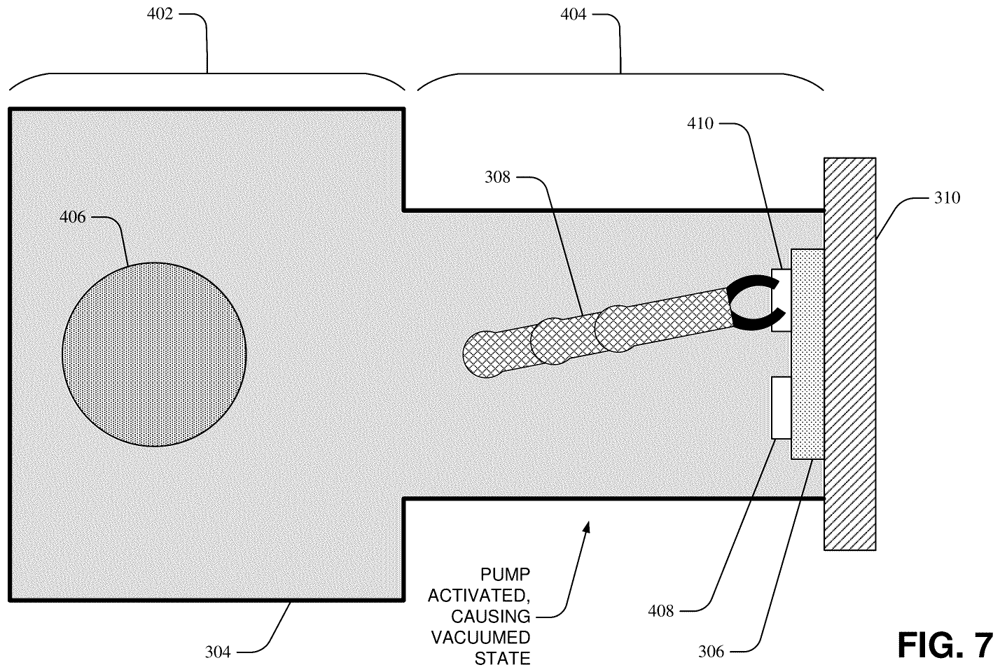

Now, consider FIG. 7. In various aspects, closing of the load-lock door 310 can cause the microscopy grid receptacle 306, and thus whatever microscopy grids it is holding or carrying, to be within reach of the robotic gripper 308. Accordingly, the microscopy grid 410 can (without loss of generality) be considered as being within reach of the robotic gripper 308. Thus, as shown, the robotic gripper 308 can physically grip, grab, or grasp the microscopy grid 410.

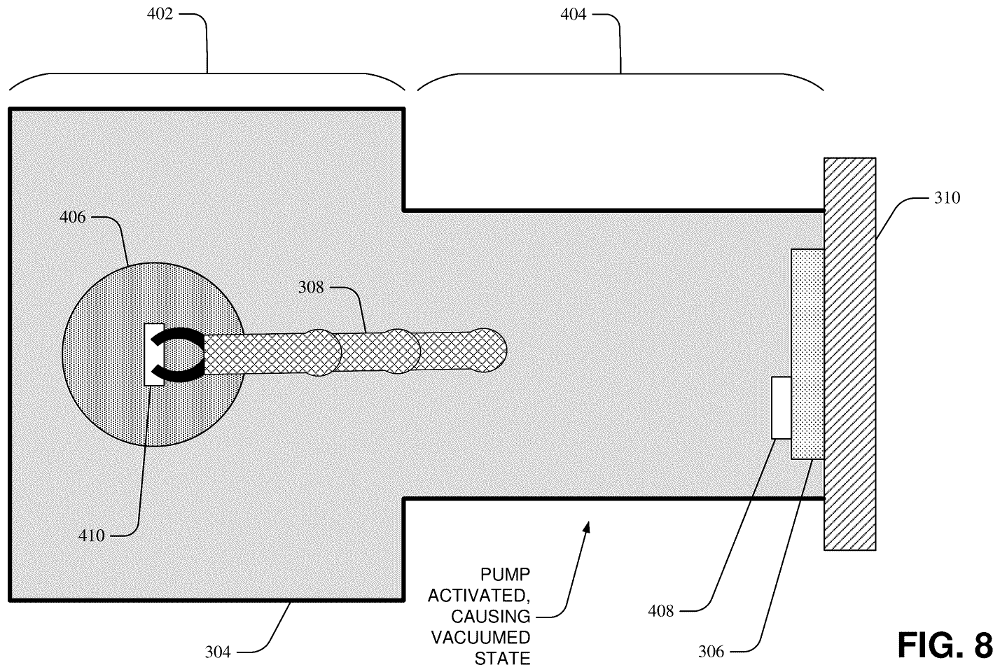

Next, consider FIG. 8. In various instances, as shown, the robotic gripper 308 can pull or otherwise remove the microscopy grid 410 from the microscopy grid receptacle 306, and the robotic gripper 308 can kinematically move, articulate, or telescope in space so as to transport the microscopy grid 410 to the actuatable stage 406. At such point, the robotic gripper 308 can release its grip or grasp of the microscopy grid 410, thereby placing, setting, or positioning the microscopy grid 410 on the actuatable stage 406. Thus, the microscopy grid 410 can be scanned by the charged-particle microscope 302.

Now, consider FIG. 9. As shown, FIG. 9 illustrates the vacuum chamber 304, the microscopy grid receptacle 306, the robotic gripper 308, the load-lock door 310, and the actuatable stage 406, as described above. In the non-limiting example of FIG. 9, the load-lock door 310 is opened, and the vacuum chamber 304 is in the vented state.

In various aspects, as shown, the positioning mechanism 316 can be physically coupled to both the adjustable force applicator 314 and to the exterior of the vacuum chamber 304. It should be appreciated that FIG. 9 shows mere conceptual depictions of the adjustable force applicator 314 and the positioning mechanism 316. Indeed, although FIG. 9 shows the adjustable force applicator 314 as being an actuatable piston, press, or jack, it should be understood that the adjustable force applicator 314 can exhibit any suitable level of mechanical, electrical, pneumatic, or hydraulic complexity. In any case, the adjustable force applicator 314 can extend (e.g., and thus more intensely or forcefully push or press a target object) or contract (e.g., and thus less intensely or forcefully push or press a target object) along a direction indicated by numeral 904. Likewise, although FIG. 9 shows the positioning mechanism 316 as being two dynamically or slidably coupled beams, it should be understood that the positioning mechanism 316 can exhibit any suitable level of mechanical, electrical, pneumatic, or hydraulic complexity. In particular, the non-limiting example of FIG. 9 shows the positioning mechanism 316 as being made up of a straight beam and an L-shaped beam that are dynamically or movably coupled together by a roller or rack-and-pinion joint. As shown, the straight beam can be physically affixed or fastened to the adjustable force applicator 314, and a non-roller or non-rack-and-pinion end of the L-shaped beam can be physically affixed or fastened to the exterior of the vacuum chamber 304. In such configuration, actuation of the positioning mechanism 316 can cause the straight beam, and thus the adjustable force applicator 314, to move upward or downward along a direction or axis denoted by numeral 902. In various cases, the positioning mechanism 316 can be considered as causing the adjustable force applicator 314 to be currently located in the retracted position, such that the adjustable force applicator 314 can (as shown) not be in physical contact with the load-lock door 310. In other words, in the non-limiting example of FIG. 9, the positioning mechanism 316 can be considered as achieving the retracted position by moving or transporting the adjustable force applicator 314 upward by a distance that is sufficient to cause the adjustable force applicator 314 to be at a different elevation than the load-lock door 310. In contrast, in the non-limiting example of FIG. 9, the positioning mechanism 316 could instead achieve the deployed position (after the load-lock door 310 is closed) by moving or transporting the adjustable force applicator 314 downward by a distance that is sufficient to cause the adjustable force applicator 314 to be at the same elevation as the load-lock door 310.

However, these are mere non-limiting examples for ease of illustration and explanation. It should be understood and appreciated that the positioning mechanism 316 can be configured or designed to move the adjustable force applicator 314 in any suitable direction, even in directions that are different from that indicated by numeral 902. In such situations, the retracted position (e.g., any position that causes the adjustable force applicator 314 to be unable to push or press against the outer surface of the load-lock door 310) may not be associated with upward movement or transportation of the adjustable force applicator 314. Similarly, in such situations, the deployed position (e.g., any position that causes the adjustable force applicator 314 to be able to push or press against the outer surface of the load-lock door 310) may not be associated with downward movement or transportation of the adjustable force applicator 314.

In any case, as shown, the feedback sensor 318 can be operatively or operably coupled (e.g., mechanically, electrically, optically, or hydraulically) to the load-lock door 310. Accordingly, the feedback sensor 318 can be able to measure, at any give time or instant, the deflection, deformation, displacement, force, pressure, stress, or strain exhibited by the load-lock door 310.

Referring back to FIG. 3, the system 320 can be electronically integrated, via any suitable wired or wireless electronic connections, with the charged-particle microscope 302 or with the vacuum-simulation hardware 312. In various cases, the system 320 can electronically facilitate consistent or repeatable positioning of the microscopy grid receptacle 306, by leveraging the vacuum-simulation hardware 312.

In various aspects, the system 320 can comprise a processor 322 (e.g., computer processing unit, microprocessor) and a non-transitory computer-readable memory 324 that is operably or operatively or communicatively connected or coupled to the processor 322. The non-transitory computer-readable memory 324 can store computer-executable instructions which, upon execution by the processor 322, can cause the processor 322 or other components of the system 320 (e.g., access component 326, reference component 328, simulation component 330, alignment component 332) to perform one or more acts. In various embodiments, the non-transitory computer-readable memory 324 can store computer-executable components (e.g., access component 326, reference component 328, simulation component 330, alignment component 332), and the processor 322 can execute the computer-executable components.

In various embodiments, the system 320 can comprise an access component 326. In various aspects, the access component 326 can electronically access the charged-particle microscope 302 or the vacuum-simulation hardware 312. That is, the access component 326 can electronically communicate or otherwise electronically interact with (e.g., transmit electronic instructions or commands to, receive electronic data from) the charged-particle microscope 302 (e.g., with the robotic gripper 308, with the actuators of the load-lock door 310) or with the vacuum-simulation hardware 312 (e.g., with the adjustable force applicator 314, with the positioning mechanism 316, with the feedback sensor 318). Accordingly, the access component 326 can be considered as a proxy or conduit through which other components of the system 320 can interact with, communicate with, or otherwise manipulate the charged-particle microscope 302 or the vacuum-simulation hardware 312.

In various embodiments, the system 320 can comprise a reference component 328. In various aspects, the reference component 328 can, as described herein, capture a reference feedback signal of the load-lock door 310 that is measured by the feedback sensor 318 and that is associated with the vacuum chamber 304 being in the vacuumed state.

In various embodiments, the system 320 can comprise a simulation component 330. In various instances, the simulation component 330 can, as described herein, identify a pressing input parameter value that recreates the reference feedback signal when the vacuum chamber 304 is in the vented state.

In various embodiments, the system 320 can comprise an alignment component 332. In various cases, the alignment component 332 can, as described herein, facilitate or perform a vacuum-less alignment procedure on or with respect to the microscopy grid receptacle 306, by leveraging the vacuum-simulation hardware 312 and the identified pressing input parameter value.

Note that, in various instances, the access component 326, the reference component 328, the simulation component 330, and the alignment component 332 can collectively be considered as being one or more software components 325 of the system 320. In various aspects, it should be appreciated that the one or more software components 325 are described primarily herein as comprising four components (e.g., the access component 326, the reference component 328, the simulation component 330, and the alignment component 332) for ease of explanation and illustration. However, the one or more software components 325 are not limited to being implemented as exactly such four components in every embodiment. Indeed, in some embodiments, the functionalities described herein of such four components can be combined in any suitable fashions, so as to be implemented in or by fewer than four components (e.g., in some cases, a single component can perform all of the functionalities that are described herein with respect to the access component 326, the reference component 328, the simulation component 330, and the alignment component 332). In other embodiments, the functionalities described herein of such four components can instead be distributed, separated, split, or fragmented in any suitable fashions, so as to be implemented in or by more than four components (e.g., two or more components can facilitate the functionalities that are performable by the access component 326; two or more components can facilitate the functionalities that are performable by the reference component 328; two or more components can facilitate the functionalities that are performable by the simulation component 330; two or more components can facilitate the functionalities that are performable by the alignment component 332).

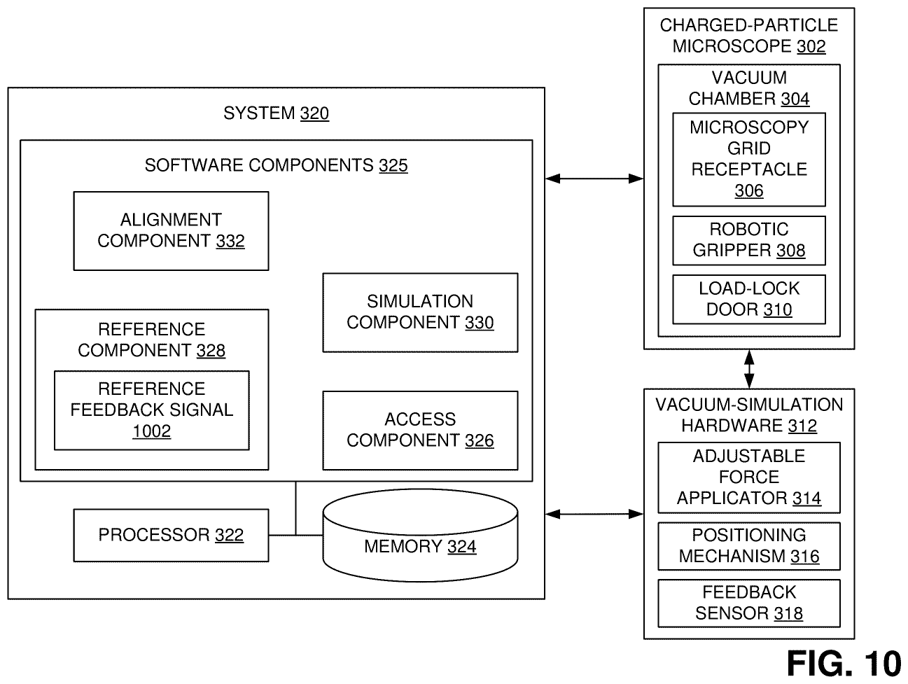

FIG. 10 illustrates a block diagram of an example, non-limiting system including a reference feedback signal that can facilitate vacuum simulation for charged-particle microscopy grid receptacles in accordance with one or more embodiments described herein.

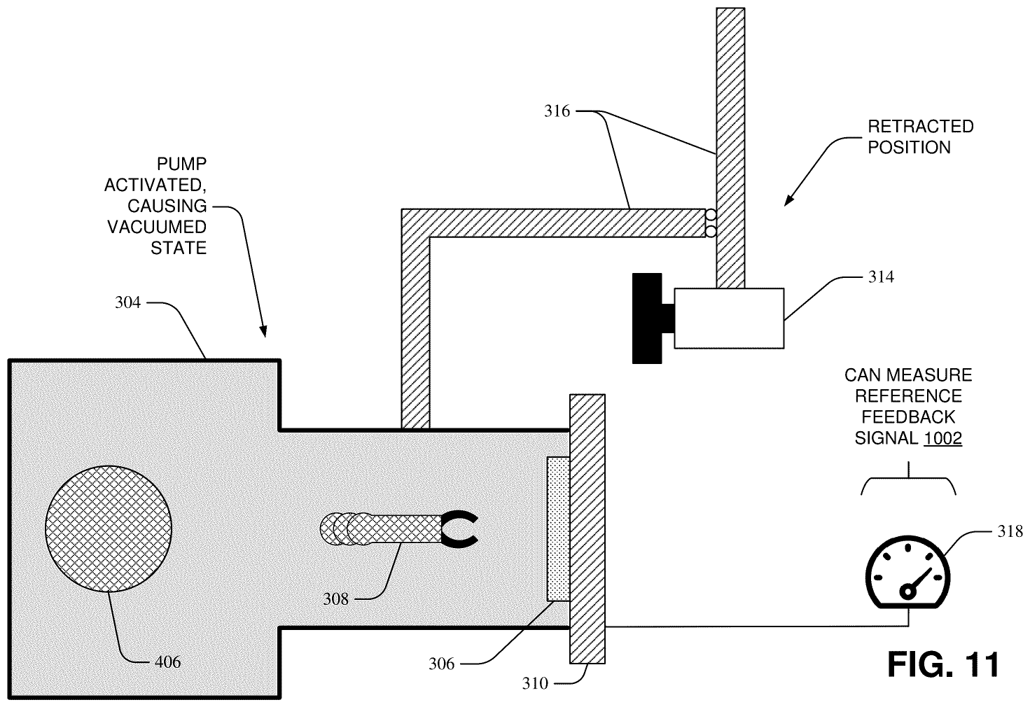

In various embodiments, the reference component 328 can electronically identify or otherwise electronically obtain a reference feedback signal 1002. In various aspects, the reference component 328 can facilitate such identification, by leveraging the vacuum-simulation hardware 312. Non-limiting aspects are described with respect to FIG. 11.

FIG. 11 illustrates an example, non-limiting block diagram showing how the reference feedback signal 1002 can be obtained or identified in accordance with one or more embodiments described herein.

In various aspects (such as shown in FIG. 9), the load-lock door 310 can be initially open, the vacuum chamber 304 can be initially in the vented state, and the positioning mechanism 316 can cause the adjustable force applicator 314 to be initially in the retracted position. Now, in various instances, the reference component 328 can electronically command, electronically instruct, or otherwise electronically cause the load-lock door 310 to be closed, and can electronically command, electronically instruct, or otherwise electronically cause the vacuum chamber 304 to transition from the vented state to the vacuumed state. In various cases, because the vacuum chamber 304 can be in the vacuumed state, the load-lock door 310 can be considered as experiencing a pressure differential. After all, the exterior of the vacuum chamber 304 can be at atmospheric pressure, whereas the interior of the vacuum chamber 304 can instead be at negative operating pressure. In other words, the atmospheric pressure can be considered as pushing inwards against the outer surface of the load-lock door 310, and the negative operating pressure can be considered as pulling inwards on the inner surface of the load-lock door 310. This pressure differential can cause the load-lock door 310 to deform, deflect, bend, or bow inwards by a non-zero amount (e.g., by tens or even hundreds of micrometers). In other words, such inwards deformation, deflection, bending, or bowing of the load-lock door 310 can be considered as being caused or induced by the vacuumed state of the vacuum chamber 304. For ease of explanation, such inwards deformation, deflection, bending, or bowing can be referred to as vacuum-induced deflection.

Now, in various aspects, the reference feedback signal 1002 can be whatever electronic data is measured by the feedback sensor 318 when the load-lock door 310 is experiencing the vacuum-induced deflection. Thus, in situations where the feedback sensor 318 measures kinematic or positional information, the reference feedback signal 1002 can be whatever measured displacement, deformation, or deflection that the load-lock door 310 undergoes due to the vacuumed state. In contrast, in situations where the feedback sensor 318 measures kinetic or force-based information, the reference feedback signal 1002 can instead be whatever measured force, pressure, or stress that the load-lock door 310 undergoes due to the vacuumed state. No matter the specific units of measurement employed by the feedback sensor 318, the reference feedback signal 1002 can be considered as indicating or quantifying how the load-lock door 310 physically responds to the vacuumed state, and the reference component 328 can electronically identify or obtain the reference feedback signal 1002 by reading the feedback sensor 318 when the vacuum chamber 304 is in the vacuumed state and the adjustable force applicator 314 is in the retracted position.

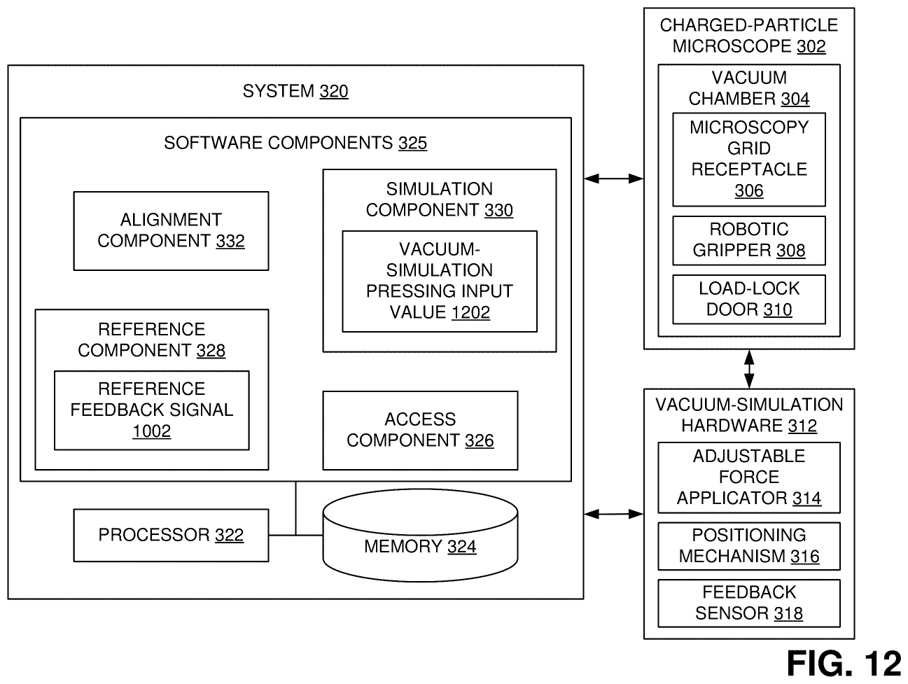

FIG. 12 illustrates a block diagram of an example, non-limiting system including a vacuum-simulation pressing input value that can facilitate vacuum simulation for charged-particle microscopy grid receptacles in accordance with one or more embodiments described herein.

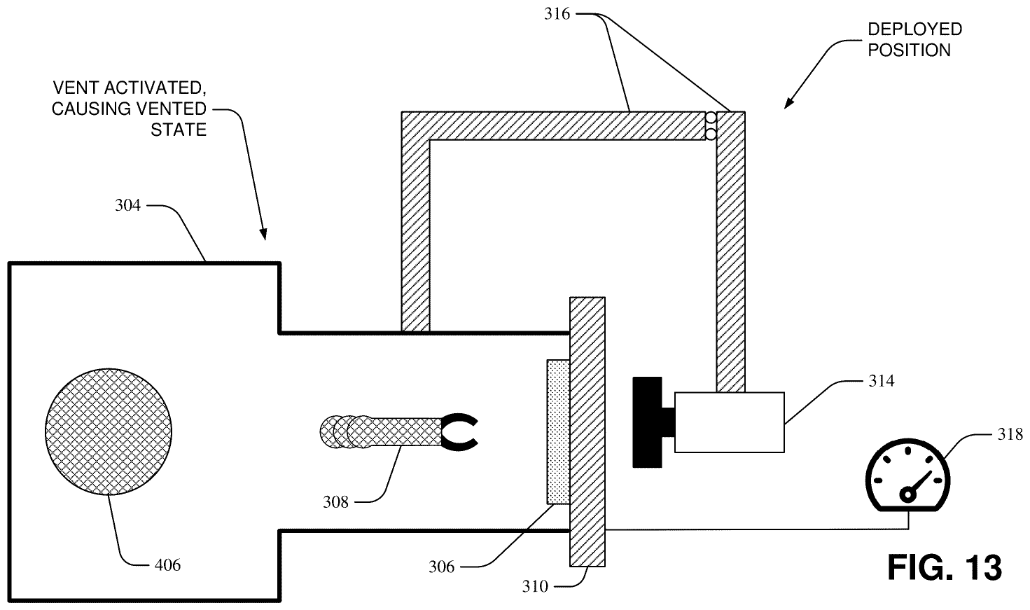

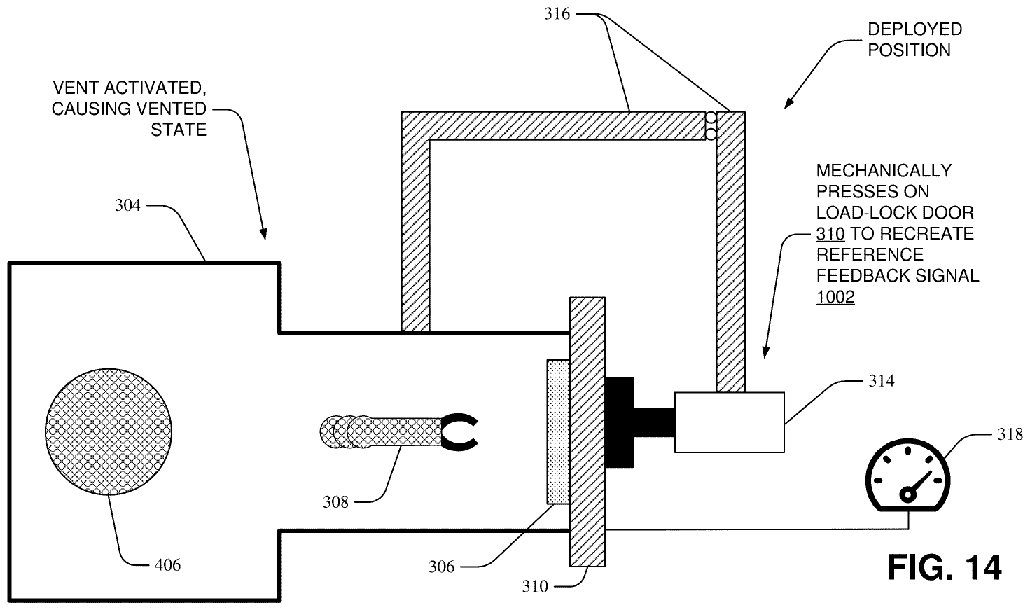

In various embodiments, the simulation component 330 can electronically identify or otherwise electronically obtain a vacuum-simulation pressing input value 1202. In various aspects, the simulation component 330 can facilitate such identification, by leveraging the vacuum-simulation hardware 312 and the reference feedback signal 1002. Non-limiting aspects are described with respect to FIGS. 13-14.

FIGS. 13-14 illustrate example, non-limiting block diagrams showing how the vacuum-simulation pressing input value 1202 can be obtained in accordance with one or more embodiments described herein.

First, consider FIG. 13. As explained above with respect to FIG. 11, the load-lock door 310 can be currently or presently closed, the vacuum chamber 304 can be currently or presently in the vacuumed state, and the positioning mechanism 316 can cause the adjustable force applicator 314 to be currently or presently in the retracted position. Now, in response to identification of the reference feedback signal 1002, the simulation component 330 can electronically command, electronically instruct, or otherwise electronically cause the vacuum chamber 304 to transition from the vacuumed state to the vented state. In various instances, the simulation component can accomplish this transition by deactivating the vacuum pumps of the vacuum chamber 304 and by activating or opening any suitable vents (not shown) of the vacuum chamber 304. In any case, the vacuum chamber 304 can now be in the vented state, such that the load-lock door 310 is no longer experiencing the vacuum-induced deflection. In various aspects, as shown, the load-lock door 310 can remain closed, and the simulation component 330 can electronically command, electronically instruct, or otherwise electronically cause the positioning mechanism 316 to move or transport the adjustable force applicator 314 to the deployed position. Accordingly, as shown, the adjustable force applicator 314 can now be within reach of (or can even be physically touching or contacting) the outer surface of the load-lock door 310.

Next, consider FIG. 14. In various embodiments, the simulation component 330 can electronically cause the adjustable force applicator 314 to mechanically press against the outer surface of the load-lock door 310 according to various different values of the pressing input parameter, and the simulation component 330 can electronically read the feedback sensor 318 for each of those different pressing input parameter values. In various cases, whichever pressing input parameter value causes the adjustable force applicator 314 to recreate the reference feedback signal 1002 can be considered or referred to as the vacuum-simulation pressing input value 1202. In some cases, the simulation component 330 can identify the vacuum-simulation pressing input value 1202 by sweeping the adjustable force applicator 314 through a range of pressing input values.

As a non-limiting example, the simulation component 330 can initialize the pressing input parameter at some minimum value. The simulation component 330 can then engage or activate the adjustable force applicator 314, thereby causing the adjustable force applicator 314 to mechanically press against the outer surface of the load-lock door 310 with whatever amount of intensity or forcefulness corresponds to the current value of the pressing input parameter. Such mechanical pressing can cause the load-lock door 310 to deform, deflect, bend, or bow inwards by some non-zero amount. In various cases, the simulation component 330 can read the feedback sensor 318 and can compare such reading to the reference feedback signal 1002. If that reading is within any suitable threshold margin of the reference feedback signal 1002, the current value of the pressing input parameter can be considered as simulating the vacuumed state of the vacuum chamber 304 (e.g., can be considered as causing the adjustable force applicator 314 to push against the load-lock door 310 such that the load-lock door 310 experiences the same deflection or force that it experienced due to the vacuumed state). Thus, the current value of the pressing input parameter can be considered or treated as the vacuum-simulation pressing input value 1202. In contrast, if that reading is not within any suitable threshold margin of the reference feedback signal 1002, the simulation component 330 can increment the current value of the pressing input parameter by any suitable amount (e.g., by 1 Newton, by 1%, by 1 pound-force), can cause the adjustable force applicator 314 to press against the outer surface of the load-lock door 310 according to that new, updated, or incremented value, and can read whatever new measurement is returned by the feedback sensor 318. In various aspects, the simulation component 330 can repeat such actions, until a pressing input parameter value is found that recreates the reference feedback signal 1002, and such value can be considered or treated as the vacuum-simulation pressing input value 1202.

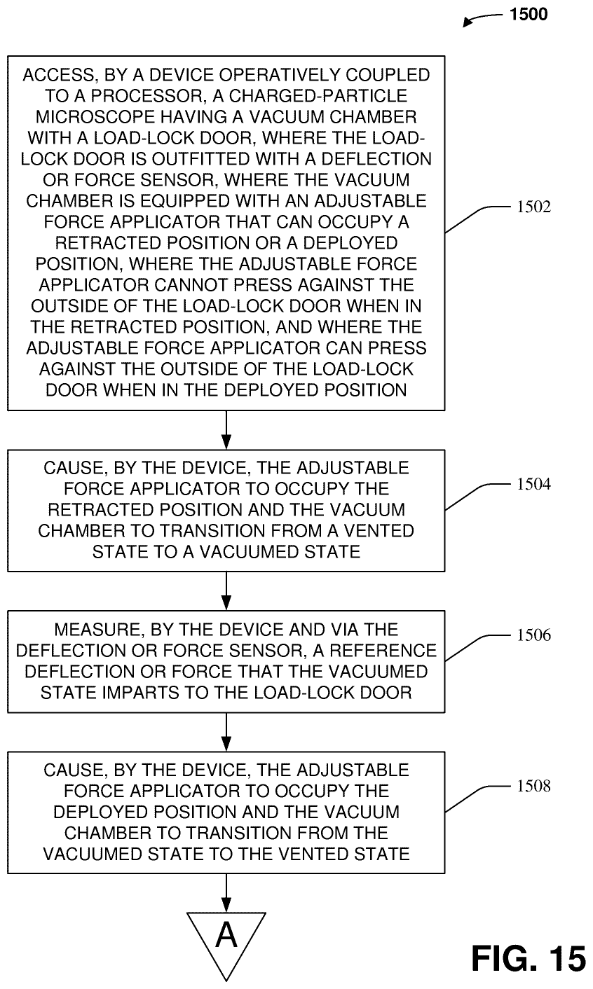

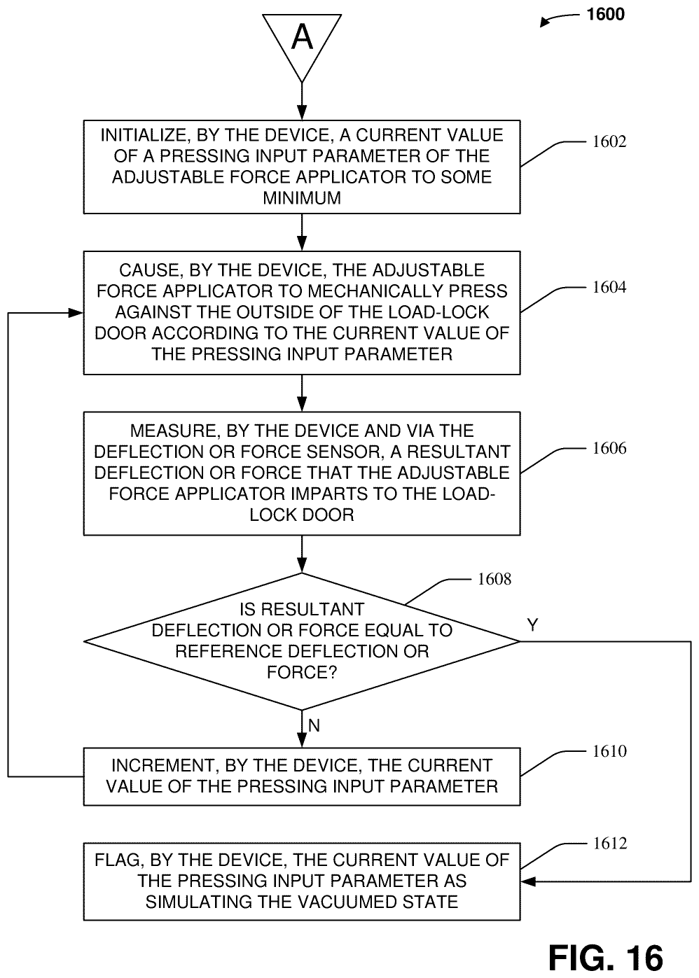

FIGS. 15-16 illustrate flow diagrams of example, non-limiting computer-implemented methods 1500 and 1600 for obtaining a reference feedback signal (e.g., 1002) and a vacuum-simulation pressing input value (e.g., 1202) in accordance with one or more embodiments described herein. In various cases, the system 320 can facilitate or perform the computer-implemented methods 1500 and 1600.

First, consider FIG. 15. In various embodiments, act 1502 can include accessing, by a device (e.g., via 326) operatively coupled to a processor (e.g., 322), a charged-particle microscope (e.g., 302) having a vacuum chamber (e.g., 304) with a load-lock door (e.g., 310). In various aspects, the load-lock door can be outfitted with a deflection or force sensor (e.g., 318). In various instances, the vacuum chamber can be equipped with an adjustable force applicator (e.g., 314) that can occupy a retracted position or a deployed position. In various cases, the adjustable force applicator cannot press against the outside of the load-lock door when in the retracted position. In various aspects, the adjustable force applicator can press against the outside of the load-lock door when in the deployed position.

In various instances, act 1504 can include causing, by the device (e.g., via 328), the adjustable force applicator to occupy the retracted position and the vacuum chamber to transition from a vented state to a vacuumed state.

In various cases, act 1506 can include measuring, by the device (e.g., via 328) and via the deflection or force sensor, a reference deflection or force (e.g., 1002) that the vacuumed state imparts to the load-lock door.

In various aspects, act 1508 can include causing, by the device (e.g., via 330), the adjustable force applicator to occupy the deployed position and the vacuum chamber to transition from the vacuumed state to the vented state. In various cases, the computer-implemented method 1500 can proceed to act 1602 of the computer-implemented method 1600.

Now, consider FIG. 16. In various embodiments, act 1602 can include initializing, by the device (e.g., via 330), a current value of a pressing input parameter of the adjustable force applicator to some minimum.

In various aspects, act 1604 can include causing, by the device (e.g., via 330), the adjustable force applicator to mechanically press against the outside of the load-lock door according to the current value of the pressing input parameter.

In various instances, act 1606 can include measuring, by the device (e.g., via 330) and via the deflection or force sensor, a resultant deflection or force that the adjustable force applicator imparts to the load-lock door.

In various cases, act 1608 can include determining, by the device (e.g., via 330), whether the resultant deflection or force is equal to (e.g., is within a threshold margin of) the reference deflection or force. If not, the computer-implemented method 1600 can proceed to act 1610. If so, the computer-implemented method 1600 can instead proceed to act 1612.

In various aspects, act 1610 can include incrementing, by the device (e.g., via 330), the current value of the pressing input parameter. The computer-implemented method 1600 can proceed back to act 1604.

In various instances, act 1612 can include flagging, by the device (e.g., via 330), the current value of the pressing input parameter as simulating the vacuumed state (e.g., marking the current value as 1202).

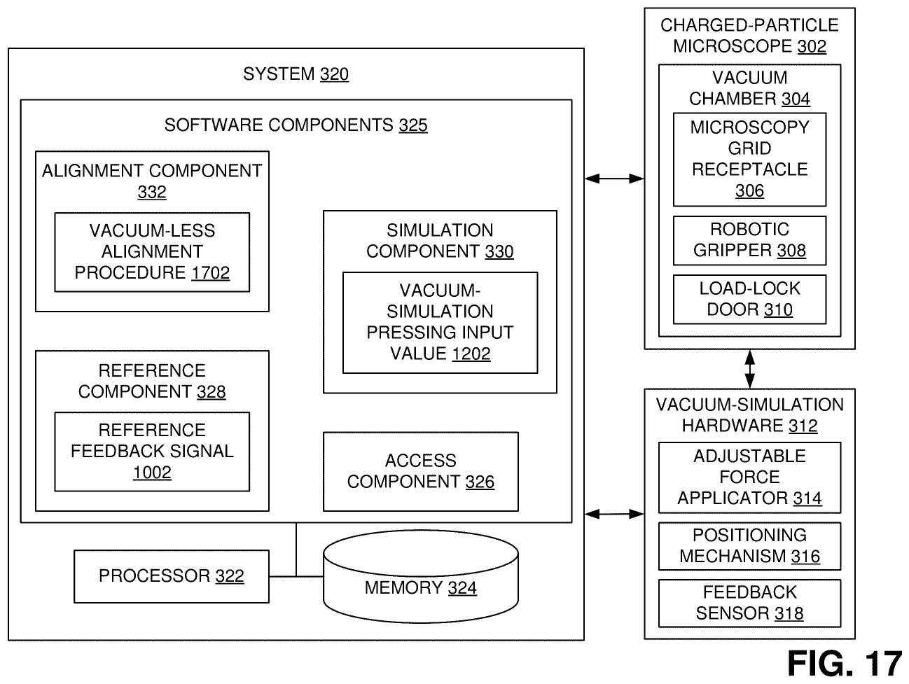

FIG. 17 illustrates a block diagram of an example, non-limiting system including a vacuum-less alignment procedure that can facilitate vacuum simulation for charged-particle microscopy grid receptacles in accordance with one or more embodiments described herein.

In various embodiments, the alignment component 332 can electronically perform, electronically conduct, or otherwise electronically facilitate a vacuum-less alignment procedure 1702 with respect to the microscopy grid receptacle 306, by leveraging the vacuum-simulation hardware 312 and the vacuum-simulation pressing input value 1202. In various cases, the vacuum-less alignment procedure 1702 can proceed as follows.

In various aspects, the alignment component 332 can electronically command, electronically instruct, or otherwise electronically cause: the vacuum chamber 304 to be in the vented state; the adjustable force applicator 314 to be in the retracted position; and the load-lock door 310 to be open. This can allow a technician associated with the charged-particle microscope 302 to coarsely place the microscopy grid receptacle 306 on the inner surface of the load-lock door 310 at whatever position the microscopy grid receptacle 306 occupied during training of the robotic gripper 308. In response to any suitable electronic or mechanical indication that the technician has completed positioning the microscopy grid receptacle 306 (e.g., the technician can press a designated electronic button of the charged-particle microscope 302 to signify such completion), the alignment component 332 can electronically command, electronically instruct, or otherwise electronically cause: the load-lock door 310 to close; the vacuum chamber 304 to remain or stay in the vented state (e.g., to not transition to the vacuumed state); and the adjustable force applicator 314 to move to the deployed position. In various aspects, the alignment component 332 can then cause the adjustable force applicator 314 to mechanically press against the outer surface of the load-lock door 310 with whatever intensity or forcefulness corresponds to the vacuum-simulation pressing input value 1202. Such mechanical pressing can cause the load-lock door 310 to deflect inwards, as if the vacuum chamber 304 were in the vacuumed state. Thus, such mechanical pressing can be considered as causing the microscopy grid receptacle 306 to be in whatever true position that it would occupy if the vacuum chamber 304 were in the vacuumed state, but such true position can be achieved without the time-consuming hassle of actually pumping the vacuum chamber 304 down to the vacuumed state. In various instances, the alignment component 332 can then electronically command, electronically instruct, or otherwise electronically cause the robotic gripper 308 to attempt to engage or interact with the microscopy grid receptacle 306 using whatever angularly and translationally aligned position or orientation that the robotic gripper 308 has been taught. During such attempted engagement or interaction, the technician can observe (e.g., via any suitable cameras, borescopes, or lasers) an alignment error exhibited by the robotic gripper 308. Alternatively, the alignment component 332 can automatically observe or measure such alignment error (e.g., via any suitable cameras, borescopes, or lasers). In response to observation of the alignment error (e.g., if manually observed, the technician can press a designated electronic button of the charged-particle microscope 302 to signify such completion), the alignment component 332 can electronically command, electronically instruct, or otherwise electronically cause: the adjustable force applicator 314 to move to the retracted position; the vacuum chamber 304 to remain in the vented state; and the load-lock door 310 to open. This can allow the technician to finely adjust the position of the microscopy grid receptacle 306 on the inner surface of the load-lock door 310 so as to reduce the observed alignment error. In various cases, the alignment component 332 can then repeat such actions for any suitable number of iterations or cycles (e.g., until the most recently observed alignment error is below any suitable threshold). In response to the most recently observed alignment error being satisfactorily low, the alignment component 332 can electronically generate or transmit an electronic notification or message indicating that the microscopy grid receptacle 306 is now aligned with the robotic gripper 308 (e.g., indicating that the microscopy grid receptacle 306 is now in the same position on the inner surface of the load-lock door 310 that it was in when the robotic gripper 308 was taught alignment).

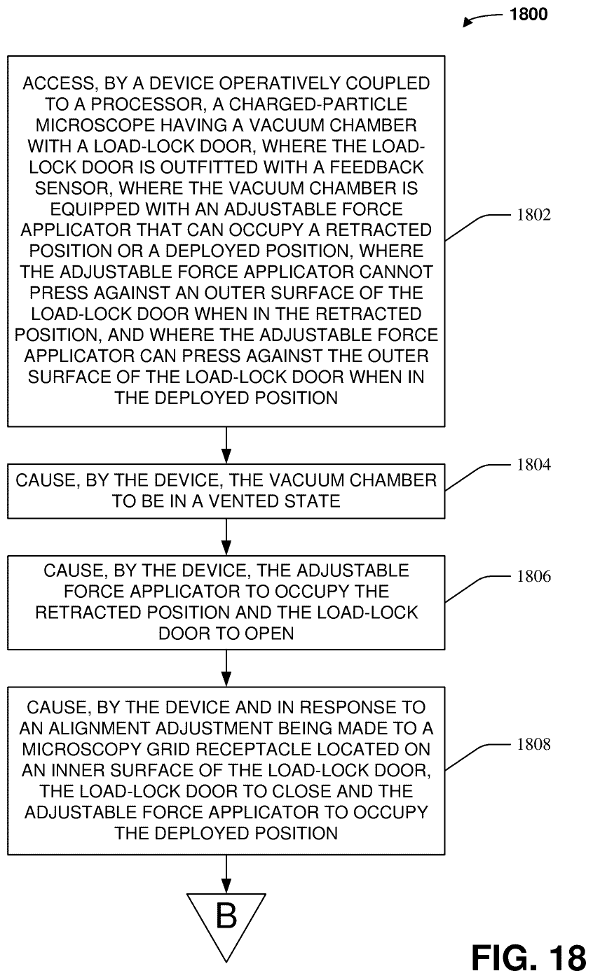

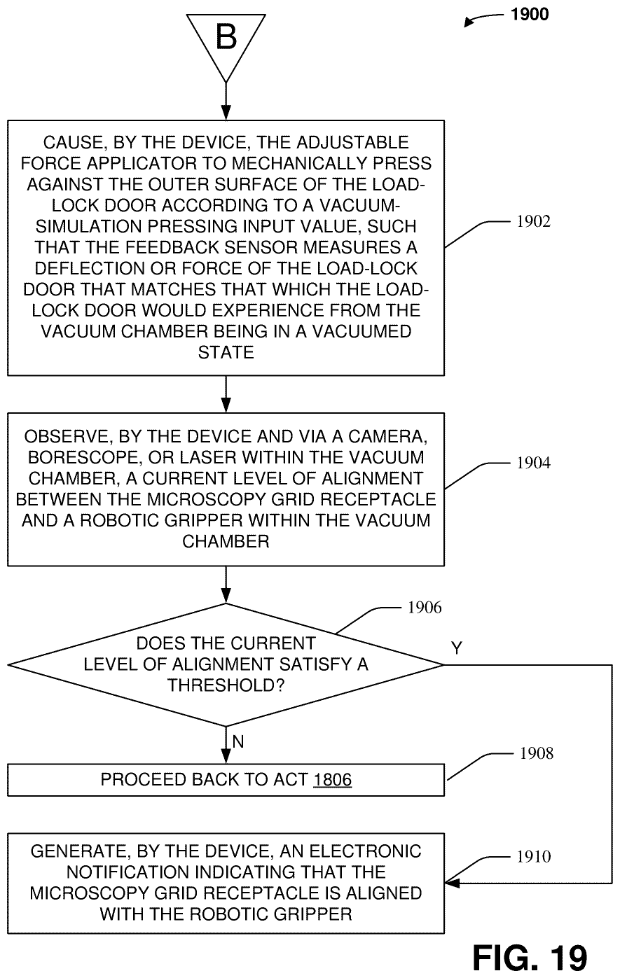

FIGS. 18-19 illustrate flow diagrams of example, non-limiting computer-implemented methods 1800 and 1900 that can facilitate a vacuum-less alignment procedure (e.g., 1702) in accordance with one or more embodiments described herein. In various cases, the system 320 can facilitate or perform the computer-implemented methods 1800 and 1900.

First, consider FIG. 18. In various embodiments, act 1802 can include accessing, by a device (e.g., via 326) operatively coupled to a processor (e.g., 322), a charged-particle microscope (e.g., 302) having a vacuum chamber (e.g., 304) with a load-lock door (e.g., 310). In various aspects, the load-lock door can be outfitted with a feedback sensor (e.g., 318). In various instances, the vacuum chamber can be equipped with an adjustable force applicator (e.g., 314) that can occupy a retracted position or a deployed position. In various cases, the adjustable force applicator cannot press against the outside of the load-lock door when in the retracted position. In various aspects, the adjustable force applicator can press against the outside of the load-lock door when in the deployed position.

In various aspects, act 1804 can include causing, by the device (e.g., via 332), the vacuum chamber to be in a vented state.

In various instances, act 1806 can include causing, by the device (e.g., via 332), the adjustable force applicator to occupy the retracted position and the load-lock door to open.

In various cases, act 1808 can include causing, by the device (e.g., via 332) and in response to an alignment adjustment being or having been made to a microscopy grid receptacle (e.g., 306) on an inner surface of the load-lock door, the load-lock door to close and the adjustable force applicator to occupy the deployed position. In various aspects, the computer-implemented method 1800 can proceed to act 1902 of the computer-implemented method 1900.

Now, consider FIG. 19. In various embodiments, act 1902 can include causing, by the device (e.g., via 332), the adjustable force applicator to mechanically press against the outer surface of the load-lock door according to a vacuum-simulation pressing input value (e.g., 1202), such that the feedback sensor measures a deflection or force of the load-lock door that matches (e.g., is within a threshold margin of) that which the load-lock door would experience from the vacuum chamber being in a vacuumed state (e.g., that matches 1002).

In various aspects, act 1904 can include observing, by the device (e.g., via 332) and via a camera, borescope, or laser within the vacuum chamber, a current level of alignment between the microscopy grid receptacle and a robotic gripper within the vacuum chamber.

In various instances, act 1906 can include determining, by the device (e.g., via 332), whether or not the current level of alignment satisfies a threshold. If not, the computer-implemented method 1900 can proceed to act 1908. If so, the computer-implemented method 1900 can instead proceed to act 1910.

In various cases, act 1908 can include proceeding, by the device (e.g., via 332), back to act 1806 of the computer-implemented method 1800.

In various aspects, act 1910 can include generating, by the device (e.g., via 332), an electronic notification indicating that the microscopy grid receptacle is aligned with the robotic gripper.

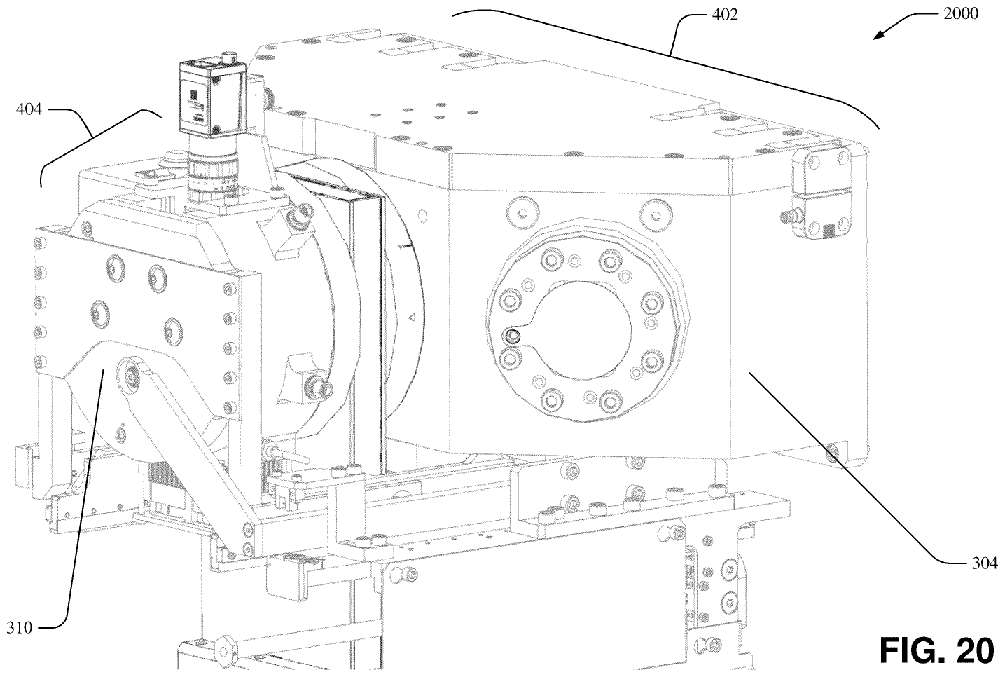

FIGS. 20-25 illustrate example, non-limiting images of various experimental reductions to practice in accordance with one or more embodiments described herein.

First, consider FIG. 20. FIG. 20 shows a computer-aided design drawing 2000 of the vacuum chamber 304. As shown, the computer-aided design drawing 2000 depicts a perspective view of a non-limiting exterior of the vacuum chamber 304. In other words, the computer-aided design drawing 2000 can be considered as showing or illustrating non-limiting example embodiments of the main portion 402, the load-lock portion 404, and the load-lock door 310.

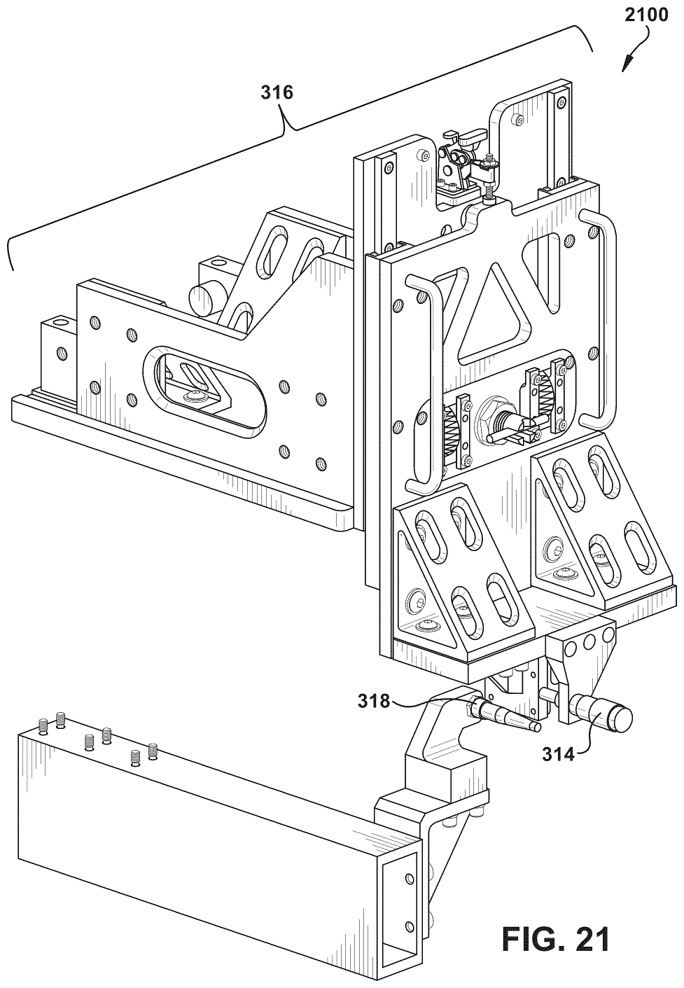

Next, consider FIG. 21. FIG. 21 shows a computer-aided design drawing 2100 of the vacuum-simulation hardware 312. In particular, the computer-aided design drawing 2100 can be considered as depicting or illustrating a perspective view of non-limiting example embodiments of the adjustable force applicator 314, the positioning mechanism 316, and the feedback sensor 318. Note that the computer-aided design drawing 2100 shows the adjustable force applicator 314 as being in the deployed position.

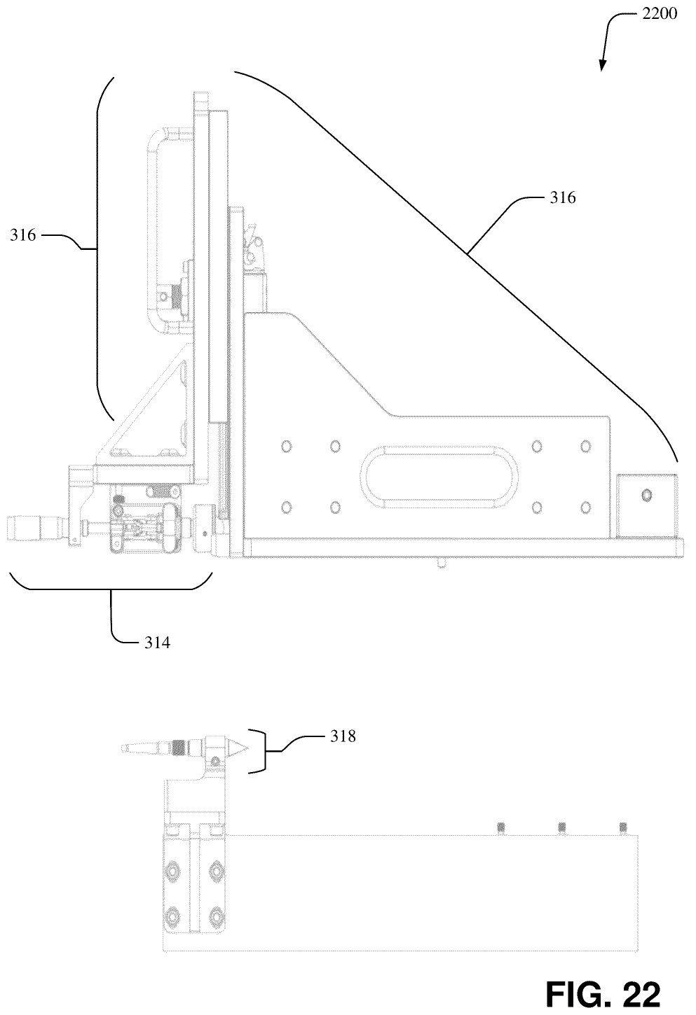

Now, consider FIG. 22. FIG. 22 shows a computer-aided design drawing 2200 of the vacuum-simulation hardware 312. In particular, the computer-aided design drawing 2200 can be considered as depicting or illustrating a profile view of non-limiting example embodiments of the adjustable force applicator 314, the positioning mechanism 316, and the feedback sensor 318. Note that the computer-aided design drawing 2200 shows the adjustable force applicator 314 as being in the retracted position.

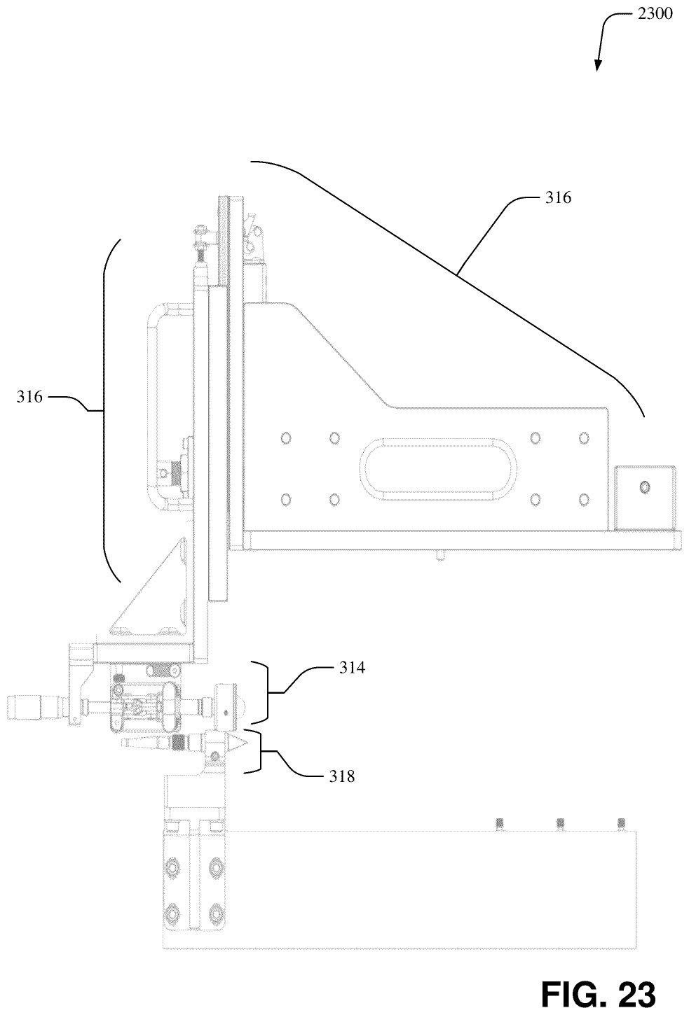

Consider FIG. 23. FIG. 23 shows a computer-aided design drawing 2300 of the vacuum-simulation hardware 312. In particular, like the computer-aided design drawing 2200, the computer-aided design drawing 2300 can be considered as depicting or illustrating a profile view of non-limiting example embodiments of the adjustable force applicator 314, the positioning mechanism 316, and the feedback sensor 318. However, unlike the computer-aided design drawing 2200, the computer-aided design drawing 2300 shows the adjustable force applicator 314 as being in the deployed position.

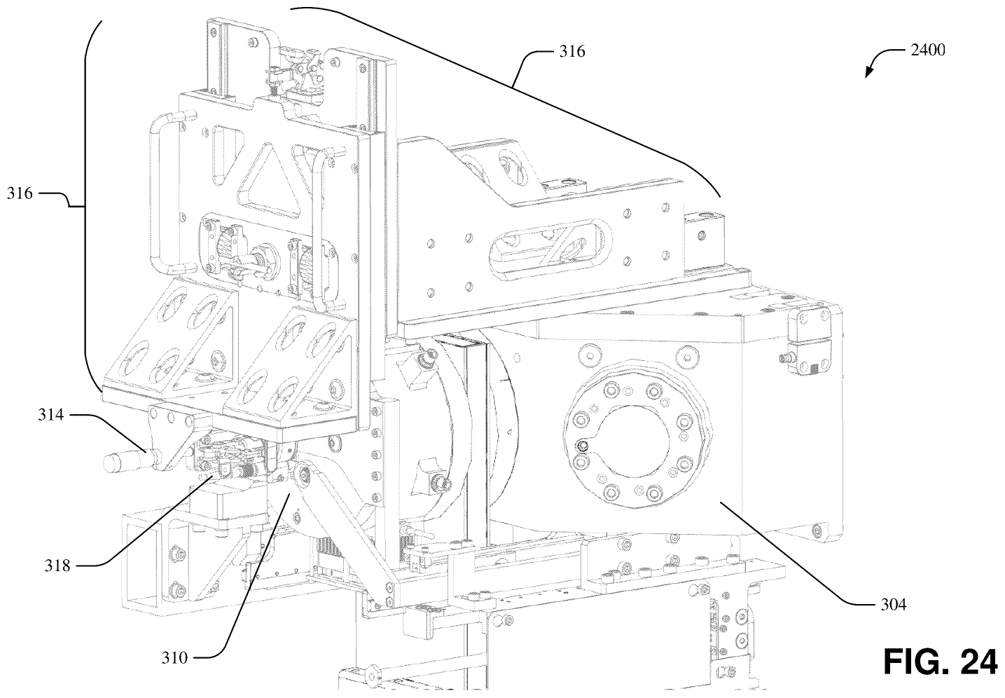

Next, consider FIG. 24. FIG. 24 shows a computer-aided design drawing 2400 of the vacuum chamber 304 outfitted or equipped with the vacuum-simulation hardware 312. Note that the computer-aided design drawing 2400 shows the adjustable force applicator 314 as being in the deployed position.

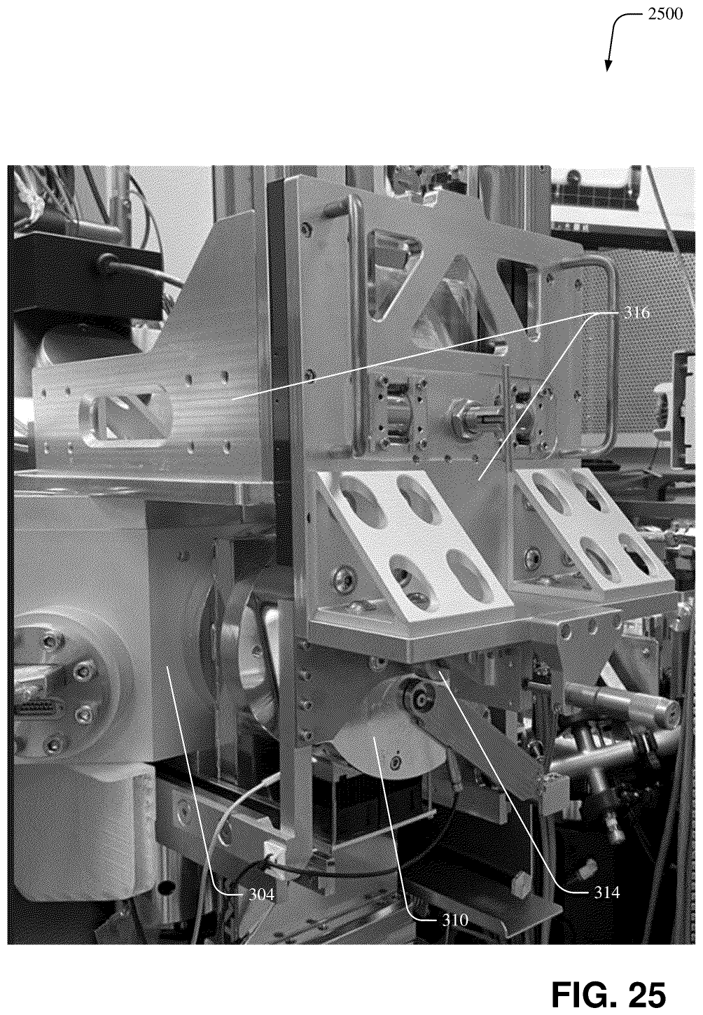

Lastly, consider FIG. 25. FIG. 25 shows a photograph 2500 of a prototype built by the present inventors in accordance with various embodiments described herein. As shown, the prototype includes the vacuum chamber 304, the load-lock door 310, the positioning mechanism 316, and the adjustable force applicator 314. For visual clarity, the photograph 2500 does not include the feedback sensor 318 (e.g., the feedback sensor 318 was temporarily removed before the photograph 2500 was captured). Note that the photograph 2500 shows the adjustable force applicator 314 as being in the deployed position.

Although the herein disclosure has mainly described various embodiments as simulating vacuum-induced deflection of load-lock doors of charged-particle microscopes, these are mere non-limiting examples for ease of explanation and illustration. It should be appreciated and understood that the teachings described herein can be extrapolated to simulate the operational deflections or deformations experienced by load-bearing components of any suitable scientific instruments (e.g., not limited just to simulating vacuumed states of charged-particle microscopes).

As a non-limiting example, consider any suitable scientific instrument (e.g., charged-particle microscope, mass spectrometer). Such scientific instrument can comprise any suitable constituent part or structure (e.g., 310) that bears a mechanical load during operation of the scientific instrument and that does not bear such mechanical load during idling of the scientific instrument (e.g., such constituent part or structure might not be a load-lock door of a vacuum chamber). Regardless of its specific identity, that constituent part or structure can be outfitted with the feedback sensor 318, and the adjustable force applicator 314 can be configured, positioned, or designed to mechanically load that constituent part or structure when in the deployed position and to not mechanically load that constituent part or structure when in the retracted position. In such cases, the reference feedback signal 1002 can be whatever kinematic-based (e.g., displacement) or kinetic-based (e.g., force) reading is measured by the feedback sensor 318 when the scientific instrument is in an operating state. Moreover, in such cases, the vacuum-simulation pressing input value 1202 can (when the scientific instrument is in the idle state, not the operating state) cause the adjustable force applicator 314 to mechanically load the constituent part or structure, such that the constituent part or structure experiences the same amount of deflection or force that it would experience due to the operating state. Accordingly, the vacuum-simulation pressing input value 1202 can instead be referred to as an operating-simulation pressing input value. Therefore, if an alignment procedure (or any other suitable type of procedure which requires that the constituent part or structure behave as if the scientific instrument were in the operating state or were in use) is desired to be performed on the constituent part or structure, such alignment procedure can be performed by simulating the operating state while the scientific instrument is actually or truly in the idle state. This can save time or reduce complexity.

The scientific instrument systems, methods, or techniques disclosed herein may include interactions with a human user (e.g., via a user local computing device 2820 discussed herein with reference to FIG. 28). These interactions may include providing information to the user (e.g., information regarding the operation of a scientific instrument such as the scientific instrument 2810 of FIG. 28, information regarding a sample being analyzed or other test or measurement performed by a scientific instrument, information retrieved from a local or remote database, or other information) or providing an option for a user to input commands (e.g., to control the operation of a scientific instrument such as the scientific instrument 2810 of FIG. 28, or to control the analysis of data generated by a scientific instrument), queries (e.g., to a local or remote database), or other information. In some embodiments, these interactions may be performed through a graphical user interface (GUI) that includes a visual display on a display device (e.g., a display device 2710 discussed herein with reference to FIG. 27) that provides outputs to the user and/or prompts the user to provide inputs (e.g., via one or more input devices, such as a keyboard, mouse, trackpad, or touchscreen, included in other I/O devices 2712 discussed herein with reference to FIG. 27). The scientific instrument systems, methods, or techniques disclosed herein may include any suitable GUls for interaction with a user.

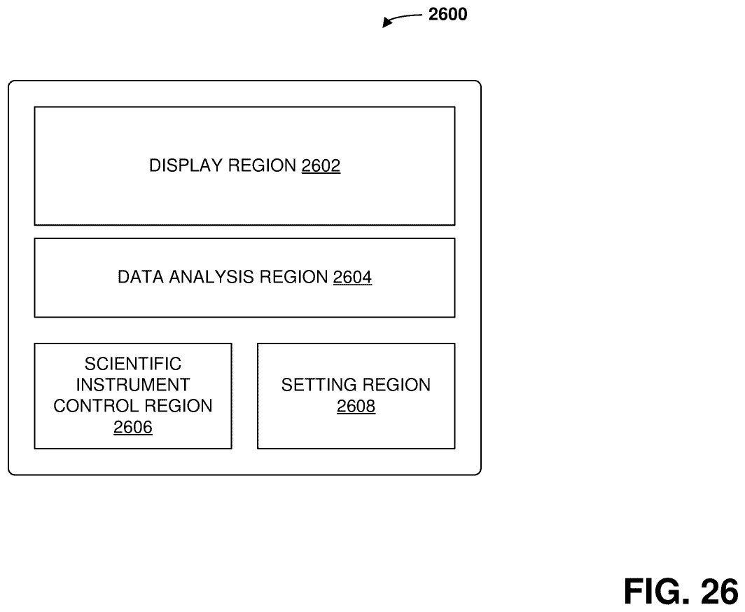

FIG. 26 depicts an example graphical user interface 2600 (hereafter “GUI 2600”) that can be used in the performance of some or all of the support methods or techniques disclosed herein, in accordance with various embodiments. In various aspects, the GUI 2600 can be provided on any suitable electronic display (e.g., a display device 2710 discussed herein with reference to FIG. 27) of a computing device (e.g., a computing device 2700 discussed herein with reference to FIG. 27) of a scientific instrument support system (e.g., a scientific instrument support system 2800 discussed herein with reference to FIG. 28), and a user or technician can interact with the GUI 2600 using any suitable input device (e.g., any of other I/O devices 2712 discussed herein with reference to FIG. 27) and input technique (e.g., movement of a cursor, motion capture, facial recognition, gesture detection, voice recognition, actuation of buttons).

The GUI 2600 can include a data display region 2602, a data analysis region 2604, a scientific instrument control region 2606, and a setting region 2608. The particular number and arrangement of regions depicted in FIG. 26 is merely illustrative, and any number and arrangement of regions, including any desired features, can be included in other embodiments of the GUI 2600.

The data display region 2602 can display data generated by a scientific instrument (e.g., a scientific instrument 2810 discussed herein with reference to FIG. 28).

The data analysis region 2604 can display any suitable data analysis results (e.g., the results of analyzing the data illustrated in the data display region 2602 or other data). In some embodiments, the data display region 2602 and the data analysis region 2604 can be combined in the GUI 2600 (e.g., to include both data output from a scientific instrument and some analysis of the data in a common graph or region).

The scientific instrument control region 2606 can include options that allow a user or technician to control a scientific instrument (e.g., the scientific instrument 2810 discussed herein with reference to FIG. 28). For example, the scientific instrument control region 2606 can include configurable parameters that govern operation of such scientific instrument (e.g., configurable parameters that govern voltages or electric currents of the scientific instrument, that govern interior temperatures of the scientific instrument, or that govern fluid flow rates of the scientific instrument).

The setting region 2608 can include options that allow a user or technician to control any features or functions of the GUI 2600 (or of other GUls) or to perform common computing operations with respect to the data display region 2602 and the data analysis region 2604 (e.g., saving data on a storage device, such as the storage device 2704 discussed herein with reference to FIG. 27, sending data to another user, labeling data).

As noted above, the scientific instrument module 102 can be implemented by one or more computing devices. FIG. 27 is a block diagram of a computing device 2700 that can perform some or all of the scientific instrument methods or techniques disclosed herein, in accordance with various embodiments. In some embodiments, the scientific instrument module 102 can be implemented by a single instance of the computing device 2700 or by multiple instances of the computing device 2700. Further, as discussed below, the computing device 2700 (or multiple instances thereof) that implements the scientific instrument module 102 can be part of one or more of a scientific instrument 2810, a user local computing device 2820, a service local computing device 2830, or a remote computing device 2840 of FIG. 28.

The computing device 2700 is illustrated as having a number of components, but any one or more of these components can be omitted or duplicated, as suitable for the application and setting. In some embodiments, some or all of the components included in the computing device 2700 can be attached to one or more motherboards and enclosed in a housing (e.g., including plastic, metal, or other materials). In some embodiments, some these components can be fabricated onto a single system-on-a-chip (SoC) (e.g., an SoC may include one or more instances of a processing device 2702 and one or more instances of a storage device 2704). Additionally, in various embodiments, the computing device 2700 can omit one or more of the components illustrated in FIG. 27, but can include interface circuitry (not shown) for coupling to the one or more omitted components using any suitable interface (e.g., a Universal Serial Bus (USB) interface, a High-Definition Multimedia Interface (HDMI) interface, a Controller Area Network (CAN) interface, a Serial Peripheral Interface (SPI) interface, an Ethernet interface, a wireless interface, or any other appropriate interface). For example, the computing device 2700 can omit a display device 2710, but can include display device interface circuitry (e.g., a connector and driver circuitry) to which a display device 2710 can be coupled.

The computing device 2700 can include a processing device 2702 (e.g., one or more processing devices). As used herein, the term “processing device” can refer to any device or portion of a device that processes electronic data from registers or memory to transform that electronic data into other electronic data that may be stored in registers or memories. The processing device 2702 can include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

The computing device 2700 can include a storage device 2704 (e.g., one or more storage devices). The storage device 2704 can include one or more memory devices such as random access memory (RAM) (e.g., static RAM (SRAM) devices, magnetic RAM (MRAM) devices, dynamic RAM (DRAM) devices, resistive RAM (RRAM) devices, or conductive-bridging RAM (CBRAM) devices), hard drive-based memory devices, solid-state memory devices, networked drives, cloud drives, or any combination of memory devices. In some embodiments, the storage device 2704 can include memory that shares a die with a processing device 2702. In such an embodiment, the memory may be used as cache memory and may include embedded dynamic random access memory (eDRAM) or spin transfer torque magnetic random access memory (STT-MRAM), for example. In some embodiments, the storage device 2704 can include non-transitory computer readable media having instructions thereon that, when executed by one or more processing devices (e.g., the processing device 2702), cause the computing device 2700 to perform any appropriate ones of or portions of the methods disclosed herein.

The computing device 2700 can include an interface device 2706 (e.g., one or more instances of the interface device 2706). The interface device 2706 can include one or more communication chips, connectors, or other hardware and software to govern communications between the computing device 2700 and other computing devices. For example, the interface device 2706 can include circuitry for managing wireless communications for the transfer of data to and from the computing device 2700. The term “wireless” and its derivatives may be used to describe circuits, devices, systems, methods, techniques, or communications channels that may communicate data through the use of modulated electromagnetic radiation through a nonsolid medium. The term does not imply that the associated devices do not contain any wires, although in some embodiments they might not. Circuitry included in the interface device 2706 for managing wireless communications may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”)). In some embodiments, circuitry included in the interface device 2706 for managing wireless communications can operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. In some embodiments, circuitry included in the interface device 2706 for managing wireless communications can operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). In some embodiments, circuitry included in the interface device 2706 for managing wireless communications may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. In some embodiments, the interface device 2706 may include one or more antennas (e.g., one or more antenna arrays) to receipt and/or transmission of wireless communications.

In some embodiments, the interface device 2706 can include circuitry for managing wired communications, such as electrical, optical, or any other suitable communication protocols. For example, the interface device 2706 can include circuitry to support communications in accordance with Ethernet technologies. In some embodiments, the interface device 2706 can support both wireless and wired communication, or can support multiple wired communication protocols or multiple wireless communication protocols. For example, a first set of circuitry of the interface device 2706 may be dedicated to shorter-range wireless communications such as Wi-Fi or Bluetooth, and a second set of circuitry of the interface device 2706 may be dedicated to longer-range wireless communications such as global positioning system (GPS), EDGE, GPRS, CDMA, WiMAX, LTE, EV-DO, or others. In some embodiments, a first set of circuitry of the interface device 2706 can be dedicated to wireless communications, and a second set of circuitry of the interface device 2706 can be dedicated to wired communications.

The computing device 2700 can include battery/power circuitry 2708. The battery/power circuitry 2708 can include one or more energy storage devices (e.g., batteries or capacitors) or circuitry for coupling components of the computing device 2700 to an energy source separate from the computing device 2700 (e.g., alternating current line power).

The computing device 2700 can include a display device 2710 (e.g., multiple display devices). The display device 2710 can include any visual indicators, such as a heads-up display, a computer monitor, a projector, a touchscreen display, a liquid crystal display (LCD), a light-emitting diode display, or a flat panel display.

The computing device 2700 can include other input/output (I/O) devices 2712. The other I/O devices 2712 can include one or more audio output devices (e.g., speakers, headsets, earbuds, alarms), one or more audio input devices (e.g., microphones or microphone arrays), location devices (e.g., GPS devices in communication with a satellite-based system to receive a location of the computing device 2700), audio codecs, video codecs, printers, sensors (e.g., thermocouples or other temperature sensors, humidity sensors, pressure sensors, vibration sensors, accelerometers, gyroscopes), image capture devices such as cameras, keyboards, cursor control devices such as a mouse, a stylus, a trackball, or a touchpad, bar code readers, Quick Response (QR) code readers, or radio frequency identification (RFID) readers, for example.

The computing device 2700 can have any suitable form factor for its application and setting, such as a handheld or mobile computing device (e.g., a cell phone, a smart phone, a mobile internet device, a tablet computer, a laptop computer, a netbook computer, an ultrabook computer, a personal digital assistant (PDA), an ultra mobile personal computer), a desktop computing device, or a server computing device or other networked computing component.

One or more computing devices implementing any of the scientific instrument modules, methods, or techniques disclosed herein may be part of a scientific instrument support system. FIG. 28 is a block diagram of an example scientific instrument support system 2800 in which some or all of the scientific instrument support methods disclosed herein may be performed, in accordance with various embodiments. The scientific instrument modules, methods, or techniques disclosed herein (e.g., the scientific instrument module 102; the computer-implemented method 200; the system 320; the computer-implemented methods 1500, 1600, 1800, and 1900) can be implemented by one or more of a scientific instrument 2810, a user local computing device 2820, a service local computing device 2830, or a remote computing device 2840 of the scientific instrument support system 2800.

Any of the scientific instrument 2810, the user local computing device 2820, the service local computing device 2830, or the remote computing device 2840 can include any of the embodiments of the computing device 2700, and any of the scientific instrument 2810, the user local computing device 2820, the service local computing device 2830, or the remote computing device 2840 can take the form of any appropriate ones of the embodiments of the computing device 2700.

The scientific instrument 2810, the user local computing device 2820, the service local computing device 2830, or the remote computing device 2840 may each include a processing device 2802, a storage device 2804, and an interface device 2806. The processing device 2802 may take any suitable form, including any form of the processing device 2702, and the processing devices 2802 included in different ones of the scientific instrument 2810, the user local computing device 2820, the service local computing device 2830, or the remote computing device 2840 may take the same form or different forms. The storage device 2804 may take any suitable form, including any form of the storage device 2704, and the storage devices 2804 included in different ones of the scientific instrument 2810, the user local computing device 2820, the service local computing device 2830, or the remote computing device 2840 may take the same form or different forms. The interface device 2806 may take any suitable form, including any form of the interface device 2706, and the interface devices 2806 included in different ones of the scientific instrument 2810, the user local computing device 2820, the service local computing device 2830, or the remote computing device 2840 may take the same form or different forms.

The scientific instrument 2810, the user local computing device 2820, the service local computing device 2830, and the remote computing device 2840 can be in communication with other elements of the scientific instrument support system 2800 via communication pathways 2808. The communication pathways 2808 may communicatively couple the interface devices 2806 of different ones of the elements of the scientific instrument support system 2800, as shown, and may be wired or wireless communication pathways (e.g., in accordance with any of the communication techniques discussed herein with reference to the interface device 2706). The particular scientific instrument support system 2800 depicted in FIG. 28 includes communication pathways between each pair of the scientific instrument 2810, the user local computing device 2820, the service local computing device 2830, and the remote computing device 2840, but this “fully connected” implementation is merely illustrative, and in various embodiments, various ones of the communication pathways 2808 may be absent. For example, in some embodiments, a service local computing device 2830 can lack a direct communication pathway 2808 between its interface device 2806 and the interface device 2806 of the scientific instrument 2810, but can instead communicate with the scientific instrument 2810 via the communication pathway 2808 between the service local computing device 2830 and the user local computing device 2820 and the communication pathway 2808 between the user local computing device 2820 and the scientific instrument 2810.

The scientific instrument 2810 may include any appropriate scientific instrument, such as the charged-particle microscope 302.

The user local computing device 2820 can be a computing device (e.g., in accordance with any of the embodiments of the computing device 2700) that is local to a user of the scientific instrument 2810. In some embodiments, the user local computing device 2820 may also be local to the scientific instrument 2810, but this need not be the case; for example, a user local computing device 2820 that is in a user's home or office may be remote from, but in communication with, the scientific instrument 2810 so that the user may use the user local computing device 2820 to control or access data from the scientific instrument 2810. In some embodiments, the user local computing device 2820 may be a laptop, smartphone, or tablet device. In some embodiments the user local computing device 2820 can be a portable computing device.

The service local computing device 2830 can be a computing device (e.g., in accordance with any of the embodiments of the computing device 2700) that is local to an entity that services the scientific instrument 2810. For example, the service local computing device 2830 may be local to a manufacturer of the scientific instrument 2810 or to a third-party service company. In some embodiments, the service local computing device 2830 can communicate with the scientific instrument 2810, the user local computing device 2820, or the remote computing device 2840 (e.g., via a direct communication pathway 2808 or via multiple “indirect” communication pathways 2808, as discussed above) to receive data regarding the operation of the scientific instrument 2810, the user local computing device 2820, or the remote computing device 2840 (e.g., the results of self-tests of the scientific instrument 2810, calibration coefficients used by the scientific instrument 2810, the measurements of sensors associated with the scientific instrument 2810). In some embodiments, the service local computing device 2830 may communicate with the scientific instrument 2810, the user local computing device 2820, or the remote computing device 2840 (e.g., via a direct communication pathway 2808 or via multiple “indirect” communication pathways 2808, as discussed above) to transmit data to the scientific instrument 2810, the user local computing device 2820, or the remote computing device 2840 (e.g., to update programmed instructions, such as firmware, in the scientific instrument 2810, to initiate the performance of test or calibration sequences in the scientific instrument 2810, to update programmed instructions, such as software, in the user local computing device 2820 or the remote computing device 2840). A user of the scientific instrument 2810 can utilize the scientific instrument 2810 or the user local computing device 2820 to communicate with the service local computing device 2830 to report a problem with the scientific instrument 2810 or the user local computing device 2820, to request a visit from a technician to improve the operation of the scientific instrument 2810, to order consumables or replacement parts associated with the scientific instrument 2810, or for other purposes.

The remote computing device 2840 can be a computing device (e.g., in accordance with any of the embodiments of the computing device 2700 discussed herein) that is remote from the scientific instrument 2810 or from the user local computing device 2820. In some embodiments, the remote computing device 2840 can be included in a datacenter or other large-scale server environment. In some embodiments, the remote computing device 2840 may include network-attached storage (e.g., as part of the storage device 2804). The remote computing device 2840 can store data generated by the scientific instrument 2810, perform analyses of the data generated by the scientific instrument 2810 (e.g., in accordance with programmed instructions), facilitate communication between the user local computing device 2820 and the scientific instrument 2810, or facilitate communication between the service local computing device 2830 and the scientific instrument 2810.

In some embodiments, one or more of the elements of the scientific instrument support system 2800 illustrated in FIG. 28 can be omitted. Further, in some embodiments, multiple ones of various ones of the elements of the scientific instrument support system 2800 of FIG. 28 may be present. For example, a scientific instrument support system 2800 can include multiple user local computing devices 2820 (e.g., different user local computing devices 2820 associated with different users or in different locations). In another example, a scientific instrument support system 2800 may include multiple scientific instruments 2810, all in communication with service local computing device 2830 and/or a remote computing device 2840; in such an embodiment, the service local computing device 2830 may monitor these multiple scientific instruments 2810, and the service local computing device 2830 may cause updates or other information may be “broadcast” to multiple scientific instruments 2810 at the same time. Different ones of the scientific instruments 2810 in a scientific instrument support system 2800 can be located close to one another (e.g., in the same room) or farther from one another (e.g., on different floors of a building, in different buildings, in different cities, etc.). In some embodiments, a scientific instrument 2810 can be connected to an Internet-of-Things (IoT) stack that allows for command and control of the scientific instrument 2810 through a web-based application, a virtual or augmented reality application, a mobile application, or a desktop application. Any of these applications can be accessed by a user operating the user local computing device 2820 in communication with the scientific instrument 2810 by the intervening remote computing device 2840. In some embodiments, a scientific instrument 2810 may be sold by the manufacturer along with one or more associated user local computing devices 2820 as part of a local scientific instrument computing unit 2812.

In some embodiments, different ones of the scientific instruments 2810 included in a scientific instrument support system 2800 may be different types of scientific instruments 2810; for example, one scientific instrument 2810 may be a mass spectrometer, while another scientific instrument 2810 may be a chromatograph or autosampler. In some such embodiments, the remote computing device 2840 or the user local computing device 2820 can combine data from different types of scientific instruments 2810 included in a scientific instrument support system 2800.

In various instances, machine learning algorithms or models can be implemented in any suitable way to facilitate any suitable aspects described herein. To facilitate some of the above-described machine learning aspects of various embodiments, consider the following discussion of artificial intelligence (AI). Various embodiments described herein can employ artificial intelligence to facilitate automating one or more features or functionalities. The components can employ various AI-based schemes for carrying out various embodiments/examples disclosed herein. In order to provide for or aid in the numerous determinations (e.g., determine, ascertain, infer, calculate, predict, prognose, estimate, derive, forecast, detect, compute) described herein, components described herein can examine the entirety or a subset of the data to which it is granted access and can provide for reasoning about or determine states of the system or environment from a set of observations as captured via events or data. Determinations can be employed to identify a specific context or action, or can generate a probability distribution over states, for example. The determinations can be probabilistic; that is, the computation of a probability distribution over states of interest based on a consideration of data and events. Determinations can also refer to techniques employed for composing higher-level events from a set of events or data.

Such determinations can result in the construction of new events or actions from a set of observed events or stored event data, whether or not the events are correlated in close temporal proximity, and whether the events and data come from one or several event and data sources. Components disclosed herein can employ various classification (explicitly trained (e.g., via training data) as well as implicitly trained (e.g., via observing behavior, preferences, historical information, receiving extrinsic information, and so on)) schemes or systems (e.g., support vector machines, neural networks, expert systems, Bayesian belief networks, fuzzy logic, data fusion engines, and so on) in connection with performing automatic or determined action in connection with the claimed subject matter. Thus, classification schemes or systems can be used to automatically learn and perform a number of functions, actions, or determinations.

A classifier can map an input attribute vector, z=(z₁, z₂, z₃, z₄, zₙ), to a confidence that the input belongs to a class, as by f(z)=confidence (class). Such classification can employ a probabilistic or statistical-based analysis (e.g., factoring into the analysis utilities and costs) to determinate an action to be automatically performed. A support vector machine (SVM) can be an example of a classifier that can be employed. The SVM operates by finding a hyper-surface in the space of possible inputs, where the hyper-surface attempts to split the triggering criteria from the non-triggering events. Intuitively, this makes the classification correct for testing data that is near, but not identical to training data. Other directed and undirected model classification approaches include, e.g., naïve Bayes, Bayesian networks, decision trees, neural networks, fuzzy logic models, or probabilistic classification models providing different patterns of independence, any of which can be employed. Classification as used herein also is inclusive of statistical regression that is utilized to develop models of priority.

In order to provide additional context for various embodiments described herein, FIG. 29 and the following discussion are intended to provide a brief, general description of a suitable computing environment 2900 in which the various embodiments of the embodiment described herein can be implemented. While the embodiments have been described above in the general context of computer-executable instructions that can run on one or more computers, those skilled in the art will recognize that the embodiments can be also implemented in combination with other program modules or as a combination of hardware and software.

Generally, program modules include routines, programs, components, data structures, etc., that perform particular tasks or implement particular abstract data types. Moreover, those skilled in the art will appreciate that the inventive methods can be practiced with other computer system configurations, including single-processor or multi-processor computer systems, minicomputers, mainframe computers, Internet of Things (IoT) devices, distributed computing systems, as well as personal computers, hand-held computing devices, microprocessor-based or programmable consumer electronics, and the like, each of which can be operatively coupled to one or more associated devices.

The illustrated embodiments of the embodiments herein can be also practiced in distributed computing environments where certain tasks are performed by remote processing devices that are linked through a communications network. In a distributed computing environment, program modules can be located in both local and remote memory storage devices.

Computing devices typically include a variety of media, which can include computer-readable storage media, machine-readable storage media, or communications media, which two terms are used herein differently from one another as follows. Computer-readable storage media or machine-readable storage media can be any available storage media that can be accessed by the computer and includes both volatile and nonvolatile media, removable and non-removable media. By way of example, and not limitation, computer-readable storage media or machine-readable storage media can be implemented in connection with any method or technology for storage of information such as computer-readable or machine-readable instructions, program modules, structured data or unstructured data.

Computer-readable storage media can include, but are not limited to, random access memory (RAM), read only memory (ROM), electrically erasable programmable read only memory (EEPROM), flash memory or other memory technology, compact disk read only memory (CD-ROM), digital versatile disk (DVD), Blu-ray disc (BD) or other optical disk storage, magnetic cassettes, magnetic tape, magnetic disk storage or other magnetic storage devices, solid state drives or other solid state storage devices, or other tangible or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

Computer-readable storage media can be accessed by one or more local or remote computing devices, e.g., via access requests, queries or other data retrieval protocols, for a variety of operations with respect to the information stored by the medium.

Communications media typically embody computer-readable instructions, data structures, program modules or other structured or unstructured data in a data signal such as a modulated data signal, e.g., a carrier wave or other transport mechanism, and includes any information delivery or transport media. The term “modulated data signal” or signals refers to a signal that has one or more of its characteristics set or changed in such a manner as to encode information in one or more signals. By way of example, and not limitation, communication media include wired media, such as a wired network or direct-wired connection, and wireless media such as acoustic, RF, infrared and other wireless media.

With reference again to FIG. 29, the example environment 2900 for implementing various embodiments of the aspects described herein includes a computer 2902, the computer 2902 including a processing unit 2904, a system memory 2906 and a system bus 2908. The system bus 2908 couples system components including, but not limited to, the system memory 2906 to the processing unit 2904. The processing unit 2904 can be any of various commercially available processors. Dual microprocessors and other multi-processor architectures can also be employed as the processing unit 2904.

The system bus 2908 can be any of several types of bus structure that can further interconnect to a memory bus (with or without a memory controller), a peripheral bus, and a local bus using any of a variety of commercially available bus architectures. The system memory 2906 includes ROM 2910 and RAM 2912. A basic input/output system (BIOS) can be stored in a non-volatile memory such as ROM, erasable programmable read only memory (EPROM), EEPROM, which BIOS contains the basic routines that help to transfer information between elements within the computer 2902, such as during startup. The RAM 2912 can also include a high-speed RAM such as static RAM for caching data.

The computer 2902 further includes an internal hard disk drive (HDD) 2914 (e.g., EIDE, SATA), one or more external storage devices 2916 (e.g., a magnetic floppy disk drive (FDD) 2916, a memory stick or flash drive reader, a memory card reader, etc.) and a drive 2920, e.g., such as a solid state drive, an optical disk drive, which can read or write from a disk 2922, such as a CD-ROM disc, a DVD, a BD, etc. Alternatively, where a solid state drive is involved, disk 2922 would not be included, unless separate. While the internal HDD 2914 is illustrated as located within the computer 2902, the internal HDD 2914 can also be configured for external use in a suitable chassis (not shown). Additionally, while not shown in environment 2900, a solid state drive (SSD) could be used in addition to, or in place of, an HDD 2914. The HDD 2914, external storage device(s) 2916 and drive 2920 can be connected to the system bus 2908 by an HDD interface 2924, an external storage interface 2926 and a drive interface 2928, respectively. The interface 2924 for external drive implementations can include at least one or both of Universal Serial Bus (USB) and Institute of Electrical and Electronics Engineers (IEEE) 1394 interface technologies. Other external drive connection technologies are within contemplation of the embodiments described herein.

The drives and their associated computer-readable storage media provide nonvolatile storage of data, data structures, computer-executable instructions, and so forth. For the computer 2902, the drives and storage media accommodate the storage of any data in a suitable digital format. Although the description of computer-readable storage media above refers to respective types of storage devices, it should be appreciated by those skilled in the art that other types of storage media which are readable by a computer, whether presently existing or developed in the future, could also be used in the example operating environment, and further, that any such storage media can contain computer-executable instructions for performing the methods described herein.

A number of program modules can be stored in the drives and RAM 2912, including an operating system 2930, one or more application programs 2932, other program modules 2934 and program data 2936. All or portions of the operating system, applications, modules, or data can also be cached in the RAM 2912. The systems and methods described herein can be implemented utilizing various commercially available operating systems or combinations of operating systems.

Computer 2902 can optionally comprise emulation technologies. For example, a hypervisor (not shown) or other intermediary can emulate a hardware environment for operating system 2930, and the emulated hardware can optionally be different from the hardware illustrated in FIG. 29. In such an embodiment, operating system 2930 can comprise one virtual machine (VM) of multiple VMs hosted at computer 2902. Furthermore, operating system 2930 can provide runtime environments, such as the Java runtime environment or the .NET framework, for applications 2932. Runtime environments are consistent execution environments that allow applications 2932 to run on any operating system that includes the runtime environment. Similarly, operating system 2930 can support containers, and applications 2932 can be in the form of containers, which are lightweight, standalone, executable packages of software that include, e.g., code, runtime, system tools, system libraries and settings for an application.

Further, computer 2902 can be enable with a security module, such as a trusted processing module (TPM). For instance with a TPM, boot components hash next in time boot components, and wait for a match of results to secured values, before loading a next boot component. This process can take place at any layer in the code execution stack of computer 2902, e.g., applied at the application execution level or at the operating system (OS) kernel level, thereby enabling security at any level of code execution.

A user can enter commands and information into the computer 2902 through one or more wired/wireless input devices, e.g., a keyboard 2938, a touch screen 2940, and a pointing device, such as a mouse 2942. Other input devices (not shown) can include a microphone, an infrared (IR) remote control, a radio frequency (RF) remote control, or other remote control, a joystick, a virtual reality controller or virtual reality headset, a game pad, a stylus pen, an image input device, e.g., camera(s), a gesture sensor input device, a vision movement sensor input device, an emotion or facial detection device, a biometric input device, e.g., fingerprint or iris scanner, or the like. These and other input devices are often connected to the processing unit 2904 through an input device interface 2944 that can be coupled to the system bus 2908, but can be connected by other interfaces, such as a parallel port, an IEEE 1394 serial port, a game port, a USB port, an IR interface, a BLUETOOTH® interface, etc.

A monitor 2946 or other type of display device can be also connected to the system bus 2908 via an interface, such as a video adapter 2948. In addition to the monitor 2946, a computer typically includes other peripheral output devices (not shown), such as speakers, printers, etc.

The computer 2902 can operate in a networked environment using logical connections via wired or wireless communications to one or more remote computers, such as a remote computer(s) 2950. The remote computer(s) 2950 can be a workstation, a server computer, a router, a personal computer, portable computer, microprocessor-based entertainment appliance, a peer device or other common network node, and typically includes many or all of the elements described relative to the computer 2902, although, for purposes of brevity, only a memory/storage device 2952 is illustrated. The logical connections depicted include wired/wireless connectivity to a local area network (LAN) 2954 or larger networks, e.g., a wide area network (WAN) 2956. Such LAN and WAN networking environments are commonplace in offices and companies, and facilitate enterprise-wide computer networks, such as intranets, all of which can connect to a global communications network, e.g., the Internet.

When used in a LAN networking environment, the computer 2902 can be connected to the local network 2954 through a wired or wireless communication network interface or adapter 2958. The adapter 2958 can facilitate wired or wireless communication to the LAN 2954, which can also include a wireless access point (AP) disposed thereon for communicating with the adapter 2958 in a wireless mode.

When used in a WAN networking environment, the computer 2902 can include a modem 2960 or can be connected to a communications server on the WAN 2956 via other means for establishing communications over the WAN 2956, such as by way of the Internet. The modem 2960, which can be internal or external and a wired or wireless device, can be connected to the system bus 2908 via the input device interface 2944. In a networked environment, program modules depicted relative to the computer 2902 or portions thereof, can be stored in the remote memory/storage device 2952. It will be appreciated that the network connections shown are example and other means of establishing a communications link between the computers can be used.

When used in either a LAN or WAN networking environment, the computer 2902 can access cloud storage systems or other network-based storage systems in addition to, or in place of, external storage devices 2916 as described above, such as but not limited to a network virtual machine providing one or more aspects of storage or processing of information. Generally, a connection between the computer 2902 and a cloud storage system can be established over a LAN 2954 or WAN 2956 e.g., by the adapter 2958 or modem 2960, respectively. Upon connecting the computer 2902 to an associated cloud storage system, the external storage interface 2926 can, with the aid of the adapter 2958 or modem 2960, manage storage provided by the cloud storage system as it would other types of external storage. For instance, the external storage interface 2926 can be configured to provide access to cloud storage sources as if those sources were physically connected to the computer 2902.

The computer 2902 can be operable to communicate with any wireless devices or entities operatively disposed in wireless communication, e.g., a printer, scanner, desktop or portable computer, portable data assistant, communications satellite, any piece of equipment or location associated with a wirelessly detectable tag (e.g., a kiosk, news stand, store shelf, etc.), and telephone. This can include Wireless Fidelity (Wi-Fi) and BLUETOOTH® wireless technologies. Thus, the communication can be a predefined structure as with a conventional network or simply an ad hoc communication between at least two devices.

FIG. 30 is a schematic block diagram of a sample computing environment 3000 with which the disclosed subject matter can interact. The sample computing environment 3100 includes one or more client(s) 3010. The client(s) 3010 can be hardware or software (e.g., threads, processes, computing devices). The sample computing environment 3000 also includes one or more server(s) 3030. The server(s) 3030 can also be hardware or software (e.g., threads, processes, computing devices). The servers 3030 can house threads to perform transformations by employing one or more embodiments as described herein, for example. One possible communication between a client 3010 and a server 3030 can be in the form of a data packet adapted to be transmitted between two or more computer processes. The sample computing environment 3000 includes a communication framework 3050 that can be employed to facilitate communications between the client(s) 3010 and the server(s) 3030. The client(s) 3010 are operably connected to one or more client data store(s) 3020 that can be employed to store information local to the client(s) 3010. Similarly, the server(s) 3030 are operably connected to one or more server data store(s) 3040 that can be employed to store information local to the servers 3030.

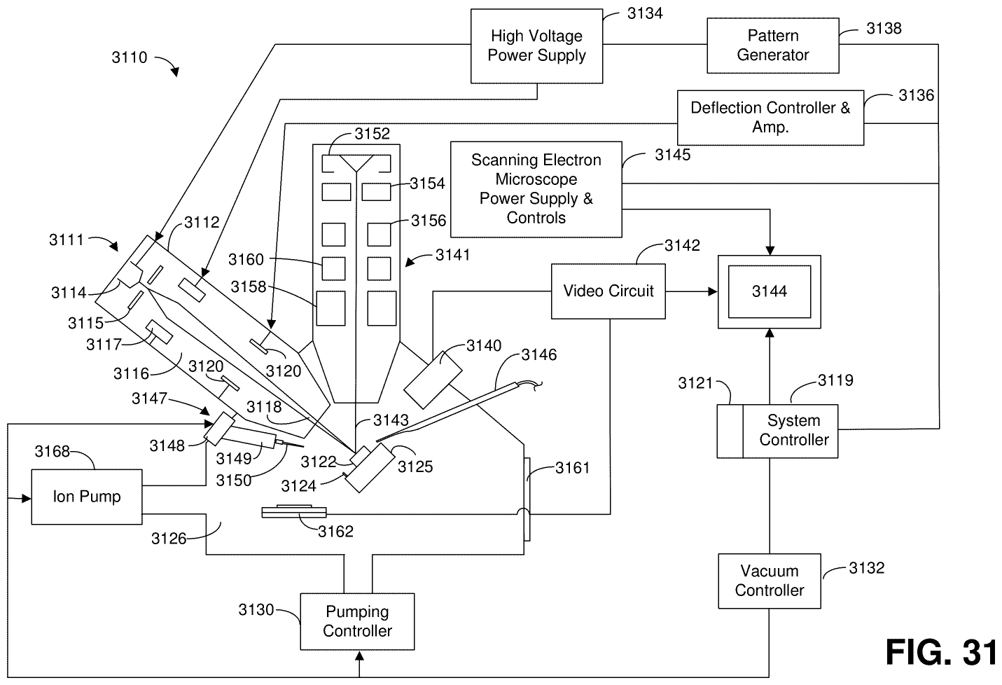

An example, non-limiting apparatus for performing various embodiments described herein is shown in FIG. 31. FIG. 31 illustrates a non-limiting example of a dual beam system 3110 with a vertically mounted scanning electron microscope (SEM) column and a focused ion beam (FIB) column mounted at an angle of approximately 52 degrees from the vertical. Such dual beam systems are commercially available, for example, from FEI Company, Hillsboro, Oregon, the assignee of the present application. While FIG. 31 shows an example of suitable microscopy hardware with which various embodiments described herein can be implemented, it is to be appreciated that such microscopy hardware is non-limiting. In other words, various embodiments described herein can be implemented in conjunction with any other suitable types of microscopy hardware. The dual beam system 3110 is a non-limiting example of the charged-particle microscope 302 or of any other scientific instruments discussed above.

A scanning electron microscope 3141, along with a power supply and control unit 3145, can be provided with the dual beam system 3110. An electron beam 3143 can be emitted from a cathode 3152 by applying voltage between the cathode 3152 and an anode 3154. The electron beam 3143 can be focused to a fine spot by means of a condensing lens 3156 and an objective lens 3158. The electron beam 3143 can be scanned two-dimensionally on any suitable specimen by means of a deflection coil 3160. Operation of the condensing lens 3156, the objective lens 3158, or the deflection coil 3160 can be controlled by the power supply and control unit 3145.

The electron beam 3143 can be focused onto a substrate 3122, which can be on a movable X-Y stage 3125 within a lower chamber 3126. When the electrons in the electron beam 3143 strike the substrate 3122, secondary electrons can be emitted. These secondary electrons can be detected by a secondary electron detector 3140 as discussed below. A scanning transmission electron microscopy (STEM) detector 3162, located beneath a STEM sample holder 3124 and the movable X-Y stage 3125, can collect electrons that are transmitted through the sample mounted on the STEM sample holder 3124 as discussed above.

The dual beam system 3110 can also include a focused ion beam (FIB) system 3111 which can comprise an evacuated chamber having an upper neck portion 3112 within which can be located an ion source 3114 and a focusing column 3116 including extractor electrodes and an electrostatic optical system (in some cases, the upper neck portion can also be referred to as an ion column 3112). The axis of the focusing column 3116 can be tilted 52 degrees (or any other suitable angular displacement) from the axis of the electron column. The ion column 3112 can include an ion source 3114, an extraction electrode 3115, a focusing element 3117, deflection elements 3120, and a focused ion beam 3118. The focused ion beam 3118 can pass from the ion source 3114 through the focusing column 3116 and between electrostatic deflection means schematically indicated at numeral 3120 toward the substrate 3122, which can comprise, for example, a semiconductor device positioned on the movable X-Y stage 3125 within the lower chamber 3126.

The movable X-Y stage 3125 can move in a horizontal plane (along X and Y axes) and vertically (along Z axis). The movable X-Y stage 3125 can tilt approximately sixty (60) degrees and rotate about the Z axis. In some embodiments, a separate STEM sample stage (not shown) can be used. Such a STEM sample stage can be moveable in the X, Y, and Z axes. A door 3161 can be opened for inserting the substrate 3122 onto the movable X-Y stage 3125 or also for servicing an internal gas supply reservoir, if one is used. The door 3161 can be interlocked so that it cannot be opened if the system is under vacuum.

An ion pump 3168 can be employed for evacuating the neck portion 3112. The chamber 3126 can be evacuated with a turbomolecular and mechanical pumping system 3130 under the control of a vacuum controller 3132. Such vacuum system can provide within the chamber 3126 a vacuum of between approximately 1×10⁻⁷ Torr and 5×10⁻⁴ Torr. If an etch assisting, an etch retarding gas, or a deposition precursor gas is used, the chamber background pressure may rise, typically to about 1×10.5 Torr.

A high voltage power supply 3134 can provide an appropriate acceleration voltage to electrodes in the focusing column 3116 for energizing and the focused ion beam 3118. When it strikes the substrate 3122, material can be sputtered (that is, physically ejected) from the sample. Alternatively, the focused ion beam 3118 can decompose a precursor gas to deposit a material.

The high voltage power supply 3134 can be connected to the ion source 3114 (which can be a liquid metal ion source) as well as to appropriate electrodes in the ion beam focusing column 3116 for forming an approximately 1 keV to 60 keV ion beam 3118 and directing the same toward a sample. A deflection controller and amplifier 3136, operated in accordance with a prescribed pattern provided by a pattern generator 3138, can be coupled to the deflection elements 3120 (which can be deflection plates) whereby the focused ion beam 3118 may be controlled manually or automatically to trace out a corresponding pattern on the upper surface of the substrate 3122. In some systems, the deflection elements 3120 can be placed before the final lens. Beam blanking electrodes (not shown) within the ion beam focusing column 3116 can cause the focused ion beam 3118 to impact onto a blanking aperture (not shown) instead of the substrate 3122 when a blanking controller (not shown) applies a blanking voltage to a blanking electrode.

The ion source 3114 can provide a metal ion beam of gallium, for example. In other examples, the ion source 3114 may be a plasma ion source that extracts ions from a generated plasma. The source can be capable of being focused into a sub one-tenth micrometer wide beam at the substrate 3122 for either modifying the substrate 3122 by ion milling, enhanced etch, material deposition, or for the purpose of imaging the substrate 3122.

A charged particle detector 3140, such as an Everhart Thornley or multi-channel plate, used for detecting secondary ion or electron emission can be connected to a video circuit 3142 that can supply drive signals to a video monitor 3144 and receive deflection signals from a system controller 3119. The location of the charged particle detector 3140 within the lower chamber 3126 can vary in different embodiments. For example, the charged particle detector 3140 can be coaxial with the ion beam and include a hole for allowing the ion beam to pass. In other embodiments, secondary particles can be collected through a final lens and then diverted off axis for collection.

A micromanipulator 3147 can precisely move objects within the vacuum chamber. The micromanipulator 3147 may comprise precision electric motors 3148 positioned outside the vacuum chamber to provide X, Y, Z, and theta control of a portion 3149 positioned within the vacuum chamber. The micromanipulator 3147 can be fitted with different end effectors for manipulating small objects. In various embodiments described herein, the end effector can be a thin probe 3150.

A gas delivery system 3146 can extend into the lower chamber 3126 for introducing and directing a gaseous vapor toward the substrate 3122. U.S. Pat. No. 5,851,413 to Casella et al. for “Gas Delivery Systems for Particle Beam Processing,” assigned to the assignee of the present invention, describes a suitable gas delivery system 3146. Another gas delivery system is described in U.S. Pat. No. 5,435,850 to Rasmussen for a “Gas Injection System,” also assigned to the assignee of the present invention. For example, iodine can be delivered to enhance etching, or a metal organic compound can be delivered to deposit a metal.

The system controller 3119 can control the operations of the various parts of the dual beam system 3110. Through the system controller 3119, a user can cause the focused ion beam 3118 or the electron beam 3143 to be scanned in a desired manner through commands entered into any suitable user interface (not shown). Alternatively, the system controller 3119 may control the dual beam system 3110 in accordance with programmed instructions stored in a memory 3121. In various embodiments, any of the one or more software components 325 can be implemented in or otherwise executed by the system controller 3119.

Various embodiments may be a system, a method, an apparatus or a computer program product at any possible technical detail level of integration. The computer program product can include a computer readable storage medium (or media) having computer readable program instructions thereon for causing a processor to carry out aspects of various embodiments. The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium can also include the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network or a wireless network. The network can comprise copper transmission cables, optical transmission fibers, wireless transmission, routers, firewalls, switches, gateway computers or edge servers. A network adapter card or network interface in each computing/processing device receives computer readable program instructions from the network and forwards the computer readable program instructions for storage in a computer readable storage medium within the respective computing/processing device. Computer readable program instructions for carrying out operations of various embodiments can be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions can execute entirely on the user's computer, partly on the user's computer, as a stand-alone software package, partly on the user's computer and partly on a remote computer or entirely on the remote computer or server. In the latter scenario, the remote computer can be connected to the user's computer through any type of network, including a local area network (LAN) or a wide area network (WAN), or the connection can be made to an external computer (for example, through the Internet using an Internet Service Provider). In some embodiments, electronic circuitry including, for example, programmable logic circuitry, field-programmable gate arrays (FPGA), or programmable logic arrays (PLA) can execute the computer readable program instructions by utilizing state information of the computer readable program instructions to personalize the electronic circuitry, in order to perform various aspects.

Various aspects are described herein with reference to flowchart illustrations or block diagrams of methods, apparatus (systems), and computer program products according to various embodiments. It will be understood that each block of the flowchart illustrations or block diagrams, and combinations of blocks in the flowchart illustrations or block diagrams, can be implemented by computer readable program instructions. These computer readable program instructions can be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart or block diagram block or blocks. These computer readable program instructions can also be stored in a computer readable storage medium that can direct a computer, a programmable data processing apparatus, or other devices to function in a particular manner, such that the computer readable storage medium having instructions stored therein comprises an article of manufacture including instructions which implement aspects of the function/act specified in the flowchart or block diagram block or blocks. The computer readable program instructions can also be loaded onto a computer, other programmable data processing apparatus, or other device to cause a series of operational acts to be performed on the computer, other programmable apparatus or other device to produce a computer implemented process, such that the instructions which execute on the computer, other programmable apparatus, or other device implement the functions/acts specified in the flowchart or block diagram block or blocks.

The flowcharts and block diagrams in the Figures illustrate the architecture, functionality, and operation of possible implementations of systems, methods, and computer program products according to various embodiments. In this regard, each block in the flowchart or block diagrams can represent a module, segment, or portion of instructions, which comprises one or more executable instructions for implementing the specified logical function(s). In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved. It will also be noted that each block of the block diagrams or flowchart illustration, and combinations of blocks in the block diagrams or flowchart illustration, can be implemented by special purpose hardware-based systems that perform the specified functions or acts or carry out combinations of special purpose hardware and computer instructions.

While the subject matter has been described above in the general context of computer-executable instructions of a computer program product that runs on a computer or computers, those skilled in the art will recognize that this disclosure also can or can be implemented in combination with other program modules. Generally, program modules include routines, programs, components, data structures, etc. that perform particular tasks or implement particular abstract data types. Moreover, those skilled in the art will appreciate that various aspects can be practiced with other computer system configurations, including single-processor or multiprocessor computer systems, mini-computing devices, mainframe computers, as well as computers, hand-held computing devices (e.g., PDA, phone), microprocessor-based or programmable consumer or industrial electronics, and the like. The illustrated aspects can also be practiced in distributed computing environments in which tasks are performed by remote processing devices that are linked through a communications network. However, some, if not all aspects of this disclosure can be practiced on stand-alone computers. In a distributed computing environment, program modules can be located in both local and remote memory storage devices.

As used in this application, the terms “component,” “system,” “platform,” “interface,” and the like, can refer to or can include a computer-related entity or an entity related to an operational machine with one or more specific functionalities. The entities disclosed herein can be either hardware, a combination of hardware and software, software, or software in execution. For example, a component can be, but is not limited to being, a process running on a processor, a processor, an object, an executable, a thread of execution, a program, or a computer. By way of illustration, both an application running on a server and the server can be a component. One or more components can reside within a process or thread of execution and a component can be localized on one computer or distributed between two or more computers. In another example, respective components can execute from various computer readable media having various data structures stored thereon. The components can communicate via local or remote processes such as in accordance with a signal having one or more data packets (e.g., data from one component interacting with another component in a local system, distributed system, or across a network such as the Internet with other systems via the signal). As another example, a component can be an apparatus with specific functionality provided by mechanical parts operated by electric or electronic circuitry, which is operated by a software or firmware application executed by a processor. In such a case, the processor can be internal or external to the apparatus and can execute at least a part of the software or firmware application. As yet another example, a component can be an apparatus that provides specific functionality through electronic components without mechanical parts, wherein the electronic components can include a processor or other means to execute software or firmware that confers at least in part the functionality of the electronic components. In an aspect, a component can emulate an electronic component via a virtual machine, e.g., within a cloud computing system.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. As used herein, the term “and/or” is intended to have the same meaning as “or.” Moreover, articles “a” and “an” as used in the subject specification and annexed drawings should generally be construed to mean “one or more” unless specified otherwise or clear from context to be directed to a singular form. As used herein, the terms “example” or “exemplary” are utilized to mean serving as an example, instance, or illustration. For the avoidance of doubt, the subject matter disclosed herein is not limited by such examples. In addition, any aspect or design described herein as an “example” or “exemplary” is not necessarily to be construed as preferred or advantageous over other aspects or designs, nor is it meant to preclude equivalent exemplary structures and techniques known to those of ordinary skill in the art.

The herein disclosure describes non-limiting examples. For ease of description or explanation, various portions of the herein disclosure utilize the term “each,” “every,” or “all” when discussing various examples. Such usages of the term “each,” “every,” or “all” are non-limiting. In other words, when the herein disclosure provides a description that is applied to “each,” “every,” or “all” of some particular object or component, it should be understood that this is a non-limiting example, and it should be further understood that, in various other examples, it can be the case that such description applies to fewer than “each,” “every,” or “all” of that particular object or component.

As it is employed in the subject specification, the term “processor” can refer to substantially any computing processing unit or device comprising, but not limited to, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. Further, processors can exploit nano-scale architectures such as, but not limited to, molecular and quantum-dot based transistors, switches and gates, in order to optimize space usage or enhance performance of user equipment. A processor can also be implemented as a combination of computing processing units. In this disclosure, terms such as “store,” “storage,” “data store,” data storage,” “database,” and substantially any other information storage component relevant to operation and functionality of a component are utilized to refer to “memory components,” entities embodied in a “memory,” or components comprising a memory. It is to be appreciated that memory or memory components described herein can be either volatile memory or nonvolatile memory, or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory, or nonvolatile random access memory (RAM) (e.g., ferroelectric RAM (FeRAM). Volatile memory can include RAM, which can act as external cache memory, for example. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM), and Rambus dynamic RAM (RDRAM). Additionally, the disclosed memory components of systems or computer-implemented methods herein are intended to include, without being limited to including, these and any other suitable types of memory.

What has been described above include mere examples of systems and computer-implemented methods. It is, of course, not possible to describe every conceivable combination of components or computer-implemented methods for purposes of describing this disclosure, but many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations will be apparent without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Various non-limiting aspects are described in the following examples.

Example 1: An apparatus can comprise: a positioning mechanism that can be configured to be coupled to a vacuum chamber of a charged-particle microscope; and an adjustable force applicator coupled to the positioning mechanism and that can be configured to simulate a vacuum for a microscopy grid receptacle located on an inner surface of a load-lock door of the vacuum chamber by mechanically pressing against an outer surface of the load-lock door.

Example 2: The apparatus of any preceding example can be implemented, wherein the adjustable force applicator can comprise a toggle-clamp, an electric rotary or linear actuator, a pneumatic rotary or linear actuator, or a hydraulic rotary or linear actuator.

Example 3: The apparatus of any preceding example can be implemented, wherein the positioning mechanism can be configured to move the adjustable force applicator between: a retracted position in which the adjustable force applicator is not in contact with the load-lock door; and a deployed position in which the adjustable force applicator is in contact with the load-lock door.

Example 4: The apparatus of any preceding example can be implemented, wherein the positioning mechanism can comprise one or more sliding, articulating, or telescoping arms or frames.

Example 5: The apparatus of any preceding example can be implemented, further comprising: a feedback sensor coupled to the load-lock door and configured to measure feedback associated with the load-lock door.

Example 6: The apparatus of any preceding example can be implemented, wherein the feedback can be a deflection experienced by the load-lock door or a force experienced by the load-lock door.

Example 7: The apparatus of any preceding example can be implemented, wherein the feedback sensor can comprise a strain gauge, a spring gauge, a force or pressure transducer, or a contactless displacement sensor.

Example 8: The apparatus of any preceding example can be implemented, further comprising: a processor that can be configured to: cause the positioning mechanism to move the adjustable force applicator to the retracted position; activate a pump of the vacuum chamber, thereby causing the vacuum chamber to transition to a vacuumed state; measure, via the feedback sensor, a reference feedback signal that the load-lock door experiences due to the vacuumed state; activate a vent of the vacuum chamber, thereby causing the vacuum chamber to transition to a vented state; cause the positioning mechanism to move the adjustable force applicator to the deployed position; and identify, via the feedback sensor and by causing the adjustable force applicator to sweep through a plurality of pressing input values, a pressing input value of the adjustable force applicator that causes the load-lock door to experience the reference feedback signal.

Example 9: The apparatus of any preceding example can be implemented, wherein the processor can be configured to: perform a vacuum-less alignment procedure on the microscopy grid receptacle using the identified pressing input value.

In various embodiments, any combination or combinations of examples 1-9 can be implemented.

Example 10: A method can comprise: coupling a positioning mechanism to a charged-particle microscope, wherein the charged-particle microscope has a vacuum chamber with a load-lock door and a microscopy grid receptacle coupled to an inner surface of the load-lock door; and simulating a vacuum for the microscopy grid receptacle by mechanically pressing against an outer surface of the load-lock door via an adjustable force applicator that is coupled to the positioning mechanism.

Example 11: The method of any preceding example can be implemented, wherein the adjustable force applicator can comprise a toggle-clamp, an electric rotary or linear actuator, a pneumatic rotary or linear actuator, or a hydraulic rotary or linear actuator.

Example 12: The method of any preceding example can be implemented, wherein the positioning mechanism can be configured to move the adjustable force applicator between: a retracted position in which the adjustable force applicator is not in contact with the load-lock door; and a deployed position in which the adjustable force applicator is in contact with the load-lock door.

Example 13: The method of any preceding example can be implemented, wherein the positioning mechanism can comprise one or more sliding, articulating, or telescoping arms or frames.

Example 14: The method of any preceding example can be implemented, wherein the charged-particle microscope can comprise a feedback sensor coupled to the load-lock door and configured to measure feedback associated with the load-lock door.

Example 15: The method of any preceding example can be implemented, wherein the feedback can be a deflection experienced by the load-lock door or a force experienced by the load-lock door.

Example 16: The method of any preceding example can be implemented, wherein the feedback sensor can comprise a strain gauge, a spring gauge, a force or pressure transducer, or a contactless displacement sensor.

Example 17: The method of any preceding example can be implemented, further comprising: causing the positioning mechanism to move the adjustable force applicator to the retracted position; activating a pump of the vacuum chamber, thereby causing the vacuum chamber to transition to a vacuumed state; measuring, via the feedback sensor, a reference feedback signal that the load-lock door experiences due to the vacuumed state; activating a vent of the vacuum chamber, thereby causing the vacuum chamber to transition to a vented state; causing the positioning mechanism to move the adjustable force applicator to the deployed position; and identifying, via the feedback sensor and by causing the adjustable force applicator to sweep through a plurality of pressing input values, a pressing input value of the adjustable force applicator that causes the load-lock door to experience the reference feedback signal.

Example 18: The method of any preceding example can be implemented, further comprising: performing a vacuum-less alignment procedure on the microscopy grid receptacle using the identified pressing input value.

In various embodiments, any combination or combinations of examples 10-18 can be implemented.

Example 19: A method can comprise: causing a vacuum chamber of a charged-particle microscope to enter a vacuumed state; measuring, via a feedback sensor coupled to a load-lock door of the vacuum chamber, a vacuum-induced deflection or pressure experienced by the load-lock door due to the vacuumed state; causing the vacuum chamber to exit the vacuumed state; and simulating the vacuumed state, by causing an adjustable force applicator to mechanically press against the load-lock door such that the load-lock door experiences the vacuum-induced deflection or pressure while the vacuum chamber is not in the vacuumed state.

Example 20: The method of any preceding example can be implemented, wherein the adjustable force applicator can be an electric, pneumatic, or hydraulic piston or clamp, and wherein the feedback sensor can be a strain gauge, force transducer, or contactless displacement sensor.

In various embodiments, any combination or combinations of examples 19-20 can be implemented.

Example 21: A method can comprise: accessing a scientific instrument having a load-bearing structure; causing the scientific instrument to enter an operational state, such that the load-bearing structure is in use; measuring, via a feedback sensor coupled to the load-bearing structure, an operational deflection or pressure experienced by the load-bearing structure due to the operational state; causing the scientific instrument to exit the operational state, such that the load-bearing structure is no longer in use; and simulating the operational state, by causing an adjustable force applicator to mechanically press against the load-bearing structure such that the load-bearing structure experiences the operational deflection or pressure while the scientific instrument is not in the operational state.

Example 22: The method of any preceding example can be implemented, wherein the load-bearing structure can comprise a load-lock door of a vacuum chamber of the scientific instrument.

In various embodiments, any combination or combinations of examples 21-22 can be implemented.

In various embodiments, any combination or combinations of examples 1-22 can be implemented.

What is claimed is:

1. An apparatus, comprising:
a positioning mechanism configured to be coupled to a vacuum chamber of a charged-particle microscope; and
an adjustable force applicator coupled to the positioning mechanism and configured to simulate a vacuum for a microscopy grid receptacle located on an inner surface of a load-lock door of the vacuum chamber by mechanically pressing against an outer surface of the load-lock door.

2. The apparatus of claim 1, wherein the adjustable force applicator comprises a toggle-clamp, an electric rotary or linear actuator, a pneumatic rotary or linear actuator, or a hydraulic rotary or linear actuator.

3. The apparatus of claim 1, wherein the positioning mechanism is configured to move the adjustable force applicator between:
a retracted position in which the adjustable force applicator is not in contact with the load-lock door; and
a deployed position in which the adjustable force applicator is in contact with the load-lock door.

4. The apparatus of claim 3, wherein the positioning mechanism comprises one or more sliding, articulating, or telescoping arms or frames.

5. The apparatus of claim 3, further comprising:
a feedback sensor coupled to the load-lock door and configured to measure feedback associated with the load-lock door.

6. The apparatus of claim 5, wherein the feedback is a deflection experienced by the load-lock door or a force experienced by the load-lock door.

7. The apparatus of claim 6, wherein the feedback sensor comprises a strain gauge, a spring gauge, a force or pressure transducer, or a contactless displacement sensor.

8. The apparatus of claim 5, further comprising:
a processor that is configured to:
cause the positioning mechanism to move the adjustable force applicator to the retracted position;
activate a pump of the vacuum chamber, thereby causing the vacuum chamber to transition to a vacuumed state;
measure, via the feedback sensor, a reference feedback signal that the load-lock door experiences due to the vacuumed state;
activate a vent of the vacuum chamber, thereby causing the vacuum chamber to transition to a vented state;
cause the positioning mechanism to move the adjustable force applicator to the deployed position; and
identify, via the feedback sensor and by causing the adjustable force applicator to sweep through a plurality of pressing input values, a pressing input value of the adjustable force applicator that causes the load-lock door to experience the reference feedback signal.

9. The apparatus of claim 8, wherein the processor is configured to:
perform a vacuum-less alignment procedure on the microscopy grid receptacle using the identified pressing input value.

10. A method, comprising:
coupling a positioning mechanism to a charged-particle microscope, wherein the charged-particle microscope has a vacuum chamber with a load-lock door and a microscopy grid receptacle coupled to an inner surface of the load-lock door; and
simulating a vacuum for the microscopy grid receptacle by mechanically pressing against an outer surface of the load-lock door via an adjustable force applicator that is coupled to the positioning mechanism.

11. The method of claim 10, wherein the adjustable force applicator comprises a toggle-clamp, an electric rotary or linear actuator, a pneumatic rotary or linear actuator, or a hydraulic rotary or linear actuator.

12. The method of claim 10, wherein the positioning mechanism is configured to move the adjustable force applicator between:
a retracted position in which the adjustable force applicator is not in contact with the load-lock door; and
a deployed position in which the adjustable force applicator is in contact with the load-lock door.

13. The method of claim 12, wherein the positioning mechanism comprises one or more sliding, articulating, or telescoping arms or frames.

14. The method of claim 12, wherein the charged-particle microscope comprises a feedback sensor coupled to the load-lock door and configured to measure feedback associated with the load-lock door.

15. The method of claim 14, wherein the feedback is a deflection experienced by the load-lock door or a force experienced by the load-lock door.

16. The method of claim 15, wherein the feedback sensor comprises a strain gauge, a spring gauge, a force or pressure transducer, or a contactless displacement sensor.

17. The method of claim 14, further comprising:
causing the positioning mechanism to move the adjustable force applicator to the retracted position;
activating a pump of the vacuum chamber, thereby causing the vacuum chamber to transition to a vacuumed state;
measuring, via the feedback sensor, a reference feedback signal that the load-lock door experiences due to the vacuumed state;
activating a vent of the vacuum chamber, thereby causing the vacuum chamber to transition to a vented state;
causing the positioning mechanism to move the adjustable force applicator to the deployed position; and
identifying, via the feedback sensor and by causing the adjustable force applicator to sweep through a plurality of pressing input values, a pressing input value of the adjustable force applicator that causes the load-lock door to experience the reference feedback signal.

18. The method of claim 17, further comprising:
performing a vacuum-less alignment procedure on the microscopy grid receptacle using the identified pressing input value.

19. A method, comprising:
causing a vacuum chamber of a charged-particle microscope to enter a vacuumed state;
measuring, via a feedback sensor coupled to a load-lock door of the vacuum chamber, a vacuum-induced deflection or pressure experienced by the load-lock door due to the vacuumed state;
causing the vacuum chamber to exit the vacuumed state; and
simulating the vacuumed state, by causing an adjustable force applicator to mechanically press against the load-lock door such that the load-lock door experiences the vacuum-induced deflection or pressure while the vacuum chamber is not in the vacuumed state.

20. The method of claim 19, wherein the adjustable force applicator is an electric, pneumatic, or hydraulic piston or clamp, and wherein the feedback sensor is a strain gauge, force transducer, or contactless displacement sensor.
